(19) United States
(12) Patent Application Publication
(10) Pub. No.: US 2026/0080646 A1
(43) Pub. Date: Mar. 19, 2026

(54) AUTOMATED ASSET GENERATION FOR ROBOTIC ASSEMBLY TASKS

(71) Applicant: NVIDIA Corporation, Santa Clara, CA (US)

(72) Inventors: Yian WANG, Amherst, MA (US); Kaichun MO, Kirkland, WA (US); Bingjie TANG, Los Angeles, CA (US); Dieter FOX, Seattle, WA (US); Yashraj NARANG, Seattle, WA (US); Iretiayo AKINOLA, Seattle, WA (US)

(21) Appl. No.: 19/275,879

(22) Filed: Jul. 21, 2025

Related U.S. Application Data
(60) Provisional application No. 63/696,112, filed on Sep. 18, 2024.

(51) Int. Cl. G06T 19/20; G06F 30/20; G06T 5/70

(52) U.S. Cl. CPC G06T 19/20; G06F 30/20; G06T 5/70; G06T 2219/2016

(57) ABSTRACT

In various examples, a three-stage pipeline is used to automate the generation of paired parts (or components) in assemblies. The pipeline includes a first contact surface extraction stage, in which a set of contact surfaces is extracted from a first part based on attributes identified by a vision language model (VLM) and/or another type of machine learning model from a visual and/or another representation of the first part. The pipeline also includes a shape completion stage, in which the contact surfaces are used to condition the operation of a diffusion model and/or another type of three-dimensional (3D) generative model in generating a shape for a second part that is complementary to the first part. The pipeline further includes a clearance specification stage, in which the shape of a given part is updated to meet a minimum clearance distance from the other part.

### CROSS-REFERENCE TO RELATED APPLICATIONS

This application claims the benefit of U.S. Provisional Application No. 63/696,112, filed on Sep. 18, 2024, the contents of which are hereby incorporated by reference in their entirety.

### BACKGROUND

Neural motion control refers to the use of a neural network (or another type of machine learning model) to move and/or animate a physical and/or virtual entity. For example, a deep learning model may be trained to perform motion control by generating a sequence of poses (i.e., positions and orientations) corresponding to motion in a human, animal, robot, and/or another type of articulated object. The output poses may then be incorporated into a robot or other autonomous machine, a game, an animation, a simulation, and/or another application involving the articulated object.

Neural motion control can also be extended to robotic assembly, in which the motion of a robot (or another type of articulated object) is used to physically combine discrete parts (also referred to herein as assets) into functional products. For example, a robot may use machine learning models trained using neural motion control techniques to perform tasks such as (but not limited to) connecting an electronic device to a charging cable, assembling furniture, installing nuts and bolts, inserting bearings, and/or fastening components.

While assembly tasks typically involve concrete goals (e.g., moving two or more parts into fixed relative poses), a number of challenges exist in teaching autonomous robots to perform robotic assembly in a robust manner. More specifically, a robot should perceive, grasp, and insert parts in a precise and accurate manner under varying environmental conditions and uncertainties in the positions and orientations of the parts. To address these challenges, recent approaches have developed fast simulations for contact-rich scenarios, techniques for transferring contact-rich assembly policies trained in simulation to the real world, and assembly policy learning techniques that are capable of handling a single pair of parts.

However, existing approaches are unable to train a general policy that can reliably assemble a range of previously seen and/or unseen parts with diverse geometries. Further, while an increase in the quantity and diversity of training data can improve the ability of a robot assembly policy in generalizing across scenes, tasks, and learning techniques, existing datasets of assembly asset pairs (e.g., different plug-and-receptacle combinations) are typically generated and/or curated via a manual process, which limits the quantity and diversity of assembly problems that can be used for policy learning. Additionally, a dataset of assembly parts that is generated via conventional techniques may include paired assets that penetrate one another and/or have insufficient clearance, which interferes with the use of the paired assets in high-accuracy simulation environments with non-penetration constraints and/or real-world environments (e.g., because the paired assets cannot be physically assembled after manufacturing).

As the foregoing illustrates, what is needed in the art are more effective techniques for training robots to perform assembly tasks.

### BRIEF DESCRIPTION OF THE DRAWINGS

The present systems and methods for automated assembly asset generation for robotics systems and applications are described in detail below with reference to the attached drawing figures, wherein:

FIG. 1 illustrates a block diagram of a computing system configured to implement one or more aspects of at least one embodiment;

FIG. 2 is a more detailed illustration of the data-generation engine, training engine, and execution engine of FIG. 1, according to at least one embodiment;

FIG. 3A illustrates how the data-generation engine of FIG. 1 determines attributes associated with a part, according to at least one embodiment;

FIG. 3B illustrates how the data-generation engine of FIG. 1 determines contact surfaces associated with a part, according to at least one embodiment;

FIG. 4A illustrates an example set of parts and a corresponding set of paired parts generated by the data-generation engine of FIG. 1, according to at least one embodiment;

FIG. 4B illustrates how the data-generation engine of FIG. 1 performs clearance specification for a part and a corresponding paired part, according to at least one embodiment;

FIG. 4C illustrates how data-generation engine 122 of FIG. 1 performs clearance specification for a part and a corresponding paired part, according to at least one embodiment;

FIG. 5 illustrates a flow diagram of a method for generating data for robotic assembly, according to at least one embodiment;

FIG. 6A is an example of sensor locations having corresponding fields of view or sensory fields for example autonomous or semi-autonomous machines, in accordance with at least some embodiments of the present disclosure;

FIG. 6B is an illustration of an example of component and sensor locations on an autonomous or semi-autonomous vehicle, in accordance with at least some embodiments of the present disclosure;

FIG. 6C is a block diagram of an example system architecture for an autonomous or semi-autonomous vehicle, robot, and/or other machine type, in accordance with at least some embodiments of the present disclosure;

FIG. 6D is a block diagram of an example architecture of a computing system—such as a system-on-a-chip (SoC)—in accordance with at least some embodiments of the present disclosure;

FIG. 6E is a system diagram for communication between cloud-based server(s) and an example autonomous or semi-autonomous vehicle, robot, and/or other machine type, in accordance with at least some embodiments of the present disclosure;

FIG. 7 is a system diagram illustrating a three computer ecosystem, including a computing system for generating or creating artificial intelligence (AI)—such as AI training and validation data, a computing system for training artificial intelligence, and a computing system deploying the AI at the edge, in accordance with at least some embodiments of the present disclosure;

FIG. 8 is a block diagram of an example computing system for generative artificial intelligence (AI), in accordance with at least some embodiments of the present disclosure; and

FIG. 9 is a block diagram of an example computing device, in accordance with at least some embodiments of the present disclosure.

### DETAILED DESCRIPTION

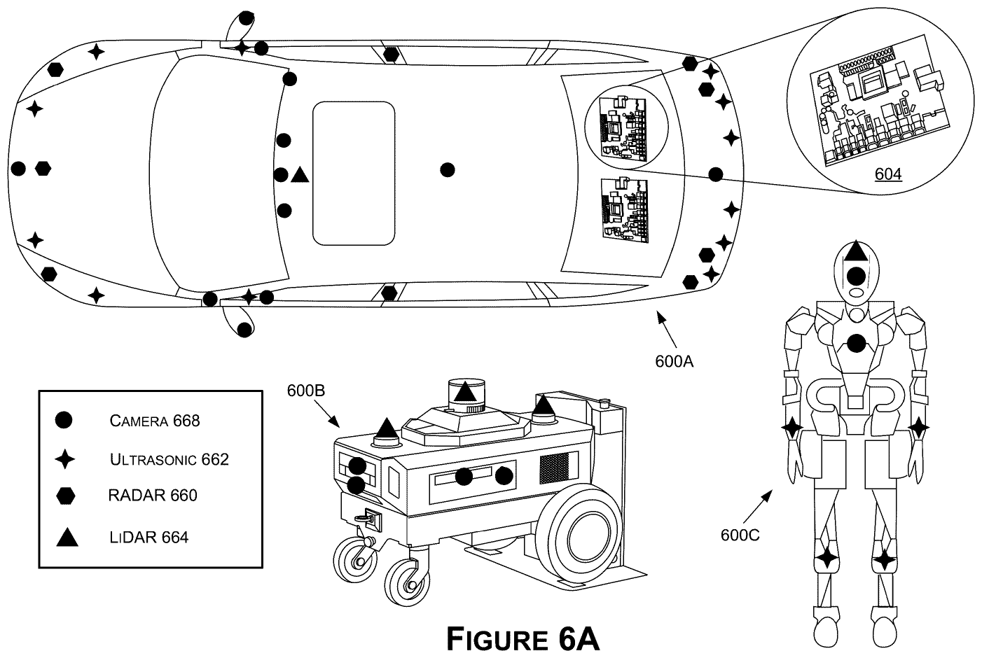

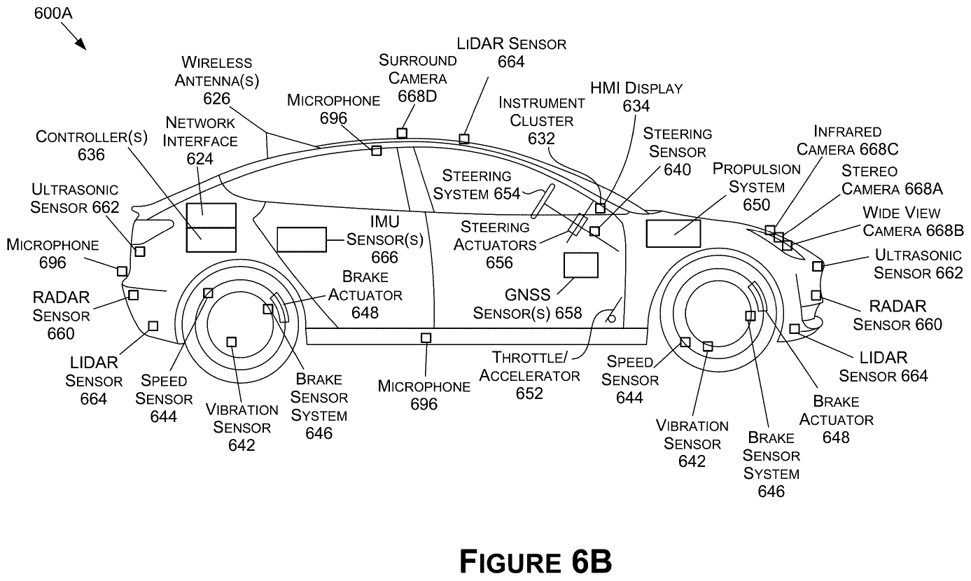

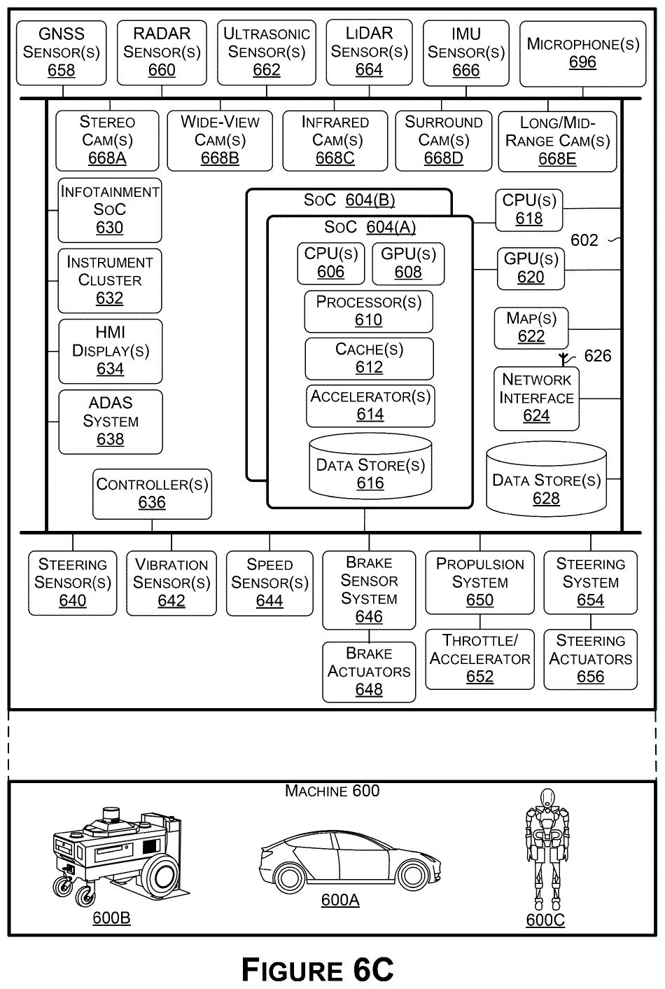

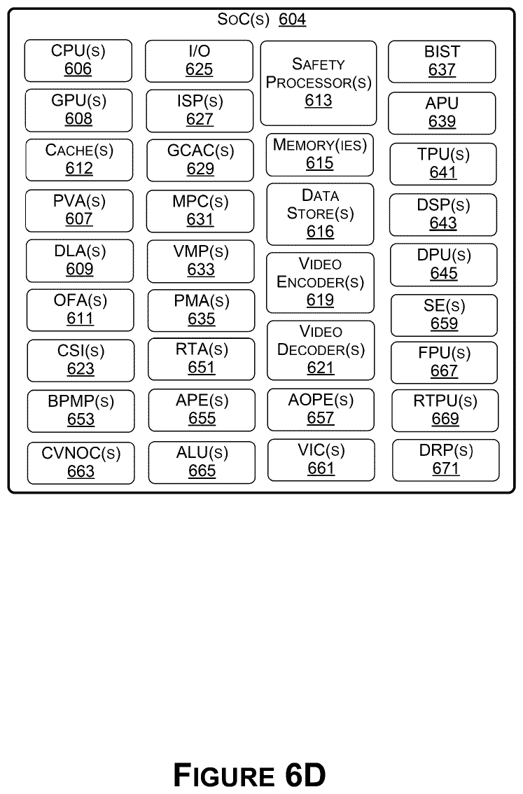

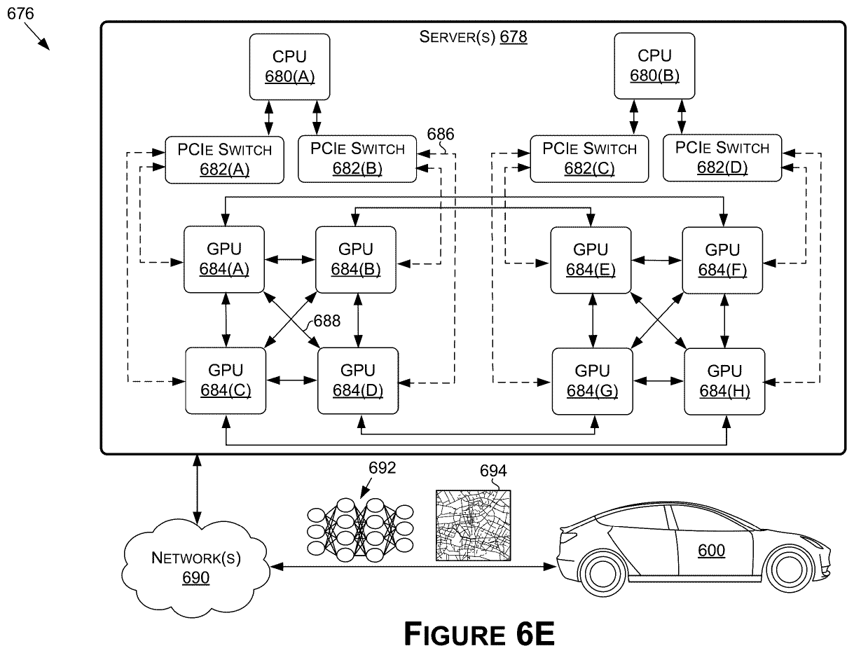

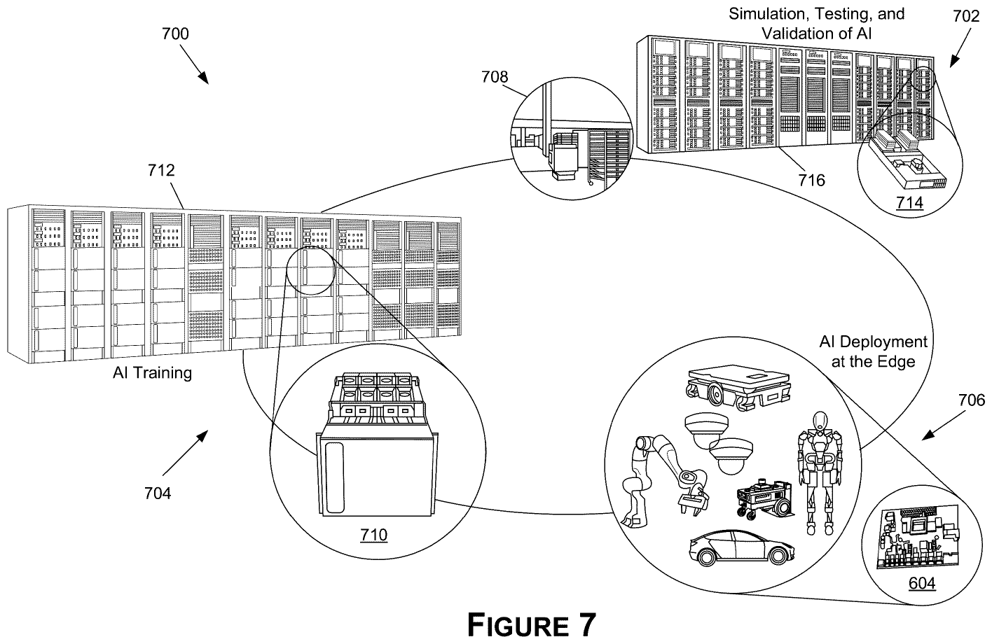

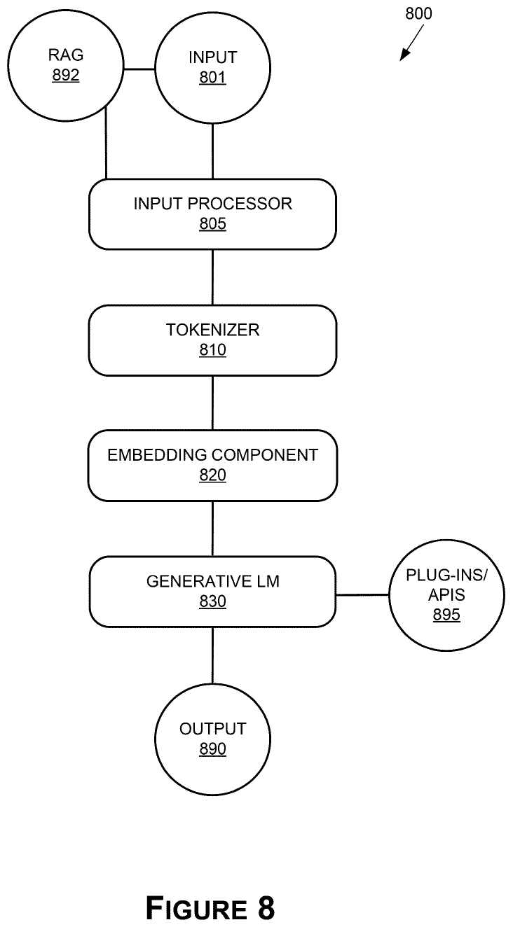

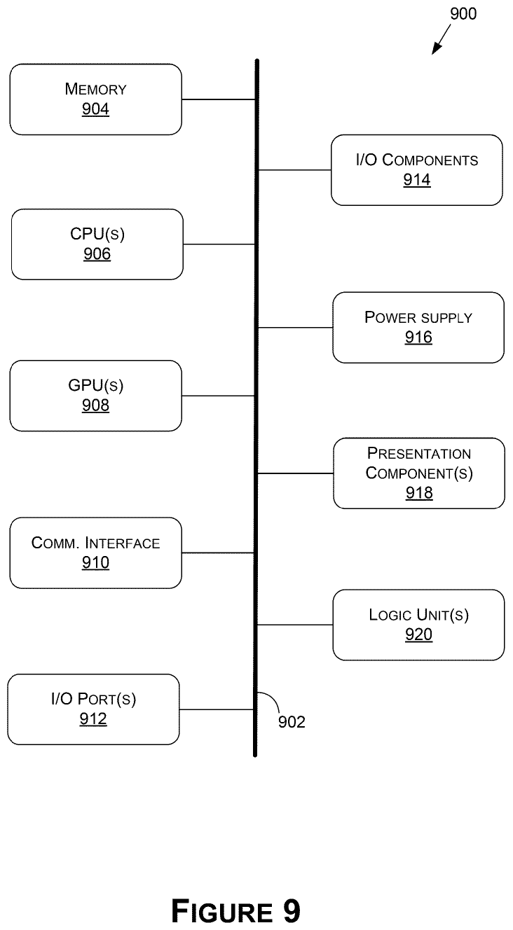

Systems and methods are disclosed related to automated assembly asset generation for robotics systems and applications. Although the present disclosure may be described with respect to an example autonomous or semi-autonomous vehicle, robot, and/or other machine type 600 (alternatively referred to herein as “vehicle 600,” “ego-vehicle 600,” “machine 600,” “ego-machine 600,” “robot 600,” and/or “ego-robot 600,” an example of which is described with respect to FIGS. 6A-6E), this is not intended to be limiting. For example, the systems and methods described herein may be used by, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms (e.g., autonomous mobile robots (AMRs), humanoid robots, robotic arms and/or end-effectors, warehouse vehicles, off-road vehicles, vehicles coupled to one or more trailers, flying vessels, watercraft, shuttles (e.g., robotaxis), emergency response vehicles, motorcycles, electric or motorized bicycles, aircraft, construction vehicles, underwater craft (e.g., piloted or unpiloted submarines), drones, and/or other vehicle, robot, or machine types. In addition, although the present disclosure may be described with respect to generation of robotic assembly assets, this is not intended to be limiting, and the systems and methods described herein may be used in augmented reality (AR), virtual reality (VR), mixed reality (MR), robotics, security and surveillance (e.g., smart cities), autonomous or semi-autonomous machine applications, industrial manufacturing, simulation, and/or any other technology spaces where assembly assets may be used. In some embodiments, the systems, methods, and/or processes described herein may be executed using similar components, features, and/or functionality to those of example machine 600 of FIGS. 6A-6E, example computing ecosystem 700 of FIG. 7, example generative language model system 800 of FIG. 8, and/or example computing device 900 of FIG. 9.

As discussed herein, it can be difficult to train a general policy that can reliably assemble a range of seen and/or unseen parts with diverse geometries. Further, while an increase in the quantity and diversity of training data can improve the ability of a robot assembly policy in generalizing across scenes, tasks, types of parts, and/or learning techniques, existing training datasets for robotic assembly tasks are limited in the number and/or types of assembly asset pairs that can be used in simulated and/or real-world environments.

To address the above limitations, the disclosed techniques include a three-stage pipeline that automates the generation of paired parts in assemblies. The pipeline includes a first contact surface extraction stage, in which a set of contact surfaces is extracted from a first part by a vision language model (VLM) and/or another type of machine learning model based on a visual and/or another representation of the first part. The pipeline also includes a second shape completion stage, in which the contact surfaces are used to condition the operation of a diffusion model and/or another type of three-dimensional (3D) generative model in generating a shape for a second part that is complementary to the first part. The pipeline further includes a third clearance specification stage, in which the shape of a given part is updated to meet a minimum clearance distance from the other part. Paired parts generated via the pipeline can then be used to train a policy on assembly tasks in a simulated environment, evaluate the performance of a deployed policy in a real-world environment, used in real-world assembly tasks, and/or used to perform other tasks related to assembly.

One advantage of the disclosed techniques relative to prior approaches is the ability to automatically generate a large and diverse set of paired parts that can be used in assembly tasks. Consequently, the disclosed techniques can be used to generate assembly asset pairs more quickly and efficiently than conventional approaches that involve manual generation and/or curation of robotic assembly datasets. The generated asset pairs can also be used to train, test, and/or evaluate robots on assembly tasks in a more comprehensive manner than robots that are trained using a much smaller and/or less diverse set of assemblies. Further, robots that are trained using the generated asset pairs may be more fault tolerant and/or capable of generalizing to different scenarios than robots that are trained using a more limited set of paired components. Additionally, the disclosed techniques can be used to “repair” interpenetrating assets generated via other techniques, thereby further increasing the number and types of assets that can be used in assembly tasks.

In some embodiments, the systems and methods described herein may be performed within a simulation environment (e.g., NVIDIA's Drive SIM, ISAAC Sim, ISAAC Gym, ISAAC Lab, etc.) using simulated data (e.g., simulated environmental data and simulated sensor data of simulated sensors of a virtual or simulated vehicle, robot, or machine within the simulated environment). For example, simulated input data (e.g., map data, perception data, ego-motion data, tactile data, and/or any other data described herein) may be used to determine assembly assets and/or environments associated with robotic assembly tasks, and this information may be used to perform operations associated with the virtual machine within the simulation environment. These simulated operations may be used to test performance of the underlying algorithms, systems, and/or processes prior to deploying them in the real-world. In some instances, the simulation may be used to generate synthetic training data—e.g., assembly asset pairs from within the simulation. The synthetic training data (in addition to or alternatively from real-world data) may then be used or processed to train and/or deploy policies for performing robotic assembly tasks.

In any example, such as where a simulation environment is used for testing, validation, training, etc., the simulation environment and/or associated training data may be rendered or otherwise generated using one or more light transport simulation algorithms—such as one or more ray-tracing and/or path-tracing algorithms. Where light transport simulation is used, the simulation system may employ one or more dedicated ray-tracing hardware accelerators and/or processors (e.g., NVIDIA's RTX, or another real-time ray-tracing GPU, such as those that include one or more ray tracing (RT) cores) optimized for performing real-time or near real-time light transport simulation operations in conjunction with one or more other processors of the system (e.g., GPUs, CPUs, accelerators, etc.). In some embodiments, the simulation environment and/or one or more objects, features, or components thereof may be generated or managed within a three-dimensional (3D) content collaboration platform (e.g., NVIDIA's OMNIVERSE) that may be optimized or suitable for industrial digitalization, generative physical artificial intelligence, and/or other use cases, applications, and/or services. For example, the content collaboration platform or system may include a system for using or developing universal scene descriptor (USD) (e.g., OpenUSD) data for managing objects, features, scenes, etc. within a simulated environment, digital environment, etc. The platform may include real physics simulation (e.g., using NVIDIA's PhysX software developer kit (SDK)), in order to simulate real physics and physical interactions with simulations hosted by the platform. The platform may integrate OpenUSD along with ray tracing/path tracing/light transport simulation (e.g., NVIDIA's RTX rendering technologies) into software tools and simulation workflows for building, training, deploying, and/or testing AI systems—such as systems for testing, validating, training (e.g., machine learning models, neural networks, etc.), and/or other tasks related to automobiles, robots, other machine types, and/or other systems and applications. In some examples, the simulation environment may include a digital twin of a real environment, such as a digital twin of a specific stretch of roadway, a warehouse, a data center, an airport, a geographic area, a marine area, and/or any other real environment where autonomous or semi-autonomous vehicles or machines may operate.

In some embodiments, teleoperation or remote control of a vehicle, robot, and/or other machine may be performed using a remote control or teleoperation system. For example, the systems and methods described herein may be used to generate and/or place assembly asset pairs that are included in a visualization or mapping of an environment to aid a remote operator in controlling—or providing waypoints or other indications of control or navigation—an autonomous or semi-autonomous machine through an environment. As such, the remote operator may use the visual, audible, textual, and/or other clues or indicators generated using the systems and methods described herein to aid in navigating the vehicle, robot, machine, etc. through a real-world environment using the teleoperation system.

In some embodiments, the system and methods described herein may be deployed in a robotics application. For example, a robot or robotic system may include one or more onboard processors (e.g., CPUs, GPUs, hardware-based deep learning accelerators (DLAs), deep learning accelerator clusters (XNNs), neural processing units (NPUs), neural network accelerators (NNAs), hardware-based programmable vision accelerators (PVAs)—which may include one or more vector processing units (VPUs), direct memory access (DMA) systems, and/or pixel processing engines (PPEs), hardware-based optical flow accelerators (OFAs), SoCs, etc.) and memory and/or storage (e.g., for storing control algorithms, sensor data, and one or more machine learning models). The robotic system may use these processors to execute one or more machine learning models (e.g., language models, vision language models (VLMs), large language models (LLMs), vision-language-action (VLA) models, multi-modal language models (MMLMs), etc.) that allow it to perform complex tasks autonomously or semi-autonomously, such as interacting with, assembling, and/or manipulating static and/or dynamic objects, or navigating environments using sensors such as cameras, LiDAR, RADAR, ultrasonic sensors, and more. The system may use sensor fusion techniques to combine data from multiple sensors (e.g., cameras, infrared, LiDAR, RADAR, accelerometers) to create a comprehensive model of the robot's surroundings. This data may be processed locally on the robot or sent to remote servers for more computationally intensive tasks, such as 3D mapping or SLAM (Simultaneous Localization and Mapping). In one or more embodiments, data from individual robots (e.g., sensor data, task status, or environmental conditions) may be uploaded to the cloud, where centralized AI models can analyze and distribute optimized commands to an entire fleet. In some embodiments, the machine learning model(s) (e.g., language models, VLMs, VLAs, LLMs, MMLMs, diffusion models, NeRF models, DNNs, etc.) described herein may be used to allow the robot to perceive and reason about the environment and/or communicate with one or more other robots and/or persons in an environment. In some embodiments, the robot may communicate (e.g., using one or more network interface cards (NICs) and/or data processing units (DPUs)) with one or more locally hosted servers/computing devices and/or with one or more remotely located servers/computing devices (e.g., in one or more data centers).

In some embodiments, the system and methods described herein may be deployed in an in-vehicle infotainment (IVI) system or in-cabin experience (IX) application. For example, the infotainment system within a vehicle (e.g., cars, trucks, drones, construction equipment, robots, semi-autonomous vehicles, or autonomous vehicles) may include one or more onboard processors (e.g., CPUs, GPUs, hardware-based deep learning accelerators (DLAs), deep learning accelerator cluster (XNNs), neural processing units (NPUs), neural network accelerators (NNAs), hardware-based programmable vision accelerators (PVAs)—which may include one or more vector processing units (VPUs), direct memory access (DMA) systems, and/or pixel processing engines (PPEs), hardware-based optical flow accelerators (OFAs), SoCs, etc.) and memory and/or storage (e.g., for storing control algorithms, sensor data, and one or more machine learning models). and memory and/or storage (e.g., for storing entertainment content, navigation data, and user preferences). The system may use these processors to execute one or more machine learning models (e.g., language models) to enable features such as voice control, personalized media recommendations, dynamic navigation, and real-time communication with other services through network connectivity. The in-vehicle infotainment system may also use natural language processing (NLP) models to enable voice-based interaction. The one or more machine learning models may be stored locally or accessed through one or more APIs that connect to cloud services, enabling the system to process requests in real time or near real-time.

In some examples, the machine learning model(s) (e.g., deep neural networks, language models, LLMs, VLMs, multi-modal language models, vision-language-action (VLA) models, perception models, tracking models, fusion models, transformer models, diffusion models, encoder-only models, decoder-only models, encoder-decoder models, neural rendering field (NERF) models, etc.) described herein may be packaged as a microservice—such an inference microservice (e.g., NVIDIA NIMs)—which may include a container (e.g., an operating system (OS)-level virtualization package) that may include an application programming interface (API) layer, a server layer, a runtime layer, and/or a model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examples—such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs—such as REST APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications—such as NVIDIA's TensorRT), and/or enterprise management data for telemetry (e.g., including identity, metrics, health checks, and/or monitoring). The machine learning model(s) described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the machine learning model(s) (e.g., a model(s) that has been optimized for high performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

Although examples may be described herein with respect to using machine learning models, such as neural networks, this is not intended to be limiting. For example, and without limitation, any of the various machine learning models and/or neural networks described herein may include any type of machine learning model, such as a machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoder neural networks, artificial neural networks (ANNs), convolutional neural networks (CNNs), recurrent neural networks (RNNs), perceptrons, Long/Short Term Memory (LSTM) networks, multi-layer perceptron (MLP) networks, deep stacking networks (DSNs), generative pre-training (GPT) models or networks, feed forward networks, radial basis function ANNs, self-organizing maps (SOMs), Kohonen maps, Hopfield networks, Boltzmann machine, deep belief neural networks, deconvolutional neural networks, generative adversarial networks (GANs), liquid state machines, modular neural networks, liquid state machines, sequence-to-sequence models, networks using transformer architectures, state space models (SSMs) (e.g., networks using Mamba architectures (e.g., Mamba-1, Mamba 2, etc.), networks using selective state space models, networks using structured state space sequence models, etc.), diffusion models (e.g., diffusion probabilistic models, score-based generative models, etc.), neural radiance field (NeRF) models, Gaussian splat models, Kolmogorov-Arnold networks (KANs), models with encoder-only architectures, models with decoder-only architectures, models with encoder-decoder architectures, generative machine learning models, language models, large language models (LLMs), vision language models (VLMs), multi-modal language models (MMLMs), large action models (LAMs), vision-language-action (VLA) models, etc.), and/or other types of machine learning models.

The systems and methods described herein may be used by, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms, warehouse vehicles, off-road vehicles, vehicles coupled to one or more trailers, flying vessels, watercraft, shuttles (e.g., robotaxis), emergency response vehicles, motorcycles, electric or motorized bicycles, aircraft, construction vehicles, underwater craft (e.g., piloted or unpiloted submarines), drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets (e.g., NVIDIA's Omniverse), cloud computing, and/or any other suitable applications.

Disclosed embodiments may be comprised in a variety of different systems such as automotive systems (e.g., a control system for an autonomous or semi-autonomous machine, a perception system for an autonomous or semi-autonomous machine, etc.), systems implemented using a robot, aerial systems, medial systems, boating systems, smart area monitoring systems, systems for performing deep learning operations, systems for performing simulation operations, systems for performing digital twin operations, systems implemented using an edge device, systems implementing language models—such as large language models (LLMs), vision language models (VLMs), vision-language-action (VLA) models, and/or multi-modal language models, systems using or deploying one or more inference microservices, systems that incorporate deploy one or more machine learning models in a service or microservice along with an OS-level virtualization package (e.g., a container), systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems for performing generative AI operations, systems implemented at least partially using cloud computing resources, and/or other types of systems.

### System Overview

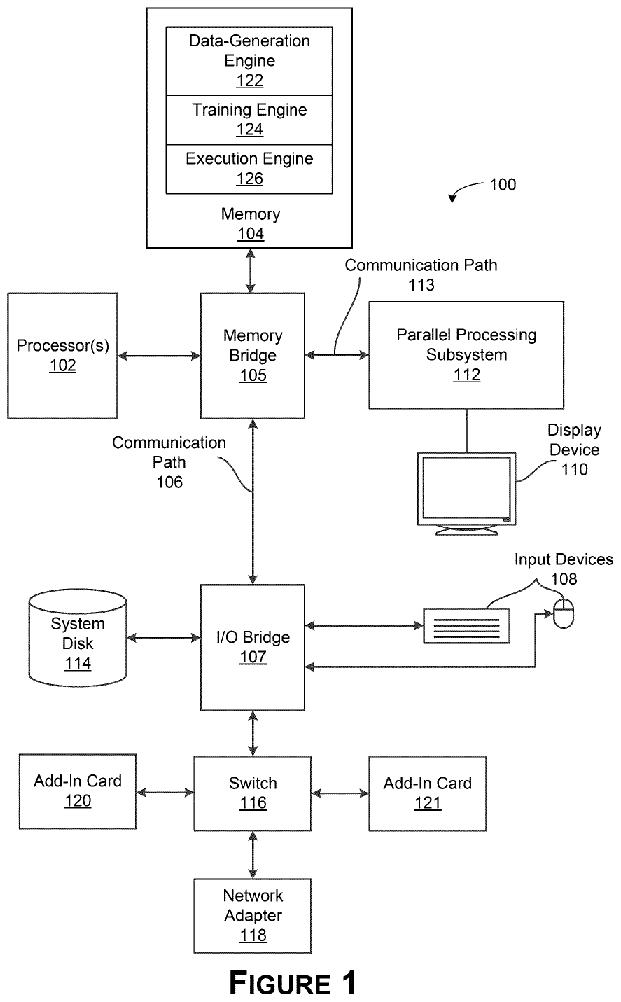

FIG. 1 is a block diagram illustrating a computing system 100 configured to implement one or more aspects of at least one embodiment. In at least one embodiment, computing system 100 may include any type of computing device, including, without limitation, a server machine, a server platform, a desktop machine, a laptop machine, a hand-held/mobile device, a digital kiosk, an in-vehicle infotainment system, a smart speaker or display, a television, and/or a wearable device. In at least one embodiment, computing system 100 is a server machine operating in a data center or a cloud computing environment that provides scalable computing resources as a service over a network.

In various embodiments, computing system 100 includes, without limitation, one or more processors 102 and one or more memories 104 coupled to a parallel processing subsystem 112 via a memory bridge 105 and a communication path 113. Memory bridge 105 is further coupled to an I/O (input/output) bridge 107 via a communication path 106, and I/O bridge 107 is, in turn, coupled to a switch 116.

In one embodiment, I/O bridge 107 is configured to receive user input information from optional input devices 108, such as (but not limited to) a keyboard, mouse, touch screen, sensor data analysis (e.g., evaluating gestures, speech, or other information about one or more uses in a field of view or sensory field of one or more sensors), a VR/MR/AR headset, a gesture recognition system, a steering wheel, mechanical, digital, or touch sensitive buttons or input components, and/or a microphone, and forward the input information to processor(s) 102 for processing. In at least one embodiment, computing system 100 may be a server machine in a cloud computing environment. In such embodiments, computing system 100 may omit input devices 108 and receive equivalent input information as commands (e.g., responsive to one or more inputs from a remote computing device) and/or messages transmitted over a network and received via the network adapter 118. In at least one embodiment, switch 116 is configured to provide connections between I/O bridge 107 and other components of computing system 100, such as a network adapter 118 and various add-in cards 120 and 121.

In at least one embodiment, I/O bridge 107 is coupled to a system disk 114 that may be configured to store content and applications and data for use by processor(s) 102 and parallel processing subsystem 112. In one embodiment, system disk 114 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 107 as well.

In various embodiments, memory bridge 105 may be a Northbridge chip, and I/O bridge 107 may be a Southbridge chip. In addition, communication paths 106 and 113, as well as other communication paths within computing system 100, may be implemented using any technically suitable protocols, including, without limitation, AGP (Accelerated Graphics Port), HyperTransport, or any other bus or point-to-point communication protocol known in the art.

In at least one embodiment, parallel processing subsystem 112 includes a graphics subsystem that delivers pixels to an optional display device 110 that may be any conventional cathode ray tube, liquid crystal display, light-emitting diode display, and/or the like. In such embodiments, parallel processing subsystem 112 may incorporate circuitry optimized for graphics and video processing, including, for example, video output circuitry. Such circuitry may be incorporated across one or more parallel processing units (PPUs), also referred to herein as parallel processors, included within the parallel processing subsystem 112.

In at least one embodiment, parallel processing subsystem 112 incorporates circuitry optimized (e.g., that undergoes optimization) for general purpose and/or compute processing. Again, such circuitry may be incorporated across one or more PPUs included within parallel processing subsystem 112 that are configured to perform such general purpose and/or compute operations. In yet other embodiments, the one or more PPUs included within parallel processing subsystem 112 may be configured to perform graphics processing, general purpose processing, and/or compute processing operations. Memor(ies) 104 include at least one device driver configured to manage the processing operations of the one or more PPUs within parallel processing subsystem 112. In addition, memor(ies) 104 include instructions implementing a data-generation engine 122, a training engine 124, and an execution engine 126, which can be executed by processor(s) and/or parallel processing subsystem 112.

In various embodiments, parallel processing subsystem 112 may be integrated with one or more of the other elements of FIG. 1 to form a single system. For example, parallel processing subsystem 112 may be integrated with processor(s) 102 and other connection circuitry on a single chip to form a system on a chip (SoC).

Processor(s) 102 may include any suitable processor implemented as a central processing unit (CPU), a graphics processing unit (GPU), an application-specific integrated circuit (ASIC), a field programmable gate array (FPGA), an artificial intelligence (AI) accelerator, a deep learning accelerator (DLA), a parallel processing unit (PPU), a data processing unit (DPU), a vector or vision processing unit (VPU), a programmable vision accelerator (PVA) (which may include one or more VPUs, pixel processing engines (PPEs), and/or direct memory access (DMA) systems), any other type of processing unit, or a combination of different processing units, such as a CPU(s) configured to operate in conjunction with a GPU(s). In general, processor(s) 102 may include any technically feasible hardware unit capable of processing data and/or executing software applications. Further, in the context of this disclosure, the computing elements shown in computing system 100 may correspond to a physical computing system (e.g., a system in a data center or a machine) and/or may correspond to a virtual computing instance executing within a computing cloud.

In at least one embodiment, processor(s) 102 issue commands that control the operation of PPUs. In at least one embodiment, communication path 113 is a Peripheral Component Interconnect Express (PCIe) link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processors 102, and the number of parallel processing subsystems 112, may be modified as desired. For example, in at least one embodiment, memor(ies) 104 may be connected to processor(s) 102 directly rather than through memory bridge 105, and other devices may communicate with memor(ies) 104 via memory bridge 105 and processors 102. In other embodiments, parallel processing subsystem 112 may be connected to I/O bridge 107 or directly to processor(s) 102, rather than to memory bridge 105. In still other embodiments, I/O bridge 107 and memory bridge 105 may be integrated into a single chip instead of existing as one or more discrete devices. In certain embodiments, one or more components shown in FIG. 1 may not be present. For example, switch 116 may be eliminated, and network adapter 118 and add-in cards 120, 121 would connect directly to I/O bridge 107. Further, in certain embodiments, one or more components shown in FIG. 1 may be implemented as virtualized resources in a virtual computing environment, such as a cloud computing environment. In particular, the parallel processing subsystem 112 may be implemented as a virtualized parallel processing subsystem in at least one embodiment. For example, the parallel processing subsystem 112 may be implemented as a virtual graphics processing unit(s) (vGPU(s)) that renders graphics on a virtual machine(s) (VM(s)) executing on a server machine(s) whose GPU(s) and other physical resources are shared across one or more VMs.

### Automated Assembly Asset Generation

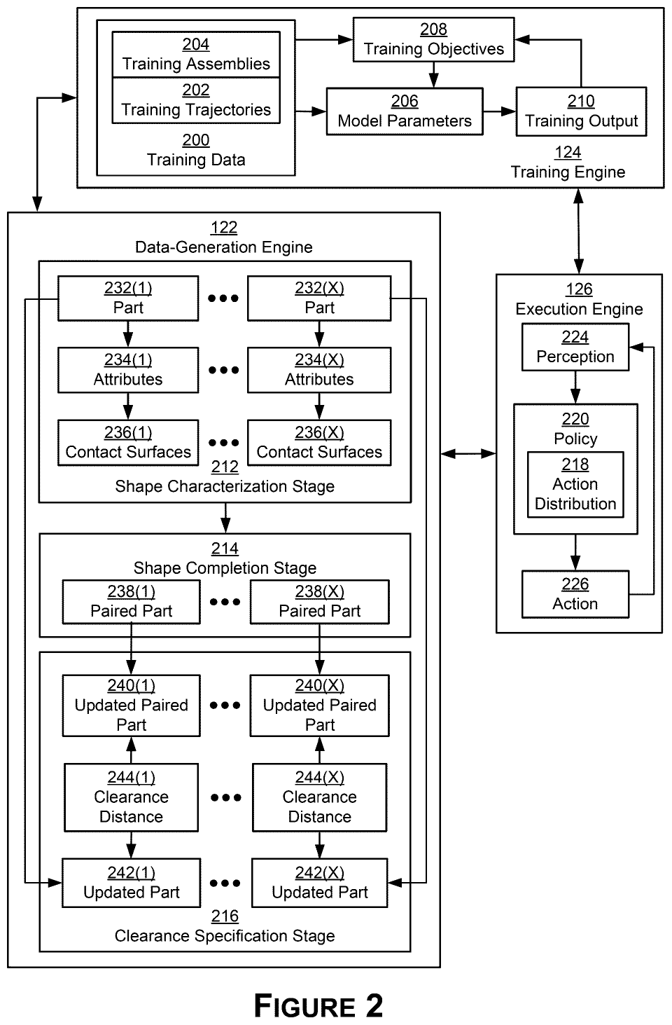

FIG. 2 is a more detailed illustration of data-generation engine 122, training engine 124, and execution engine 126 of FIG. 1, according to at least one embodiment. As discussed herein, data-generation engine 122, training engine 124, and execution engine 126 are configured to perform automated data generation, training, and/or inference for robotic assembly tasks. Each of these components is described in further detail below.

In one or more embodiments, robotic assembly refers to the use of a robot (or another type of articulated object) to physically combine discrete parts (also referred to herein as assets or components) into functional products. For example, robotic assembly may involve the use of a bimanual robot, human robot, and/or another type of robot to perform tasks such as (but not limited to) connecting an electronic device to a charging cable, assembling furniture, installing nuts and bolts, inserting bearings, and/or fastening components.

Additionally, robotic assembly may be performed under a framework for neural motion control, in which a policy 220 that includes one or more neural networks (or other types of machine learning models) is used to generate a different action 226 for each frame, or time step, in a motion for the robot. For example, each action 226 produced by policy 220 may be used to update a configuration of joints and/or other parts of the robot at a corresponding time step, thereby resulting in a corresponding motion in the robot. A sequence of actions generated by policy 220 for a corresponding sequence of time steps may be used to operate multiple arms and/or end effectors on each arm to perform one or more tasks involving manipulation and/or assembly of parts.

As shown in FIG. 2, each action 226 is generated by policy 220 based on a corresponding perception 224. In one or more embodiments, perception 224 includes data that represents the current and/or past state of the robot. For example, perception 224 may include (but is not limited to) current positions, angles, velocities, angular velocities, linear accelerations, contact forces, actions, and/or other physical attributes of joints, end effectors, and/or other parts of the robot. This data may be derived from inertial data, torque data, force data, and/or other sensory inputs available to the articulated object in a real-world and/or simulated environment.

Perception 224 may also, or instead, include observations of the real-world and/or simulated environment that are available to the robot. For example, perception 224 may include (but is not limited to) one or more camera views of the environment around the articulated object, one or more visualizations (e.g., birds-eye, perspective, 360-degree, etc.) that are generated by combining multiple camera views of the environment, semantic labels (e.g., segmentation maps, detected objects, bounding shapes, etc.) associated with the camera views and/or visualizations, three-dimensional (3D) representations of the environment (e.g., a point cloud, mesh, universal scene description (USD), etc.), and/or other representations of the environment.

In one or more embodiments, policy 220 generates an action distribution 218 based on input that includes perception 224. A corresponding action 226 may be sampled from action distribution 218 as positions, orientations, motor commands, and/or other types of output related to motion in the joints and/or end effectors of the robot. Action 226 may then be used to actuate the degrees of freedom in the robot (e.g., via a controller for the robot), resulting in an updated perception 224 for the next time step. The process may be repeated until an overall target goal (e.g., completion of one or more assembly tasks) is achieved and/or another predefined termination condition is met.

It will be appreciated that policy 220 can generate action distribution 218 based on additional input associated with the operation of the articulated object. For example, this additional input may include a goal to be attained by performing action 226 during the current time step. This goal may include target positions, orientations, angles, linear velocities, angular velocities, and/or other attributes of joints, end effectors, and/or other portions of the articulated object at various time steps. This goal may also, or instead, include higher-level task objectives such as (but not limited to) attaining a specific configuration of two or more parts and/or accomplishing a given task via manipulation of two or more parts using the arms and/or end effectors of the articulated object.

Data-generation engine 122 generates asset pairs that can be physically assembled in a simulated and/or real-world environment. Each asset pair includes a first part 232(1)-232(X) (each of which is referred to individually herein as part 232) and a second paired part 238(1)-238(X) (each of which is referred to individually herein as paired part 238) that is complementary to the first part 232. For example, a given part 232 and a corresponding paired part 238 may include a screwdriver and screw, nut and bolt, container and lid, and/or another type of plug and receptacle that can be mated with one another to form a corresponding assembly.

In some embodiments, data-generation engine 122 performs assembly asset generation over a pipeline that includes three stages. As shown in FIG. 2, the pipeline includes a shape characterization stage 212, in which data-generation engine 122 determines different sets of attributes 234(1)-234(X) (each of which is referred to individually herein as attributes 234) and contact surfaces 236(1)-236(X) (each of which is referred to individually herein as contact surfaces 236) for individual parts 232.

In one or more embodiments, shape characterization stage 212 involves interaction between data-generation engine 122 and a VLM, LLM, MMLM, and/or another type of machine learning model that is capable of general-purpose understanding and/or generation of natural language and visual content. Input into the machine learning model includes a visual and/or another representation of a given part 232 to be characterized. For example, part 232 may include a computer aided design (CAD) model and/or another three-dimensional (3D) representation of a standalone asset that is sampled from a dataset and/or generated (e.g., by a user, another machine learning model, a procedural generation technique, etc.). Data-generation engine 122 may generate a rendering of part 232 using a set of pre-specified and/or user-defined parameters (e.g., normalizing part 232 to fit into a [−1,1]³ bounding box and rendering part 232 from a top-front view at coordinates (5,5,0) looking toward (0,0,0)). Data-generation engine 122 may then input the rendered part 232 into the machine learning model and obtain predictions of one or more attributes 234 associated with the rendered part 232 as corresponding output of the machine learning model.

Input into the machine learning model also, or instead, includes additional information that can be used to determine attributes 234 for a given part 232. Continuing with the above example, data-generation engine 122 may also input, with the rendered part 232, one or more prompts that instruct the machine learning model to output attributes 234 based on the rendered part 232. Data-generation engine 122 may also, or instead, input a textual description of the rendered part 232 and/or additional context associated with the rendered part 232 to assist the machine learning model with determining attributes 234.

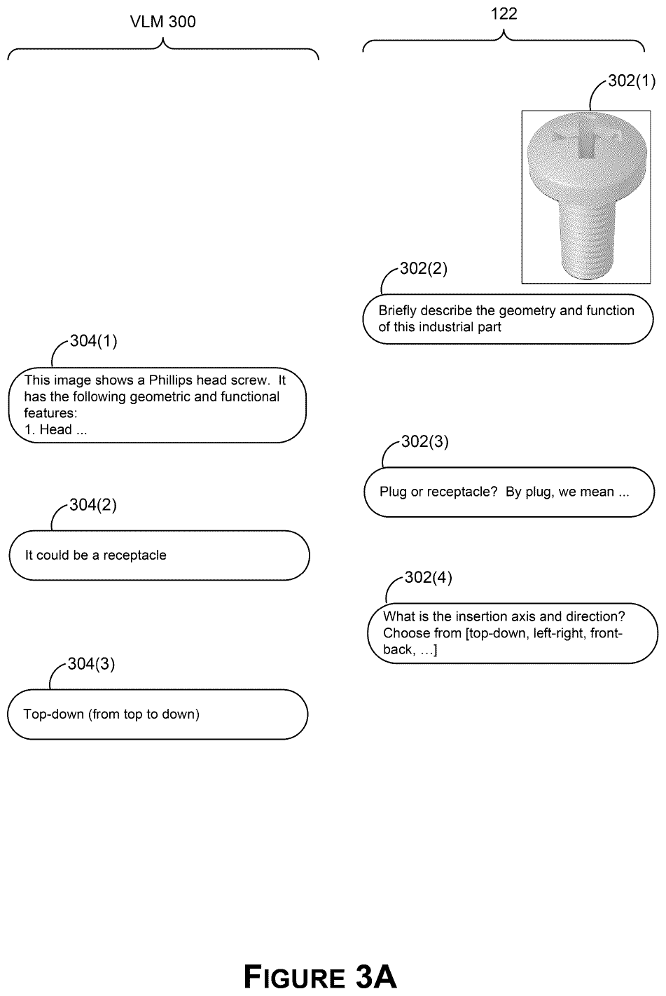

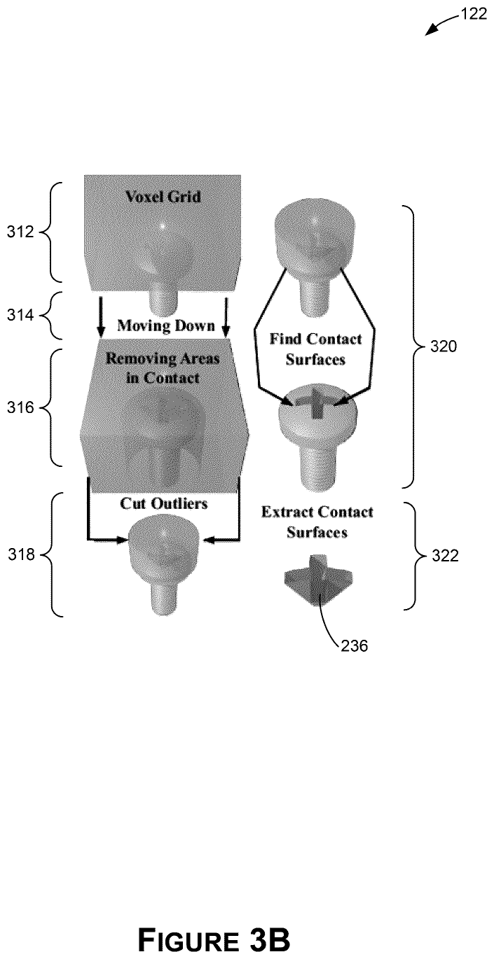

FIG. 3A illustrates how data-generation engine 122 of FIG. 1 determines attributes 234 associated with a part, according to at least one embodiment. As shown in FIG. 3A, data-generation engine 122 generates a series of inputs 302(1)-302(4) (each of which is referred to individually herein as input 302) into a VLM 300 and obtains a series of corresponding outputs 304(1)-304(3) (each of which is referred to individually herein as output 304) that include attributes 234 associated with a given part 232.

More specifically, data-generation engine 122 uses chain-of-thought prompting to guide VLM 300 in generating outputs 304 that specify different attributes 234 of part 232. During this chain-of-thought prompting, data-generation engine 122 generates a first input 302(1) that includes a rendering of a selected part 232, as well as a second input 302(2) that includes a prompt to describe the geometry and function of that part 232. Based on inputs 302(1)-302(2), VLM 300 generates a first output 304(1) that identifies part 232 as a Phillips head screw with certain geometric and functional features.

Next, data-generation engine 122 generates a third input 302(3) that asks VLM 300 to identify part 232 as a plug or receptacle and includes a definition of “plug” and “receptacle.” Based on this third input 302(3), VLM 300 generates a second output 304(2) that identifies part 232 as a receptacle.

Data-generation engine 122 then generates a fourth input 302(4) that asks VLM 300 to select an insertion axis and direction from a list. Based on this fourth input 302(4), VLM 300 generates a third output 304(3) that identifies the insertion axis and direction as “top-down.”

By iteratively prompting VLM 300 to recognize different attributes 234 of part 232, data-generation engine 122 may improve the quality and/or accuracy of the output attributes 234. For example, data-generation engine 122 may prompt VLM 300 to predict increasingly specific attributes of part 232, so that each predicted attribute can be included in a context that informs the prediction of subsequent attributes 234 for the same part 232.

Returning to the discussion of FIG. 2, after attributes 234 have been determined for a given part 232, data-generation engine 122 uses some or all attributes 234 to determine a set of contact surfaces 236 for the same part 232. In some embodiments, contact surfaces 236 include surfaces on part 232 that are predicted to come into contact with a corresponding paired part 238 during assembly. As described in further detail below with respect to FIG. 3B, data-generation engine 122 may use an analytical procedure that leverages the insertion axis and direction specified in attributes 234 to identify contact surfaces 236 for part 232.

FIG. 3B illustrates how data-generation engine 122 of FIG. 1 determines contact surfaces 236 associated with a part (e.g., the Phillips head screwdriver of FIG. 3A), according to at least one embodiment. As shown in FIG. 3B, data-generation engine 122 performs a first step 312 of generating a voxel grid above the part. For example, data-generation engine 122 may align the assembly direction of the part with a z-axis in a “top-down” orientation. Data-generation engine 122 may also initialize the voxel grid (e.g., of 512³ dimensions) above the aligned part.

Next, data-generation engine 122 performs a second step 314 of moving the voxel grid downward until the top layer of the voxel grid aligns with the top of the part. As the voxel grid is moved downward, data-generation engine 122 also performs a step 316 of removing grid cells that come in contact with the part. Data-generation engine 122 further performs a step 318 of removing “outlier” grid cells in the voxel grid that are not directly above the part.

Data-generation engine 122 then performs two steps 320 and 322 that use the remaining grid cells to find contact surfaces 236 on the part. In step 320, data-generation engine 122 removes additional grid cells that lie outside the convex hull of the part (e.g., when the part is identified to be a receptacle). In step 322, data-generation engine 122 iterates over the faces in the part to extract contact surfaces 236 as those that are fully in contact with the remaining portion of the voxel grid.

Returning to the discussion of FIG. 2, after contact surfaces 236 have been identified for a given part 232, data-generation engine 122 performs a second shape completion stage 214 to generate a corresponding paired part 238. In one or more embodiments, shape completion stage 214 uses contact surfaces 236 to condition the operation of a three-dimensional (3D) generative model in generating a shape for paired part 238 that is complementary to part 232. For example, data-generation engine 122 may perform shape completion stage 214 by using a transformer-based diffusion model to generate a 3D computer aided design (CAD) model within a unit box and in a Boundary Representation (B-rep) format, which includes a graph where geometric primitives (e.g., faces and edges) are represented by graph nodes and topological relationships between the geometric primitives are represented by graph edges. Data-generation engine 122 may initialize the denoising process performed by the diffusion model by moving contact surfaces 236 to the bottom of the unit box. During at least a portion of the time steps in the denoising process, data-generation engine 122 may replace a subset of face tokens processed by the diffusion model with contact surfaces 236. The denoising process may thus be used to complete a shape that includes contact surfaces 236.

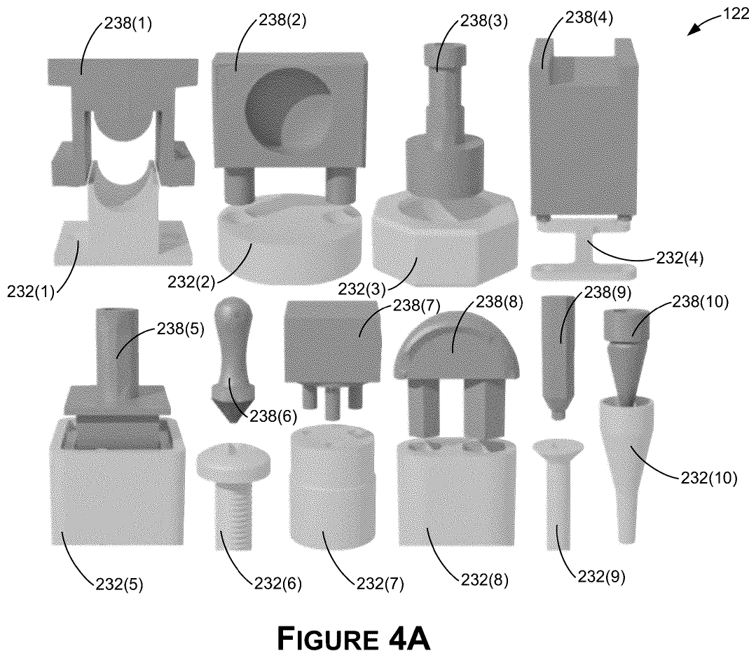

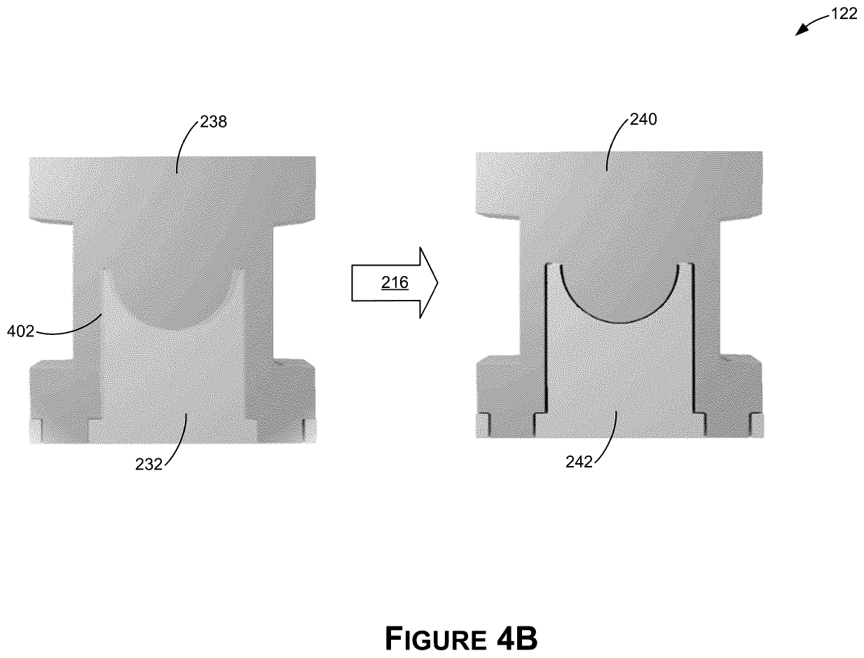

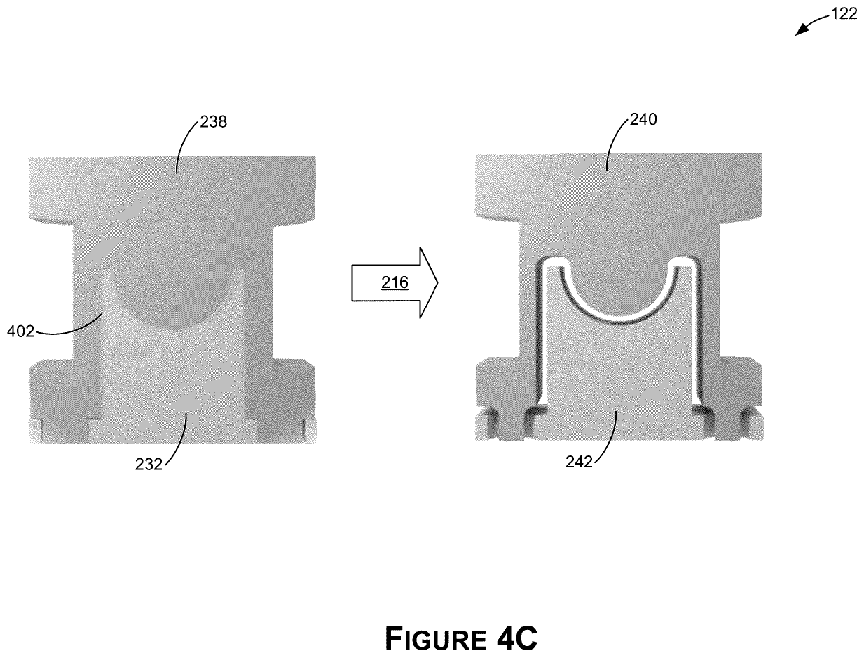

FIG. 4A illustrates an example set of parts 232(1)-232(10) and a corresponding set of paired parts 238(1)-238(10) generated by data-generation engine 122 of FIG. 1, according to at least one embodiment. As shown in FIG. 4A, the top of each part 232(1)-232(10) and the bottom of a corresponding paired part 238(1)-238(10) are complementary to one another and can be mated in a specific configuration (e.g., via insertion of the bottom of a given paired part 238(1)-238(10) into the top of a corresponding part 232(1)-232(10)). The geometries of the tops of paired parts 238(1)-238(10) may vary (e.g., based on the operation and/or output of one or more machine learning models used in shape completion stage 214), thereby allowing robots that perform assembly using parts 232 and paired parts 238 to be trained, tested, and/or evaluated on assembly tasks in a comprehensive manner.

Returning to the discussion of FIG. 2, data-generation engine 122 additionally performs a third clearance specification stage 216, in which a minimum clearance distance 244(1)-244(X) (each of which is referred to individually herein as clearance distance 244) between a given part 232 and a corresponding paired part 238 is enforced to ensure that each part 232 and corresponding paired part 238 can be successfully mated in a real-world and/or simulated environment. Each clearance distance 244 may be user-specified, set to a default value, determined by a machine learning model, set to a value based on standards and/or rules associated with a type and/or application of part 232 and/or paired part 238, and/or determined via another technique.

During clearance specification stage 216, data-generation engine 122 may convert a given part 232 and/or corresponding paired part 238 into an occupancy grid representation and initialize part 232 and the corresponding paired part 238 in an assembled state. Data-generation engine 122 may also remove grid cells in the occupancy grid that come into contact with or fall within clearance distance 244 of the other part until the minimum clearance distance 244 is met by all grid cells in that occupancy grid. Data-generation engine 122 may then convert the resulting “trimmed” occupancy grid into a mesh (e.g., via a marching cubes technique) or another 3D format for an updated part 242(1)-242(X) (each of which is referred to individually herein as updated part 242) corresponding to part 232 and/or an updated paired part 240(1)-240(X) (each of which is referred to individually herein as updated paired part 240) corresponding to paired part 238.

FIG. 4B illustrates how data-generation engine 122 of FIG. 1 performs clearance specification for a part 232 and a corresponding paired part 238, according to at least one embodiment. As shown in FIG. 4B, a region 402 between part 232 and paired part 238 includes portions of part 232 and paired part 238 that interpenetrate with one another, which can cause part 232 and paired part 238 to explode when loaded into a simulated environment and/or prevent part 232 and paired part 238 from mating in a real-world environment.

To resolve the interpenetration, data-generation engine 122 uses clearance specification stage 216 to remove portions of part 232 and/or paired part 238 that are within a one-millimeter clearance distance 244 of one another. Contact surfaces of the resulting updated part 242 and updated paired part 240 are separated by one another by at least one millimeter.

FIG. 4C illustrates how data-generation engine 122 of FIG. 1 performs clearance specification for part 232 and a corresponding paired part 238, according to at least one embodiment. Part 232 and paired part 238 of FIG. 4C are identical to those of FIG. 4B and interpenetrate within region 402.

To resolve the interpenetration, data-generation engine 122 uses clearance specification stage 216 to remove portions of part 232 and/or paired part 238 that are within a four-millimeter clearance distance 244 of one another. Contact surfaces of the resulting updated part 242 and updated paired part 240 are separated by one another by at least four millimeters.

Continuing with the discussion of FIG. 2, while the operation of data-generation engine 122 has been described with respect to the generation of paired assembly assets such as plugs and receptacles, it will be appreciated that data-generation engine 122 can be used to generate parts that can be included in other types of assemblies. For example, data-generation engine 122 may be configured to generate assemblies of more than two parts by including, in a given assembly, a first part with more than one plug, more than one receptacle, and/or at least one plug and one receptacle and generating more than one additional part that mates with the plug(s) and/or receptacle(s) in the first part. Data-generation engine 122 may also, or instead, form a plug and/or receptacle using more than one part and generate one or more additional parts that mate with the plug and/or receptacle. In another example, data-generation engine 122 may include functionality to generate other types of parts, such as (but not limited to) interlocking assemblies, puzzle pieces, gears, shafts, bearings, races, frames, panels, brackets, rails, hinges, clamps, couplings, hoses, clips, and/or rotating assemblies.

After shape characterization stage 212, shape completion stage 214, and clearance specification stage 216 are used to generate a given updated part 242 and corresponding updated paired part 240, data-generation engine 122 adds updated part 242 and updated paired part 240 to a set of training assemblies 204 included in training data 200 for one or more machine learning models. For example, data-generation engine 122 may add a given updated part 242 and corresponding updated paired part 240 to training assemblies 204 after verifying that the two parts can successfully be mated in a simulated and/or real-world environment.

Training engine 124 uses training data 200 and one or more training objectives 208 to update model parameters 206 of one or more machine learning models that implement a policy 220 for robotic assembly. As shown in FIG. 2, training data 200 includes training assemblies 204 generated by data-generation engine 122, as well as training trajectories 202 associated with training assemblies 204. Training trajectories 202 may include sequences of actions that are performed to assemble mated parts (e.g., updated parts 242 and updated paired parts 240 generated by data-generation engine 122) in training assemblies 204. For example, a given training trajectory may include a sequence of training actions for a given end effector of a robot over a certain number of time steps. Each action may include a set of positions, orientations, motor commands, and/or other output describing the configuration of joints, end effectors, and/or other portions of the articulated object for a certain “frame” or time step within a corresponding motion. A given training trajectory may also include and/or be associated with a set of training perceptions (e.g., states and/or observations) for each “frame” or time step. These training perceptions may include (but are not limited to) positions, angles, velocities, angular velocities, linear accelerations, contact forces, actions, and/or other representations of state for joints, end effectors, and/or other parts of the articulated object. These training perceptions may also, or instead, include (but are not limited to) camera views of the environment around the articulated object, visualizations that are generated by combining multiple camera views of the environment, semantic labels associated with the camera views and/or visualizations, 3D representations of the environment, and/or other information related to observations of the environment. Training actions and/or training perceptions in a given training trajectory may be generated by data-generation engine 122, training engine 124, and/or another component via assembly-by-disassembly, human demonstration via teleoperation systems, dataset aggregation, and/or other techniques.

Additionally, training engine 124 may use a variety of training techniques and/or corresponding training objectives 208 to update model parameters 206 using training data 200. For example, training engine 124 may use behavior cloning, dataset aggregation, trajectory matching, and/or other types of reinforcement learning (RL) and/or imitation learning techniques and corresponding training objectives 208 to update model parameters 206 of a multilayer perceptron (MLP), long short term memory (LSTM) neural network, recurrent neural network (RNN), RNN-Gaussian Mixture Model (RNN-GMM), diffusion policy 220, and/or another type of machine learning model corresponding to policy 220 based on training data 200 and one or more training objectives 208. During training of policy 220, training engine 124 initializes a simulated environment with an updated part 242 and a corresponding updated paired part 240 from training assemblies 204 in predefined and/or randomized poses. Training engine also inputs training perceptions associated with various time steps in training trajectories 202 into policy 220. Training engine 124 uses model parameters 206 of policy 220 to generate training output 210 that corresponds to actions for the same time step. Training engine 124 computes one or more training objectives 208 using the generated training output 210 and updates parameters of policy 220 in a way that optimizes training objectives 208.

After training of policy 220 is complete, execution engine 126 uses the trained policy 220 to perform various robotic assembly tasks. During a task, execution engine 126 inputs perception 224 for a given time step into policy 220 and uses policy 220 to generate a corresponding action distribution 218. Execution engine 126 samples a corresponding action 226 from action distribution 218 outputted by policy 220 and converts action 226 into a command and/or corresponding motion in the articulated object. Execution engine 126 repeats the process with a new perception 224 for the next time step until a certain number of time steps has elapsed, an overall target goal (e.g., completion of one or more assembly tasks) is achieved, and/or another predefined termination condition is met.

Execution engine 126 may additionally incorporate each generated action 226 into various applications. For example, execution engine 126 may simulate the articulated object performing robotic assembly within a game, video, virtual world, visualization, and/or another setting. Execution engine 126 may also, or instead, generate commands that cause a robot corresponding to the articulated object to perform each action 226 in a real-world environment.

While the operation of data-generation engine 122, training engine 124, and execution engine 126 has been described above with respect to generating paired assembly assets for use in training machine learning models, it will be appreciated that data-generation engine 122, training engine 124, and/or execution engine 126 may be used to perform other types of tasks. For example, data-generation engine 122 may use clearance specification stage 216 to repair assets and/or assemblies that include interpenetrating parts and/or otherwise cannot be used within a simulated and/or real-world environment. In another example, one or more updated parts 242 and corresponding updated paired parts 240 may be manufactured for assembly and/or use in a real-world environment by a robot, human, and/or another type of articulated object.

It should be understood that this and other arrangements described herein are set forth only as examples. Other arrangements, components, features, and elements (e.g., machines, interfaces, functions, orders, groupings of functions, etc.) may be used in addition to or instead of those shown, and some elements may be omitted altogether. Further, many of the arrangements, components, features, elements, etc. described herein are functional entities that may be implemented as discrete or distributed components or in conjunction with other components, and in any suitable combination and location (e.g., on a local device, vehicle, or machine at the edge, on-premises—such as locally hosted servers, remotely located—such as in one or more computing or server devices in one or more data centers in the cloud, and/or at other locations). Various functions described herein as being performed by entities may be carried out by hardware, firmware, and/or software. For instance, various functions may be carried out using one or more processors (e.g., central processing units (CPU(s)), graphics processing units (GPU(s)), microprocessors, microcontrollers, embedded processors, digital signal processors (DSPs), image signal processors (ISPs), physics processing units (PPUs), field-programmable gate arrays (FPGAs), accelerator(s) (e.g., deep learning accelerators (DLAs), deep learning accelerator cluster (XNNs), neural network accelerators (NNAs), and/or neural processing units (NPUs), programmable vision accelerators (PVAs), optical flow accelerators (OFAs), etc.), application specific integrated circuits (ASICs), data processing units (DPUs), quantum processors, etc.) executing instructions stored in memory. In some embodiments, the systems, methods, and processes described herein may be executed using similar components, features, and/or functionality to those of example machine 600 of FIGS. 6A-6E, example computing ecosystem 700 of FIG. 7, example generative language model system 800 of FIG. 8, and/or example computing device 900 of FIG. 9.

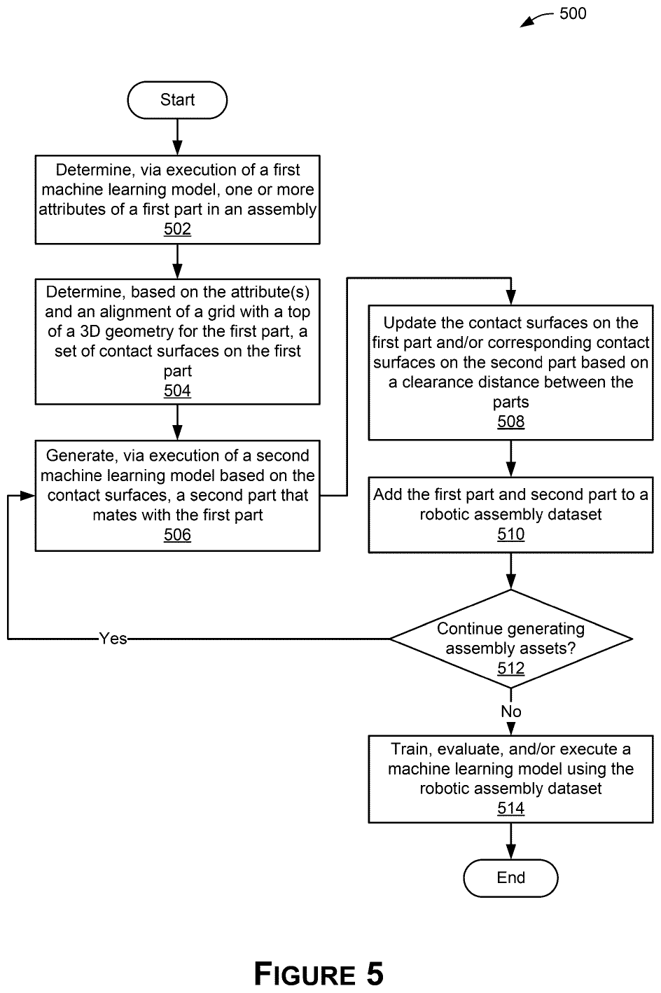

Now referring to FIG. 5, each block of method 500, described herein, comprises a computing process that may be performed using any combination of hardware, firmware, and/or software. For instance, various functions may be carried out using one or more processors (such as, but not limited to, those described herein) executing instructions stored in one or more memories or memory systems. In some embodiments, the computer processes may also be embodied as computer-usable instructions stored on computer storage media. The methods may be provided by a standalone application, a service or hosted service (standalone or in combination with another hosted service), an application programming interface (API) and/or a plug-in to another product, etc. In addition, method 500 is described, by way of example, with respect to the systems of FIGS. 1-2. However, these methods may additionally or alternatively be executed by any one system, or any combination of systems, including, but not limited to, those described herein.

FIG. 5 illustrates a flow diagram of a method 500 for generating data for robotic assembly, according to at least one embodiment. As shown in FIG. 5, method 500 begins with operation 502, in which data-generation engine 122 determines, via execution of a first machine learning model, one or more attributes of a first part in an assembly. For example, data-generation engine 122 may select the first part from a dataset, receive the first part from a user, and/or generate the first part. Data-generation engine 122 may also input a rendering and/or another visual representation of the first part and one or more instructions to describe the geometry, function, type (e.g., plug, receptacle, etc.), insertion axis, insertion direction, and/or other attributes of the first part into a VLM and/or another type of machine learning model. After a given instruction is received, the machine learning model may generate output that includes an answer to the instruction based on the visual representation of the first part and/or a context that includes previous interactions between data-generation engine 122 and the machine learning model.

In operation 504, data-generation engine 122 determines, based on the attribute(s) and an alignment of a grid with a top of a 3D geometry for the first part, a set of contact surfaces on the first part. For example, data-generation engine 122 may rotate the 3D geometry for the first part to assign the assembly direction identified in operation 502 with the z-axis in a top-down orientation. Data-generation engine 122 may also initialize a voxel grid above the rotated first part and lower the voxel grid until the top layer of the grid aligns with the top surface of the first part. Thus, data-generation engine 122 may “project” or “overlay” the voxel grid over the first part. As the voxel grid descends, data-generation engine 122 may remove grid cells that contact the first part. Data-generation engine 122 may also, or instead, remove grid cells that lie outside the convex hull of the first part (e.g., when the first part is identified as a receptacle). Data-generation engine 122 may then identify the contact surfaces as a set of faces in the first part that are fully in contact with the remaining grid cells in the voxel grid.

In operation 506, data-generation engine 122 generates, via execution of a second machine learning model based on the contact surfaces, a second part that mates with the first part. For example, data-generation engine 122 may use a diffusion model and/or another type of generative model to generate a 3D representation of the first part. Data-generation engine 122 may also condition the operation and/or output of the generative model on the contact surfaces (e.g., by replacing a portion of an output shape generated by the generative model and/or by a denoising step performed by the generative model with the contact surfaces).

In operation 508, data-generation engine 122 updates the contact surfaces on the first part and/or corresponding contact surfaces on the second part based on a clearance distance between the parts. For example, data-generation engine 122 may convert a given part into an occupancy grid representation and remove grid cells of the occupancy grid along the assembly axis of the occupancy grid until all grid cells in the occupancy grid are at least a minimum “clearance distance” from the other part. Data-generation engine 122 may then convert the occupancy grid into a triangular mesh and/or another “final” representation of the part.

In operation 510, data-generation engine 122 adds the first part and second part to a robotic assembly dataset. For example, data-generation engine 122 may add the parts to the robotic assembly dataset after verifying that the parts can be mated in a simulated and/or real-world environment.

In operation 512, data-generation engine 122 determines whether to continue generating assembly assets. For example, data-generation engine 122 may determine that generation of assembly assets is to continue until a certain number of assemblies and/or assembly assets has been generated, a certain number of a type of assembly and/or assembly asset has been generated, and/or another condition is met. While data-generation engine 122 determines that generation of assembly assets is to continue, data-generation engine 122 repeats operations 502, 504, 506, 508, and 510 to generate additional paired assembly assets that mate with one another.

After data-generation engine 122 determines that generation of assembly assets is no longer to be continued (or while data-generation engine 122 continues generating assembly assets), training engine 124 and/or execution engine 126 perform operation 514, in which training engine 124 and/or execution engine 126 train, evaluate, and/or execute a machine learning model using the robotic assembly dataset. For example, training engine 124 may train a generalist and/or specialist policy for robotic assembly using paired parts in the robotic assembly dataset. In another example, execution engine 126 may evaluate the performance of a robotic assembly policy and/or robot on various assembly tasks involving parts in the robotic assembly dataset. In a third example, execution engine 126 may use a robotic assembly policy and/or robot to assemble assets in the robotic assembly dataset in a simulated and/or real-world environment.

In sum, the disclosed techniques automate the generation of paired parts (also referred to herein as components) in assemblies via a three-stage pipeline. The pipeline includes a first contact surface extraction stage, in which a set of contact surfaces is extracted from a first part by a vision language model (VLM) and/or another type of machine learning model based on a visual and/or another representation of the first part. The pipeline also includes a second shape completion stage, in which the contact surfaces are used to condition the operation of a diffusion model and/or another type of three-dimensional (3D) generative model in generating a shape for a second part that is complementary to the first part. The pipeline further includes a third clearance specification stage, in which the shape of a given part is updated to meet a minimum clearance distance from the other part. Paired parts generated via the pipeline can then be used to train a policy on assembly tasks in a simulated environment, evaluate the performance of a deployed policy in a real-world environment, used in real-world assembly tasks, and/or used to perform other tasks related to assembly.

One advantage of the disclosed techniques relative to prior approaches is the ability to automatically generate a large and diverse set of paired parts that can be used in assembly tasks. Consequently, the disclosed techniques can be used to generate assembly asset pairs more quickly and efficiently than conventional approaches that involve manual generation and/or curation of robotic assembly datasets. The generated asset pairs can also be used to train, test, and/or evaluate robots on assembly tasks in a more comprehensive manner than robots that are trained using a much smaller and/or less diverse set of assemblies. Further, robots that are trained using the generated asset pairs may be more fault tolerant and/or capable of generalizing to different scenarios than robots that are trained using a more limited set of paired components. Additionally, the disclosed techniques can be used to “repair” interpenetrating assets generated via other techniques, thereby further increasing the number and types of assets that can be used in assembly tasks.

The systems and methods described herein may be used by, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms, warehouse vehicles, off-road vehicles, vehicles coupled to one or more trailers, flying vessels, watercraft, shuttles (e.g., robotaxis), emergency response vehicles, motorcycles, electric or motorized bicycles, aircraft, construction vehicles, underwater craft (e.g., piloted or unpiloted submarines), drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets (e.g., NVIDIA's Omniverse), cloud computing, and/or any other suitable applications.

Disclosed embodiments may be comprised in a variety of different systems such as automotive systems (e.g., a control system for an autonomous or semi-autonomous machine, a perception system for an autonomous or semi-autonomous machine, etc.), systems implemented using a robot, aerial systems, medial systems, boating systems, smart area monitoring systems, systems for performing deep learning operations, systems for performing simulation operations, systems for performing digital twin operations, systems implemented using an edge device, systems implementing language models—such as large language models (LLMs), vision language models (VLMs), and/or multi-modal language models, systems using or deploying one or more inference microservices, systems that incorporate deploy one or more machine learning models in a service or microservice along with an OS-level virtualization package (e.g., a container), systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems for performing generative AI operations, systems implemented at least partially using cloud computing resources, and/or other types of systems.

### Example Autonomous or Semi-Autonomous Machine

FIG. 6A is an example of sensor locations having corresponding fields of view or sensory fields for an autonomous or semi-autonomous vehicle 600a, an autonomous mobile robot (AMR) 600b, and a humanoid robot 600c, in accordance with some embodiments of the present disclosure. Although three types of machines 600 are illustrated, this is not intended to be limiting, and the machine(s) 600 described herein may include a vehicle, a car, a truck, a bus, a first responder vehicle, a shuttle, an electric or motorized bicycle, a motorcycle, a fire truck, a police or emergency vehicle, an ambulance, a watercraft, a construction vehicle, an underwater craft, a robot (e.g., AMR, humanoid, robotic arm, end-effector, forklift, etc.), a drone, an aircraft, a vehicle coupled to a trailer (e.g., a semi-tractor-trailer truck used for hauling cargo), and/or another type of vehicle or machine (e.g., that is unmanned and/or that accommodates one or more passengers). The vehicle 600a, AMR 600b, humanoid robot 600c, and/or other machine types may be referred to herein collectively as machine 600, in some instances.

With respect to vehicles 600A, autonomous and semi-autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The machine 600 may be capable of functionality in accordance with one or more of Level 3-Level 5 of the autonomous driving levels. The machine 600 may be capable of functionality in accordance with one or more of Level 1-Level 5 of the autonomous driving levels. For example, the machine 600 may be capable of driver assistance (Level 1), partial automation (Level 2, Level 2+, Level 2++), conditional automation (Level 3), high automation (Level 4), and/or full automation (Level 5), depending on the embodiment. The term “autonomous,” as used herein, may include any and/or all types of autonomy for the machine 600 or other machine, such as being fully autonomous, being highly autonomous, being conditionally autonomous, being partially autonomous, providing assistive autonomy, being semi-autonomous, being primarily autonomous, or other designation.

With respect to FIG. 6A, the sensors and their respective fields of view (not illustrated for clarity purposes) or sensory fields (not illustrated for clarity purposes) are one example embodiment and are not intended to be limiting. Although not illustrated, each sensor may have a corresponding field of view (e.g., a 360 degree field of view of a surround camera 668D, a 180 degree field of view of a wide view camera 668B, a 360 degree sensory field of a LiDAR sensor 664, etc.). For example, only a subset of the sensors illustrated may be included, additional sensors may be included, alternative sensors may be included, the number of each sensor modality may differ, the sensor modalities may differ (e.g., may not include LiDAR or RADAR, may include SONAR, thermal sensors, etc.), the sensor locations may be different from those illustrated on the vehicle 600a, AMR 600b, and/or humanoid robot 600c, etc. For example, with respect to the vehicle 600a, depending on the type (e.g., SUV, truck, sedan, robot, motorcycle, etc.), size (e.g., 18-wheeler, moving van, small sedan, etc.), and related functionality (e.g., L2 vs. L5), the locations, numbers, modalities, and/or other sensor information may differ. Similarly, for the AMR 600b and/or humanoid robot 600c, the shape, size, purpose, implementation, model, etc. may dictate the number and types of sensors used.

As illustrated in FIG. 6A, the autonomous or semi-autonomous vehicle 600A, the AMR 600B, and the humanoid robot 600C may include different sensor types, number, and locations. For a non-limiting example, the vehicle 600A may include twelve cameras 668, such as a front wide camera (e.g., 120 degree field of view (FOV)), a front telephoto camera (e.g., 30 degree FOV), a side rear left camera (e.g., 70 degree FOV), a side rear right camera (e.g., 70 degree FOV), a front fisheye camera (e.g., 200 degree FOV), a rear fisheye camera (e.g., 200 degree FOV), a left fisheye camera (e.g., 200 degree FOV), a right fisheye camera (e.g., 200 degree FOV), a front telephoto satellite camera (e.g., 30 degree FOV), a rear telephoto camera (e.g., 30 degree FOV), a cross left camera (e.g., 120 degree FOV), and a cross right camera (e.g., 120 degree FOV). The camera(s) 668 may use, in embodiments, a gigabit multimedia serial link (GMSL) interface—such as GMSL2—as input/output (I/O).

In some embodiments, although not illustrated in FIG. 6A, the vehicle 600A may include an in-cabin occupant and/or driver monitoring system, that may include various different sensors. For example, the in-cabin sensors may include various cameras 668, such as a driver monitoring camera (e.g., 55 degree FOV positioned forward of and facing toward the driver seat), a front occupant monitoring camera (e.g., 190 degree FOV positioned forward of and facing the front occupant(s) seat(s)), and a rear occupant monitoring camera (e.g., 190 degrees positioned forward of and facing the rear occupant(s) seat(s)). Similar to the external facing camera(s) 668, the internal camera(s) 668 may, in embodiments, use a GMSL (such as GMSL2) interface for I/O.

As another non-limiting example, the vehicle 600A may further include nine RADAR sensors 660. For example, the vehicle 600A may include a front center imaging RADAR sensor (e.g., 120 degree FOV or sensory field), a corner front left RADAR sensor (e.g., 160 degree FOV or sensory field), a corner front right RADAR sensor (e.g., 160 degree FOV or sensory field), a corner rear right RADAR sensor (e.g., 160 degree FOV or sensory field), a side left RADAR sensor (e.g., 160 degree FOV or sensory field), a side right RADAR sensor (e.g., 160 degree FOV or sensory field), a rear left RADAR sensor (e.g., 50 degree FOV or sensory field), and rear right RADAR sensor (e.g., 50 degree FOV or sensory field). The RADAR sensor(s) 660 may use, in embodiments, an Ethernet interface as I/O.

The vehicle(s) 600A may further include, as a non-limiting example, twelve ultrasonic sensors 662. As illustrated in FIG. 6A, the ultrasonic sensors may be positioned along the front and rear bumpers of the vehicle 600A, and along the side of the vehicle 600A, and may be used to detect objects (static and dynamic) in close proximity to the vehicle 600A. In some embodiments, the ultrasonic sensor(s) 662 may use a DS13 interface as I/O.

The vehicle(s) 600A may further include, as a non-limiting example, a LiDAR sensor 664, such as a front center LiDAR sensor (e.g., 120 degree horizontal FOV or sensory field and 30 degree vertical FOV or sensor field). In some embodiments, such as where additional or alternative LiDAR sensors are used, the LiDAR sensor may have differing horizontal and vertical fields of view or sensory fields. For example, a LiDAR sensor 664 may include a 360 degree horizontal FOV or sensory field (such as in a spinning LiDAR sensor) and a 90 degree vertical FOV or sensory field. In some embodiment, the LiDAR sensor(s) 664 may use an Ethernet interface as I/O.

The autonomous mobile robot (AMR) 600B may include, as a non-limiting example, three LiDAR sensors 664. For example, the top-most illustrated LiDAR sensor 664 may include a beam or 3D LiDAR sensor (e.g., 360 degree horizontal and 90 degree vertical FOV or sensory field), and the front and rear LiDAR sensors may include planar or 2D LiDAR sensors (e.g., 180 degree horizontal FOV or sensory field).

The AMR 600B may further include, as a non-limiting embodiment, eight cameras 668, such as a front stereo camera (e.g., 120 degree FOV), a rear stereo camera (e.g., 120 degree FOV), a left stereo camera (e.g., 120 degree FOV), a right stereo camera (e.g., 120 degree FOV), a front fisheye camera (e.g., 202 degree+−3 degree FOV), a rear fisheye camera (e.g., 202 degree+−3 degree FOV), a left fisheye camera (e.g., 202 degree+−3 degree FOV), and a right fisheye camera (e.g., 202 degree+−3 degree FOV).

The AMR 600B may further include a charging port, charging port contacts, a status indicator light, one or more (e.g., four) RGB LEDs, one or more IMU sensors 666, a magnetometer, and a barometer. The AMR 600B is capable of high-precision time synchronization between sensors using hardware time stamping, and PTP over Ethernet with less than 10 microseconds for sensor acquisition time. The AMR 600B provides simultaneous camera capture across all cameras 668 within 100 microseconds from a single hardware trigger, in embodiments, and can write to disk at 4 GB/second for sensor capture to bag writing (e.g., writing to ROSbags for the robot operation system (ROS)). As such, the AMR 600B is capable of running the ROS (such as NVIDIA's Isaac ROS), can be teleoperated (as described herein), can map an environment, and can navigate within an environment using visual cameras 668, LiDAR sensors 664, and/or other sensor types or modalities.

The humanoid robot 600C may include, as a non-limiting example, one LiDAR sensor 664. For example, the LiDAR sensor 664 may include a beam or 3D LiDAR sensor (e.g., 360 degree horizontal and 90 degree vertical FOV or sensory field), or may include a planar or 2D LiDAR sensor (e.g., 180 degree horizontal FOV or sensory field).

The humanoid robot 600C may further include, as a non-limiting embodiment, four cameras 668, such as a front stereo camera (e.g., 120 degree FOV), a rear stereo camera (e.g., 120 degree FOV), a front fisheye camera (e.g., 202 degree+−3 degree FOV), and a rear fisheye camera (e.g., 202 degree+−3 degree FOV).

The humanoid robot 600C may further include, as a non-limiting embodiment, four ultrasonic sensors 662, such as a left arm ultrasonic sensor, a right arm ultrasonic sensor, a left leg ultrasonic sensor, and right leg ultrasonic sensor.

The humanoid robot 600C may further include any number of actuators—such as to allow control and maneuverability of joints. For example, the humanoid robot 600C may include actuators that allow for various degrees of freedom (DoF) depending on the design. In a non-limiting embodiment, the humanoid robot 600C may have 40 total degrees of freedom (DoF) (e.g., 6 DoF×2 for the arms, 6 DoF×2 for the hands, 6 DoF×2 for the legs, 2 DoF for the torso, and 2 DoF for the neck). The actuators may convert energy into physical motion, allowing for actions such as joint movements, locomotion, and gripping/manipulation. For example, joint movements may be performed using motors and servos to control the rotation of joints in an arm or manipulator, and to allow for reaching, grabbing, and manipulating objects. Locomotion may be accomplished using wheels, tracks, or other locomotion devices (robotic legs) to move around the environment. Gripping and manipulation may be performed using end-effectors or hands/fingers, which may be equipped with actuators to grip objects, apply force, and perform specific tasks. In some examples, the humanoid robot 600C may include position and orientation sensors, such as encoders, gyroscopes, and the like, to determine the position of the robot 600C in space, allowing for location determination and movement tracking. The humanoid robot 600C may include force and pressure sensors, in embodiments, to detect environment interactions, allowing the robot 600C to grasp objects with the right force and to avoid obstacles along the way. The perception sensors (e.g., cameras, LiDARs, RADARs, ultrasonic, SONAR, etc.) may be used along with tactile sensors to allow the robot 600C to perceive objects, shapes, and textures, and to understand when touch is initiated and stopped (along with force sensors that regulate the force used during touch). As a non-limiting example, the humanoid robot 600C may have a height of about 1-2 meters (e.g., 1.7 meters or 5′ 6″), a weight of 50-70 kg, be capable of moving at a speed of 8 or more km/h, and be able to carry payloads anywhere from 20-100 kg, depending on the design and requirements of the system.

The humanoid robot 600C, in embodiments, may include a conversational system—such as a conversational system powered by language models (e.g., LLMs, VLMs, MMLMs, VLAs, etc.)—in order to help understand the environment, reason, and communicate with humans, animals, devices, and/or other robots, and/or make planning, control, and navigation decisions. As such, in addition to performing various tasks, the humanoid robot 600C may use onboard sensors, microphones, and speakers to understanding speech, audio and visual cues, etc., while also being able to communicate back to the environment.

With reference to cameras 668 of the machine(s) 600, the camera types for the cameras 668 may include, but are not limited to, digital cameras that may be adapted for use with the components and/or systems of the machine 600. For a vehicle 600a implementation, the camera(s) 668 may operate at automotive safety integrity level (ASIL) B and/or at another ASIL. The camera types may be capable of any image capture rate, such as 30 frames per second (fps), 60 fps, 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

Cameras with a field of view that include portions of the environment in front of the machine 600 (e.g., front-facing cameras) may be used for surround view, to help identify forward facing paths and obstacles, as well aid in, with the help of one or more controllers 636 and/or control SoCs, providing information critical to generating an occupancy grid and/or determining the preferred machine movements, trajectories, and/or paths. Front-facing cameras may be used to perform many of the same ADAS functions as LiDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 668B that may be used to perceive objects coming into view from the periphery (e.g., pedestrians, warehouse vehicles, other robots, crossing traffic, or bicycles). In addition, any number of long-range camera(s) 668E (e.g., a long-view stereo camera pair) may be used for depth-based object detection, especially for objects for which a neural network has not yet been trained. The long-range camera(s) 668E may also be used for object detection and classification, as well as basic object tracking.

Any number of stereo cameras 668A may also be included in a front-facing and/or other (e.g., rear-facing) configuration. In at least one embodiment, one or more of stereo camera(s) 668A may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the machine's 600 environment, including a distance estimate for points in the image (e.g., a disparity or depth image). An alternative stereo camera(s) 668A may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 668A may be used in addition to, or alternatively from, those described herein. For example, in some embodiments, stereo depth estimation may be performed using other than stereo cameras, such as two monocular cameras having at least partially overlapping fields of view.

Cameras with a field of view that include portions of the environment to the side of the machine 600 (e.g., side-view cameras) may be used, for example, for surround view, providing information used to create and update the occupancy grid, as well as to generate side impact collision warnings and/or to indicate to an AMR 600B or humanoid robot 600C, for example, that there are objects, features, and/or persons present to the side. For example, surround camera(s) 668D may be positioned on the machine 600. The surround camera(s) 668D may include wide-view camera(s) 668B, fisheye camera(s), 360 degree camera(s), and/or the like. For example, four fisheye cameras may be positioned on the machine's 600 front, rear, and sides. In an alternative arrangement, the machine 600 may use three surround camera(s) 668D (e.g., left, right, and rear), and may leverage one or more other camera(s) (e.g., a forward-facing camera) as a fourth surround view camera.

Cameras 668 with a field of view that include portions of the environment to the rear of the machine 600 (e.g., rear-view cameras) may be used for gaining an understanding of objects, features, persons, and/or other information to the rear of the machine 600, such as for park assistance, surround view, rear collision warnings, planning, control, and navigation determinations, and/or creating and updating an occupancy grid, BEV image representing the environment, height map, etc. A wide variety of cameras 668 may be used including, but not limited to, cameras 668 that are also suitable as a front-facing camera(s) (e.g., long-range and/or mid-range camera(s) 668E, stereo camera(s) 668A), infrared camera(s) 668C, etc.), rear-facing camera(s), side-facing camera(s), downward facing camera(s), upward facing camera(s), and/or the like, as described herein.

Similarly, for LiDAR sensors 664, RADAR sensors 660, ultrasonic sensors 662, and/or other sensor modalities or types, the location and placement of the sensors, and their corresponding fields of view or sensory fields may be determined based on the use case, implementation, or design of the particular machine 600.

For example, the machine(s) 600 include RADAR sensor(s) 660 that may be used by the machine 600 for long-range object detection, even in darkness and/or severe weather conditions. RADAR functional safety levels may be ASIL B, in embodiments. The RADAR sensor(s) 660 may use the CAN and/or the bus 602 (e.g., to transmit data generated by the RADAR sensor(s) 660) for control and to access object tracking data, with access to Ethernet to access raw data in some examples. A wide variety of RADAR sensor types may be used. For example, and without limitation, the RADAR sensor(s) 660 may be suitable for front, rear, and side RADAR use. In some example, Pulse Doppler RADAR sensor(s) are used.

The RADAR sensor(s) 660 may include different configurations, such as long range with narrow field of view, short range with wide field of view, short range side coverage, etc. In some examples, long-range RADAR may be used for adaptive cruise control (ACC) functionality. The long-range RADAR systems may provide a broad field of view realized by two or more independent scans, such as within a 250 m range. The RADAR sensor(s) 660 may help in distinguishing between static and moving objects, and may be used by ADAS systems for emergency brake assist and forward collision warning, by robots for detecting dynamic objects in various environments—such as those with lower or no lighting. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the machine's 600 surroundings at higher speeds with minimal interference from the periphery (e.g., from traffic in adjacent lanes). The other two antennae may expand the field of view, making it possible to quickly detect objects entering or leaving the machine's immediate path (e.g., lane).

Mid-range RADAR systems may include, as an example, a range of up to 660 m (front) or 80 m (rear), and a field of view of up to 42 degrees (front) or 150 degrees (rear). Short-range RADAR systems may include, without limitation, RADAR sensors designed to be installed at both ends of a lateral surface (e.g., a rear bumper) such that two beams may be used to constantly monitor the blind spot in the rear and next to the machine 600 (e.g., vehicle, robot, etc.). As such, short-range RADAR systems may be used in an ADAS system for blind spot detection and/or lane change assist.

The machine 600 may further include ultrasonic sensor(s) 662. The ultrasonic sensor(s) 662, which may be positioned at the front, back, and/or the sides of the machine 600, may be used for assisting with near-field perception, such as for park assist, collision avoidance (e.g., for robotic parts), and/or to create and update an occupancy grid, evidence grid map (EGM), height map, BEV image, and/or other representation of objects and features in an environment of the machine 600. A wide variety of ultrasonic sensor(s) 662 may be used, and different ultrasonic sensor(s) 662 may be used for different ranges of detection (e.g., 2.5 m, 4 m). The ultrasonic sensor(s) 662 may operate at functional safety levels of ASIL B, as an example.

The machine 600 may include LiDAR sensor(s) 664. The LiDAR sensor(s) 664 may be used for object and feature detection, pedestrian and other robot detection, emergency braking, collision avoidance, simultaneous localization and mapping (SLAM), free-space detection, and/or other functions. The LiDAR sensor(s) 664 may be functional safety level ASIL B, in embodiments. In some examples, the machine 600 may include multiple LiDAR sensors 664 (e.g., two, four, six, etc.) that may use Ethernet (e.g., to provide data to a Gigabit Ethernet switch).

In some examples, the LiDAR sensor(s) 664 may be capable of providing a list of objects and their distances for a 360-degree field of view. Commercially available LiDAR sensor(s) 664 may have an advertised range of approximately 600 m, with an accuracy of 2 cm-3 cm, and with support for a 600 Mbps Ethernet connection, for example. In some examples, one or more non-protruding LiDAR sensors 664 may be used. In such examples, the LiDAR sensor(s) 664 may be implemented as a small device that may be embedded into the front, rear, sides, top, and/or corners of the machine 600. The LiDAR sensor(s) 664, in such examples, may provide up to a 120-degree horizontal and 35-degree vertical field-of-view, with a 200 m range even for low-reflectivity objects. Front-mounted LiDAR sensor(s) 664 may be configured for a horizontal field of view between 45 degrees and 135 degrees.

In some examples, LiDAR technologies, such as 3D flash LiDAR, may also be used. 3D Flash LiDAR uses a flash of a laser as a transmission source, to illuminate vehicle surroundings up to approximately 200 m. A flash LiDAR unit includes a receptor, which records the laser pulse transit time and the reflected light on each pixel, which in turn corresponds to the range from the vehicle to the objects. Flash LiDAR may allow for highly accurate and distortion-free images of the surroundings to be generated with every laser flash. In some examples, four flash LiDAR sensors may be deployed, one at each side of the machine 600. Available 3D flash LiDAR systems include a solid-state 3D staring array LiDAR camera with no moving parts other than a fan (e.g., a non-scanning LiDAR device). The flash LiDAR device may use a 5 nanosecond class I (eye-safe) laser pulse per frame and may capture the reflected laser light in the form of 3D range point clouds and co-registered intensity data. By using flash LiDAR, and because flash LiDAR is a solid-state device with no moving parts, the LiDAR sensor(s) 664 may be less susceptible to motion blur, vibration, and/or shock.

FIG. 6B is an illustration of sensor and component locations of an example autonomous or semi-autonomous vehicle 600A (alternatively referred to herein as “vehicle 600,” “ego-vehicle 600,” “ego-machine 600,” or “machine 600,”), in accordance with some embodiments of the present disclosure. Although the vehicle 600A is illustrated, this is not intended to be limiting, and similar components and/or sensors may be included on any other machine type without departing from the scope of the present disclosure. For example, similar sensors and/or components may be used for a vehicle, a car, a truck, a bus, a first responder vehicle, a shuttle, an electric or motorized bicycle, a motorcycle, a fire truck, a police vehicle, an ambulance, a watercraft, a construction vehicle, an underwater craft, a robot (e.g., AMR, humanoid, robotic arm, end-effector, forklift, etc.), a drone, an aircraft, a vehicle coupled to a trailer (e.g., a semi-tractor-trailer truck used for hauling cargo), and/or another type of vehicle or machine (e.g., that is unmanned and/or that accommodates one or more passengers).

FIG. 6C is a block diagram of an example system architecture for a machine 600, such as autonomous or semi-autonomous vehicle 600A, autonomous mobile robot (AMR) 600B, humanoid robot 600C, and/or other types of machines, in accordance with some embodiments of the present disclosure. It should be understood that this and other arrangements described herein are set forth only as examples. Other arrangements, components, features, and elements (e.g., machines, interfaces, functions, orders, groupings of functions, etc.) may be used in addition to or instead of those shown, and some elements may be omitted altogether. Further, many of the arrangements, components, features, elements, etc. described herein are functional entities that may be implemented as discrete or distributed components or in conjunction with other components, and in any suitable combination and location (e.g., on a local device, vehicle, or machine at the edge, on-premises—such as locally hosted servers, remotely located—such as in one or more computing or server devices in one or more data centers in the cloud, and/or at other locations). Various functions described herein as being performed by entities may be carried out by hardware, firmware, and/or software. For instance, various functions may be carried out using one or more processors (e.g., central processing units (CPU(s)), graphics processing units (GPU(s)), microprocessors, microcontrollers, embedded processors, digital signal processors (DSPs), image signal processors (ISPs), physics processing units (PPUs), field-programmable gate arrays (FPGAs), accelerator(s) (e.g., deep learning accelerators (DLAs, deep learning accelerator cluster (XNNs), neural network accelerators (NNAs), and/or neural processing units (NPUs), programmable vision accelerators (PVAs), optical flow accelerators (OFAs), etc.), application-specific integrated circuits (ASICs), data processing units (DPUs), quantum processors, etc.) executing instructions stored in memory. In some embodiments, the systems, methods, and processes described herein may be executed using similar components, features, and/or functionality to those of example machine 600 of FIGS. 6A-6E, example computing ecosystem 700 of FIG. 7, example generative language model system 800 of FIG. 8, and/or example computing device 900 of FIG. 9.

Each of the components, features, and systems of the machine 600 in FIG. 6C are illustrated as being connected via bus 602 (alternatively referred to as a “machine communications network 602,” or just “communications network 602”). The bus 602 may include a Controller Area Network (CAN) data interface (alternatively referred to herein as a “CAN bus”). A CAN may be a network inside the machine 600 used to aid in control of various features and functionality of the machine 600, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant. In some embodiments, in addition to or alternatively from a CAN bus, the bus 602 may include FlexRay, an embedded bus (e.g., SPI, I2C), local interconnect link (LIN), NVIDIA's NVLink, USB (2.0, 3.0, onward), radio frequency (RF), Ethernet (e.g., 10BASE/100BASE, 1000BASE, 10G, etc.), and/or another communication protocol or functionality. Additionally, although a single line is used to represent the bus 602, this is not intended to be limiting. For example, there may be any number of busses 602, which may include one or more CAN busses, one or more FlexRay busses, one or more Ethernet busses, and/or one or more other types of busses using a different protocol. In some examples, two or more busses 602 may be used to perform different functions, and/or may be used for redundancy. For example, a first bus 602 may be used for collision avoidance functionality and a second bus 602 may be used for actuation control. In any example, each bus 602 may communicate with any of the components of the machine 600, and two or more busses 602 may communicate with the same components. In some examples, each SoC 604, each controller 636, and/or each computer or compute engine within the machine 600 may have access to the same input data (e.g., inputs from sensors of the machine 600), and may be connected to a common bus, such as a CAN bus.

The machine 600 may include components such as a chassis, a vehicle body, wheels (e.g., 2, 4, 6, 8, 18, etc.), tires, axles, batteries, side-view mirrors, and/or other components of a vehicle or machine. The machine 600 may include a propulsion system 650, such as an internal combustion engine, hybrid electric power plant, an all-electric engine, a hydrogen-fueled engine, and/or another propulsion system type. The propulsion system 650 may be connected to a drive train of the machine 600, which may include a transmission, to enable the propulsion of the machine 600. The propulsion system 650 may be controlled in response to receiving signals from the throttle/accelerator 652.

A steering system 654, which may include a steering wheel and/or other steering device (e.g., remote steering and/or local steering), may be used to steer the machine 600 (e.g., along a desired path or route) when the propulsion system 650 is operating (e.g., when the vehicle is in motion). The steering system 654 may receive signals from a steering actuator 656. In some embodiments, a steering wheel or other steering mechanism may not be included, such as for a machine 600 capable of full automation (e.g., Level 5) functionality.

The brake sensor system 646 may be used to operate the vehicle brakes in response to receiving signals from the brake actuators 648 and/or brake sensors.

The machine 600 may include one or more controller(s) 636, such as those described herein with respect to FIG. 6A. The controller(s) 636 may be used for a variety of functions, and may be coupled to any of the various other components and systems of the machine 600. For example, the controllers 636 may be used for control of the machine 600, artificial intelligence executing on the machine 600, infotainment for the machine 600, and/or the like. For example, one controller 636 may be used for some or all of the functionality, or different controllers 636 may be used for different functionalities—e.g., to ensure availability and a safety separation between various controllers for different tasks. For example, the controller(s) 636 may use plans computed by the system—e.g., paths or trajectories for vehicles 600A or AMRs 600B, or movements, components trajectories, movement locations or displacements, etc. for joints or components (e.g., of manipulators, end effectors, limbs, hands, fingers, legs, feet, etc.), of a humanoid robot 600C—to control the machine(s) 600 in the environment. In some instances, the controller(s) 636 may include a proportional-integral-derivative (PID) controller, a fuzzy logic controller, a neural controller (e.g., a controller embodied as one or more neural networks), a force control controller, a programmable logic controller (PLC), and/or another type of controller. In a humanoid robot 600C, for example, the controller(s) 636 may act as the brain, responsible for analyzing sensor data, making decisions, and sending commands to the actuators. The controller(s) 636 may include a low-level controller that handles basic motor control, ensuring accurate and precise movements of individual joints and actuators. The controller(s) 636 may include a high-level controller to coordinate multiple actuators and sensors, planning complex motions and adapting to changing environments.

The controller(s) 636 may include an artificial intelligence controller, in embodiments, that may use AI algorithms (e.g., DNNs, MLMs, etc.) to learn, make decisions, and autonomously perform tasks for the machine 600. In some embodiments, the controller(s) 636 may use an open-loop control algorithm that is fixed and does not adjust actions to the environment. In other embodiments, closed-loop control may be used that incorporates feedback mechanisms to monitor the robot's performance and make necessary adjustments. In examples, the controller(s) 636 may implement reactive control in order to respond directly to sensory inputs, allowing for quick reflexes and real-time changes. Further, deliberative control may be implemented in some examples, using internal models and planning algorithms to generate high-level actions, which may be suited for complex tasks that require reasoning, decision making, and long-term planning.

Controller(s) 636, which may include one or more systems on chip (SoCs) 604 (FIGS. 6C and 6D), CPUs, GPU(s), accelerator(s), etc., may provide signals (e.g., representative of commands or messages) to one or more components and/or systems of the machine 600. Although the controller(s) 636 is listed separately from the SoC(s) 604, this is not intended to be limiting, and in some embodiments one or more components of the SoC(s) 604 may perform the operations of the controller(s) 636. For example, the controller(s) may send signals to operate the machine brakes via one or more brake actuators 648, to operate the steering system 654 via one or more steering actuators 656, to operate the propulsion system 650 via one or more throttle/accelerators 652, etc. The controller(s) 636 may include one or more onboard (e.g., integrated) computing devices (e.g., supercomputers) that process sensor signals, and output operation commands (e.g., signals representing commands) to enable autonomous or semi-autonomous navigation and movement and/or to assist a human operator using the machine 600. The controller(s) 636 may include a first controller 636 for autonomous control and navigation functions, a second controller 636 for functional safety functions, a third controller 636 for artificial intelligence functionality (e.g., computer vision), a fourth controller 636 for infotainment functionality, a fifth controller 636 for redundancy in emergency conditions, and/or other controllers. For example, the hardware used for safety monitoring and other safety functions (such as a functional safety island) may be discrete or partitioned (physically or via separation of processing) with respect to hardware used for processing sensor data for perception and making vehicle control decisions. Similarly, hardware (e.g., a controller, an SOC, etc.) for controlling in-vehicle infotainment and/or in-cabin monitoring may be discrete or separate from the hardware used for vehicle perception and control. In some examples, a single controller 636 may handle two or more of the above functionalities, two or more controllers 636 may handle a single functionality, and/or any combination thereof.

The controller(s) 636 may provide the signals for controlling one or more components and/or systems of the machine 600 in response to sensor data received from one or more sensors (e.g., sensor inputs). The sensor data may be received from, for example and without limitation, global navigation satellite systems (“GNSS”) sensor(s) 658 (e.g., Global Positioning System sensor(s)), RADAR sensor(s) 660, ultrasonic sensor(s) 662, LiDAR sensor(s) 664, inertial measurement unit (IMU) sensor(s) 666 (e.g., accelerometer(s), gyroscope(s), magnetic compass(es), magnetometer(s), etc.), microphone(s) 696, camera(s) 668 (e.g., stereo camera(s) 668A, wide-view camera(s) 668B (e.g., fisheye cameras), infrared camera(s) 668C, surround camera(s) 668D (e.g., 360 degree cameras), long-range and/or mid-range camera(s) 668E, and/or other camera types), speed sensor(s) 644 (e.g., for measuring the speed of the machine 600), vibration sensor(s) 642, steering sensor(s) 640, brake sensor(s) (e.g., as part of the brake sensor system 646), actuators, and/or other sensor types.

One or more of the controller(s) 636 may receive inputs (e.g., represented by input data) from an instrument cluster 632 of the machine 600 and provide outputs (e.g., represented by output data, display data, etc.) via a human-machine interface (HMI) display 634 (e.g., screen, heads-up display, mirror display, facial display, robotic display, etc.), an audible annunciator, a loudspeaker, a speaker, and/or via other components of the machine 600. The outputs may include information such as machine velocity, speed, time, map data corresponding to a map(s) 622 of FIG. 6C (e.g., from a navigation map, a Standard Definition (SD) map, a High Definition (“HD”) map, etc.), location data (e.g., the machine's 600 location, such as on a map 622), direction, location of other vehicles (e.g., an occupancy map, height map, bird's eye view (BEV) image, grid, etc.), information about objects and status of objects as perceived by the system, system status information, etc. For example, the HMI display(s) 634 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The machine 600 may include one or more systems on a chip (SoCs) 604 (described in more detail in FIG. 6D). The SoC(s) 604 may include CPU(s) 606, GPU(s) 608, processor(s) 610, cache(s) 612, accelerator(s) 614, data store(s) 616, and/or other components and features. The SoC(s) 604 may be used to process and provide data for various operations, such as navigation, planning, reasoning, inference, perception, control, and/or actuation operations of the machine 600 in a variety of platforms and systems. For example, the SoC(s) 604 may process live perception data (e.g., from camera, LiDAR, RADAR, ultrasonic, etc.) in addition to map data corresponding to one or more maps 622 (e.g., HD map, SD map, navigational map, occupancy map, etc.) in order to make or aid in performing various operations of the machine 600. Where a map and/or AI is used, map and/or AI (e.g., model parameter updates, fine-tuning, etc.) refreshes and/or updates via a network interface 624 from one or more servers (e.g., server(s) 678 of FIG. 6E)—such as one or more servers of a cloud-based data center.

Although an SoC(s) 604 is illustrated throughout FIGS. 6A-6E, additional or alternative components and/or architectures may be used—such as multi-chip modules (MCMs), application-specific integrated circuits (ASICs), system-in-packages (SiPs), field programmable gate arrays (FPGAs), heterogeneous integration (HI), single-board computers (SBCs)—without departing from the scope of the present disclosure. For example, depending on the type of machine 600, use of the machine 600, model of the machine 600, and required capabilities of the machine 600, one or more SoCs 604 and/or alternative architectures and/or components may be used to satisfy the particular implementation.

The machine 600 may include a CPU(s) 618 (e.g., discrete CPU(s), or dCPU(s)), that may be coupled to the SoC(s) 604 via a high-speed interconnect (e.g., PCIe). The CPU(s) 618 may include an X86 processor, for example. The CPU(s) 618 may be used to perform any of a variety of functions, including arbitrating potentially inconsistent results between ADAS sensors and the SoC(s) 604, and/or monitoring the status and health of the controller(s) 636 and/or infotainment SoC 630, for example.

The machine 600 may include a GPU(s) 620 (e.g., discrete GPU(s), or dGPU(s)), that may be coupled to the SoC(s) 604 via a high-speed interconnect (e.g., NVIDIA's NVLink). The GPU(s) 620 may provide additional artificial intelligence functionality, such as by executing redundant and/or different neural networks, and may be used to train and/or update neural networks based on input (e.g., sensor data) from sensors of the machine 600.

The machine 600 may further include the network interface 624 which may include one or more wireless antennas 626 and/or modems (e.g., one or more wireless antennas for different communication protocols, such as a cellular antenna, a Bluetooth antenna, etc.). The network interface 624 may be used to enable wireless connectivity over the Internet with the cloud (e.g., with the server(s) 678 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the machine 600 information about vehicles in proximity to the machine 600 (e.g., vehicles in front of, on the side of, and/or behind the machine 600). This functionality may be part of a cooperative adaptive cruise control functionality of the machine 600.

The network interface 624 may include a SoC that provides modulation and demodulation functionality and enables the controller(s) 636 to communicate over wireless networks. The network interface 624 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. For example, the network interface 624 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), fifth generation of mobile communications technology (5G), sixth generation of mobile communications technology (6G), and/or other cellular and/or wireless communication standards. The wireless antenna(s) 626 may also enable communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

The machine 600 may further include data store(s) 628 which may include off-chip (e.g., off the SoC(s) 604) storage. The data store(s) 628 may include one or more storage elements including RAM, SRAM, DRAM, VRAM, Flash, hard disks, and/or other components and/or devices that may store at least one bit of data.

The machine 600 may further include GNSS sensor(s) 658. The GNSS sensor(s) 658 (e.g., GPS, assisted GPS sensors, differential GPS (DGPS) sensors, etc.), to assist in mapping, perception, occupancy grid generation, and/or path planning functions. Any number of GNSS sensor(s) 658 may be used, including, for example and without limitation, a GPS using a USB connector with an Ethernet to Serial (RS-232) bridge.

The machine 600 may further include IMU sensor(s) 666. The IMU sensor(s) 666 may be located at a center of the rear axle of the machine 600, in some examples. The IMU sensor(s) 666 may include, for example and without limitation, an accelerometer(s), a magnetometer(s), a gyroscope(s), a magnetic compass(es), and/or other sensor types. In some examples, such as in six-axis applications, the IMU sensor(s) 666 may include accelerometers and gyroscopes, while in nine-axis applications, the IMU sensor(s) 666 may include accelerometers, gyroscopes, and magnetometers.

In some embodiments, the IMU sensor(s) 666 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 666 may enable the machine 600 to estimate heading without requiring input from a magnetic sensor by directly observing and correlating the changes in velocity from GPS to the IMU sensor(s) 666. In some examples, the IMU sensor(s) 666 and the GNSS sensor(s) 658 may be combined in a single integrated unit.

The vehicle may include one or more microphone 696 placed in and/or around the machine 600. The microphone(s) 696 may be used for emergency vehicle detection and identification, among other things.

The machine 600 may further include vibration sensor(s) 642. The vibration sensor(s) 642 may measure vibrations of components of the machine, such as the arms or legs of a humanoid robot 600C, or the axle(s) of a vehicle 600A or AMR 600B. For example, changes in vibrations may indicate a change in road, walking, or traversable surfaces. In another example, when two or more vibration sensors 642 are used, the differences between the vibrations may be used to determine friction or slippage of the surface (e.g., when the difference in vibration is between a power-driven axle and a freely rotating axle).

The machine 600 may include an ADAS system 638—such as when the machine 600 is a vehicle 600A. The ADAS system 638 may include a dedicated SoC(s), in some examples. The ADAS system 638 may include autonomous/adaptive/automatic cruise control (ACC), cooperative adaptive cruise control (CACC), forward crash or collision warning (FCW), automatic emergency braking (AEB), lane departure warning (LDW), lane keep assist (LKA), blind spot warning (BSW), blind spot monitoring (BSM), rear cross-traffic warning (RCTW), pedestrian detection, driver monitoring, collision warning systems (CWS), traffic sign recognition, speed limit detection, automatic parking, lane centering (LC), high beam safety system, and/or other features and functionality.

The machine 600 may further include the infotainment SoC 630 (e.g., an in-vehicle infotainment system (IVI)). Although illustrated and described as a SoC, the infotainment system may not be an SoC, and may include one or more discrete components, such as multi-chip modules (MCMs), application-specific integrated circuits (ASICs), system-in-packages (SiPs), heterogeneous integration (HI), single-board computers (SBCs), etc. The infotainment SoC 630 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., wireless, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the machine 600. For example, the infotainment SoC 630 may radios, disk players, navigation systems, video players, USB and Bluetooth connectivity, carputers, in-car entertainment, Wi-Fi, steering wheel audio controls, hands free voice control, a heads-up display (HUD), an HMI display 634, a telematics device, a control panel (e.g., for controlling and/or interacting with various components, features, and/or systems), and/or other components. The infotainment SoC 630 may further be used to provide information (e.g., visual and/or audible) to a user(s) of the vehicle, such as information from the ADAS system 638, autonomous driving information such as planned vehicle maneuvers, trajectories, surrounding environment information (e.g., intersection information, vehicle information, road information, etc.), and/or other information.

The infotainment SoC 630 may include GPU functionality. The infotainment SoC 630 may communicate over the bus 602 (e.g., CAN bus, Ethernet, etc.) with other devices, systems, and/or components of the machine 600. In some examples, the infotainment SoC 630 may be coupled to a supervisory MCU such that the GPU of the infotainment system may perform some self-driving functions in the event that the primary controller(s) 636 (e.g., the primary and/or backup computers of the machine 600) fail. In such an example, the infotainment SoC 630 may put the machine 600 into a chauffeur to safe stop mode, as described herein.

In some embodiments, the infotainment system may provide a digital or virtual assistant, that may be voice only, or may have a visual component (e.g., in the form of a digital human or digital avatar). The assistant may provide basic functions, like texting, adjusting vehicle settings, music or video control, navigation features, etc., and/or may provide more advanced features such as those supported by one or more language models—such as large language models (LLMs), vision language models (VLMs), multi-modal language models (MMLMs), etc. For example, the driver and/or occupants may be able to interact with the assistant similar to how a user may interact with a language model, such as to ask general questions, specific questions, to request restaurant, gas station, and/or other recommendations and/or locations, to learn about the vehicle functionality or troubleshooting (e.g., to ask tire pressure information, oil change information, battery exchange information, etc.). As such, the machine 600—whether a vehicle 600A, AMR 600B, humanoid robot 600C, and/or other type of machine—may include a locally stored language model(s) and/or communicate to a remotely hosted language model (e.g., via one or more APIs) to provide more detailed and in-depth communication features to the users of the machine(s) 600.

In some examples, an infotainment SoC 630, the SoC(s) 604, and/or another SoC or computing/processing system may perform in-cabin driver and/or occupant monitoring. For example, the computing system may perform facial recognition and vehicle owner identification may use data from camera and/or other sensors to identify the presence of an authorized driver and/or owner of the machine 600. The always on sensor processing engine may be used to unlock the vehicle when the owner approaches the driver door and turn on the lights, and, in security mode, to disable the vehicle when the owner leaves the vehicle. In this way, the SoC(s) 604 provide for security against theft and/or carjacking.

In some embodiments, an in-cabin monitoring camera sensor may be monitored using one or more neural networks running on another or dedicated SoC—such as an in-vehicle infotainment or in-vehicle monitoring SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. The in-cabin system may further include one or more in-cabin AI agents or assistants, which may use one or more APIs or plug-ins to interact with one or more LLMs, VLMs, MMLMs, etc. in the cloud. For example, the in-cabin AI agents or assistants may provide directions, vehicle or machine feedback information, answer general questions, handle music/video and/or other requests, activate windows, doors, and/or other vehicle components, etc. As such, one or more dedicated SoCs and/or sets of processors may be used to perform the in-cabin infotainment and/or in-cabin monitoring (e.g., as an occupant monitoring system (OMS)) for the machine 600.

The machine 600 may further include an instrument cluster 632 (e.g., a digital dash, an electronic instrument cluster, a digital instrument panel, etc.). The instrument cluster 632 may include a controller and/or supercomputer (e.g., a discrete controller or supercomputer). The instrument cluster 632 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 630 and the instrument cluster 632. In other words, the instrument cluster 632 may be included as part of the infotainment SoC 630, or vice versa.

FIG. 6D is a block diagram of an example architecture of a computing system (a subset of the system described with respect to FIG. 6C), in accordance with at least some embodiments of the present disclosure. Although illustrated as an SoC(s) 604, this is not intended to be limiting, and the computing system may additionally or instead include multi-chip modules (MCMs), application-specific integrated circuits (ASICs), system-in-packages (SiPs), heterogeneous integration (HI), single-board computers (SBCs), and/or other components and/or architectures, without departing from the scope of the present disclosure.

The SoC(s) 604 may be an end-to-end platform with a flexible architecture that spans automation levels 2-5, or the SoC(s) 604 may be specifically designed for a specific automation level (e.g., a first SoC 604 for level 2 to level 2++, a second SoC 604 for level 3, a third SoC 604 for level 4, etc.), thereby providing a comprehensive functional safety architecture that leverages and makes efficient use of computer vision, neural network inferencing, robotic planning, control, and navigation, ADAS techniques, and the like, with diversity and redundancy, to provide a platform for a flexible, reliable driving or robotic control software stack, along with deep learning tools. The SoC(s) 604 may be faster, more reliable, and even more energy-efficient and space-efficient than conventional systems. For example, the accelerator(s) 614, when combined with the CPU(s) 606, the GPU(s) 608, and the data store(s) 616, may provide for a fast, efficient platform for level 2-5 autonomous vehicles as well as for safe planning, navigation, and control of AMRs 600B, humanoid robots 600C, and/or other robot or machine types.

In some embodiments, such as where the SoC(s) 604 include a GPU 608 with 2000 or more cores (e.g., 2048 cores), 60 or more tensor cores (e.g., 64 tensor cores), and a GPU max frequency of over 1 GHz (e.g., 1.3 GHz), a CPU 606 including 10 or more cores (e.g., 12 cores), with 64 bits, 3 MB L2 and 6 MB L3 cache memory, and a max frequency of 2 or more GHz (e.g., 2.2 GHz), one or more deep learning accelerators (DLAs), deep learning accelerator clusters (XNNs), neural network accelerators (NNAs), or neural processing units (NPUs) 609 (e.g., 2 DLAs/XNNs/NNAs/NPUs 609), and a vision accelerator—such as a programmable vision accelerator (PVA) 607, a single SoC 604) may be capable of 275 tera operations per second (TOPS) of AI performance. For example, NVIDIA's Jetson AGX Orin 64 GB SoC satisfies these criteria, and achieves this performance.

Similarly, in embodiments where the SoC(s) 604 include a GPU 608 with 1700 or more cores (e.g., 1792 cores), 50 or more tensor cores (e.g., 56 tensor cores), and a GPU max frequency of over 900 MHz (e.g., 930 MHz), a CPU 606 including 8 or more cores (e.g., 8 cores), with 64 bits, 2 MB L2 and 4 MB L3 cache memory, and a max frequency of 2 or more GHz (e.g., 2.2 GHz), one or more deep learning accelerators (DLAs), deep learning accelerator clusters (XNNs), neural network accelerators (NNAs), or neural processing units (NPUs) 609 (e.g., 2 DLAs/XNNs/NNAs/NPUs 609), and a vision accelerator—such as a programmable vision accelerator (PVA) 607, a single SoC 604) may be capable of 200 tera operations per second (TOPS) of AI performance. For example, NVIDIA's Jetson AGX Orin 32 GB SoC satisfies these criteria, and achieves this performance.

In some embodiments, such as where the SoC(s) 604 include a GPU 608 with 1000 or more cores (e.g., 1024 cores), 28 or more tensor cores (e.g., 32 tensor cores), and a GPU max frequency of over 900 MHz (e.g., 1173 MHz), a CPU 606 including 8 or more cores (e.g., 8 cores), with 64 bits, 2 MB L2 and 4 MB L3 cache memory, and a max frequency of 2 or more GHz (e.g., 2 GHz), one or more deep learning accelerators (DLAs), deep learning accelerator clusters (XNNs), neural network accelerators (NNAs), or neural processing units (NPUs) 609 (e.g., 1 DLA/XNN/NNA/NPU 609), and a vision accelerator—such as a programmable vision accelerator (PVA) 607, a single SoC 604) may be capable of 157 tera operations per second (TOPS) of AI performance. For example, NVIDIA's Jetson AGX Orin NX 16 GB SoC satisfies these criteria, and achieves this performance.

In various embodiments, such as where the SoC(s) 604 include a GPU 608 with 1000 or more cores (e.g., 1024 cores), 28 or more tensor cores (e.g., 32 tensor cores), and a GPU max frequency of over 900 MHz (e.g., 1020 MHz), a CPU 606 including 6 or more cores (e.g., 6 cores), with 64 bits, 1.5 MB L2 and 4 MB L3 cache memory, and a max frequency of 1.5 or more GHz (e.g., 1.7 GHz), a single SoC 604) may be capable of 67 tera operations per second (TOPS) of AI performance. For example, NVIDIA's Jetson Orin Nano 8 GB SoC satisfies these criteria, and achieves this performance.

The SoC(s) 604 may include one or more CPUs 606. The CPU(s) 606 may include a CPU cluster or CPU complex (alternatively referred to herein as a “CCPLEX”), in embodiments. The CPU(s) 606 may include multiple cores and/or (e.g., L2, L3) caches. For example, in some embodiments, the CPU(s) 606 may include twelve cores in a coherent multi-processor configuration. In some embodiments, the CPU(s) 606 may include four dual-core clusters where each cluster has a dedicated L2 cache (e.g., a 3 MB L2 cache). The CPU(s) 606 (e.g., the CCPLEX) may be configured to support simultaneous cluster operation enabling any combination of the clusters of the CPU(s) 606 to be active at any given time.

The SoC(s) 604 may include any type and number of GPUs 608. For example, an integrated GPU(s) (alternatively referred to herein as an “iGPU(s)”) may be used in some embodiments. The GPU(s) 608 may be programmable and may be efficient for parallel workloads. The GPU(s) 608, in some examples, may use an enhanced tensor instruction set. The GPU(s) 608 may include one or more streaming microprocessors, where each streaming microprocessor may include a cache (e.g., an L1 cache with at least 96 KB storage capacity), and two or more of the streaming microprocessors may share an L2 cache (e.g., an L2 cache with a 512 KB storage capacity). In some embodiments, the GPU(s) 608 may include at least eight streaming microprocessors. The GPU(s) 608 may use compute application programming interface(s) (API(s)). In addition, the GPU(s) 608 may use one or more parallel computing platforms and/or programming models (e.g., NVIDIA's CUDA).

The GPU(s) 608 may be power-optimized for best performance in automotive, robotics, and/or other embedded use cases. For example, the GPU(s) 608 may be fabricated on a Fin field-effect transistor (FinFET). However, this is not intended to be limiting and the GPU(s) 608 may be fabricated using other semiconductor manufacturing or fabrication processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an (e.g., L0) instruction cache, a warp scheduler, a dispatch unit, and/or a (e.g., 64 KB) register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 608 may include a high bandwidth memory (HBM) and/or a (e.g., 16 GB) HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 608 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 608 to access the CPU(s) 606 page tables directly. In such examples, when the GPU(s) 608 memory management unit (MMU) experiences a miss, an address translation request may be transmitted to the CPU(s) 606. In response, the CPU(s) 606 may look in its page tables for the virtual-to-physical mapping for the address and transmits the translation back to the GPU(s) 608. As such, unified memory technology may allow a single unified virtual address space for memory of both the CPU(s) 606 and the GPU(s) 608, thereby simplifying the GPU(s) 608 programming and porting of applications to the GPU(s) 608.

The SoC(s) 604 may include any number of cache(s) 612, including those described herein. For example, the cache(s) 612 may include L0 caches, L1 caches, L2 caches, L3 caches (e.g., that are available to both the CPU(s) 606 and the GPU(s) 608 (e.g., that is connected both the CPU(s) 606 and the GPU(s) 608)), etc. The cache(s) 612 may include a write-back cache that may keep track of states of lines, such as by using one or more cache coherence protocol (e.g., MEI, MESI, MSI, etc.). The (e.g., L3) cache may include 4 MB or more, depending on the embodiment, although smaller or larger cache sizes may be used.

The SoC(s) 604 may include one or more arithmetic logic units (ALUs) 665 which may be leveraged in performing processing with respect to any of the variety of tasks or operations of the machine 600—such as computer vision, machine learning or deep learning processing, world model management, etc. In addition, the SoC(s) 604 may include a floating point unit(s) (FPU(s)) 667—or other math coprocessor or numeric coprocessor types—for performing mathematical operations within the system. For example, the SoC(s) 604 may include one or more FPUs 667 integrated as execution units within a CPU(s) 606 and/or GPU(s) 608.

The SoC(s) 604 may include one or more accelerators 614 (e.g., hardware accelerators, software accelerators, or a combination thereof). For example, the SoC(s) 604 may include a hardware acceleration cluster that may include optimized hardware accelerators and/or large on-chip memory. The large on-chip memory 615 (e.g., 4 MB of SRAM, 32 GB and/or 64 GB 256-bit LPDDR5 at 204.8 GB/s, 8 GB and/or 16 GB 128-bit LPDDR5 at 102.4 GB/s, and/or other memory types and sizes), may enable the hardware acceleration cluster to accelerate neural network processing, transformer processing, optical flow processing, vision processing, and/or other calculations or processing. The hardware acceleration cluster may be used to complement the GPU(s) 608 and to off-load some of the tasks of the GPU(s) 608 (e.g., to free up more cycles of the GPU(s) 608 for performing other tasks). As an example, the accelerator(s) 614 may be used for targeted workloads (e.g., perception, convolutional neural networks (CNNs), deep neural networks (DNNs), language models (LLMs, VLMs, MMLMs, VLAs, etc.), transformer models, diffusion models, encoder-only models, encoder-decoder models, etc. that are stable enough to be amenable to acceleration.

The accelerator(s) 614 (e.g., the hardware acceleration cluster) may include a deep learning accelerator(s) (DLA) 609 (alternatively referred to herein as “a deep learning accelerator cluster (XNN) 609,” “neural network accelerator (NNA) 609,” or “neural processing unit (NPU) 609”). The DLA(s) 609 may include one or more Tensor processing units (TPUs) 641 that may be configured to provide an additional, e.g., ten trillion operations per second for deep learning applications and inferencing. The TPUs 641 may be accelerators configured to, and optimized for, performing image processing functions (e.g., for CNNs, RCNNs, DNNs, etc.). The DLA(s) 609 may further be optimized for a specific set of neural network types and floating point operations, as well as inferencing. The design of the DLA(s) may provide more performance per millimeter than a general-purpose GPU, and vastly exceeds the performance of a CPU. The TPU(s) 641 may perform several functions, including a single-instance convolution function, supporting, for example, INT8, INT16, and FP16 data types for both features and weights, as well as post-processor functions. Although the TPU(s) 641 are described as being included as part of the DLA(s) 609, this is not intended to be limiting, and the TPU(s) 641 may be included in additional or alternative accelerator(s) 614 and/or other components, and/or may be included as a discrete processing component(s).

The DLA(s) 609 may quickly and efficiently execute neural networks on processed or unprocessed data for any of a variety of functions, including, for example and without limitation: for object and feature identification and detection (e.g., vehicles, pedestrians, other robots, lane lines, road boundary lines, debris, potholes, boxes, warehouse items, etc.) using data from one or more sensor modalities; for distance estimation using data from one or more sensor modalities; for emergency vehicle detection and identification and detection using data from microphones and/or vision-based sensors; for facial recognition; for pick and place operations; for manipulation operations; for occupant monitoring; for vehicle owner identification; and/or other in-cabin operations using data from in-cabin cameras and/or other sensor types; and/or a for security and/or safety related events, to name a few.

The DLA(s) 609 may perform any function of the GPU(s) 608, and by using an inference accelerator, for example, a designer may target either the DLA(s) 609 or the GPU(s) 608 for any function. For example, the designer may focus processing of DNNs and floating point operations on the DLA(s) 609 and leave other functions to the GPU(s) 608 and/or other accelerator(s) 614. The DLA(s) 609 may be used to run any type of network to enhance control and safety, including for example, a neural network that outputs a measure of confidence for each object detection.

The accelerator(s) 614 (e.g., the hardware acceleration cluster) may include a programmable vision accelerator(s) (PVA) 607, which may alternatively be referred to herein as a computer vision accelerator or generally a vision accelerator. The PVA(s) 607 may be designed and configured to accelerate computer vision algorithms for the advanced driver assistance systems (ADAS), semi-autonomous driving, autonomous driving, robotics applications, security and surveillance applications, augmented reality (AR), virtual reality (VR), and/or mixed reality (MR) applications, etc. The PVA(s) 607 may provide a balance between performance and flexibility. For example, each PVA(s) 607 may include, for example and without limitation, any number of reduced instruction set computer (RISC) cores, direct memory access (DMA) systems, pixel processing engines (PPEs), vector processors or vector processing units (VPUs), and/or other components. The PVA engine may include an advanced very long instruction word (VLIW), single instruction multiple data (SIMD) digital signal processor. The PVA(s) 607 may be optimized for the tasks of image processing and computer vision algorithm acceleration. For example, the PVA(s) 607 provides excellent performance with extremely low power consumption, and can be used asynchronously and concurrently with the CPU(s) 606, GPU(s) 608, and/or other accelerators in the system (e.g., vehicle, robot, etc.) as part of a heterogeneous compute pipeline.

The PVA(s) 607 may include one or more (e.g., two) vector processing subsystems (VPS), where each VPS may include one or more vector processing unit (VPU) cores, one or more decoupled look-up units (DLUTs), one or more shared or vector memories (VMEMs), and one or more instruction caches (I-caches). The VPU core(s) may be the main processing unit, and may include a vector SIMD VLIW DSP 643 optimized for computer vision. The VPU core(s) may fetch instructions through the I-cache(s), and may access data through the VMEM(s). The DLUT(s) may include a specialized hardware component that enhances the efficiency of parallel lookup operations. For example, the DLUT(s) allow parallel lookups using a single copy of the lookup table by executing these lookups in a decoupled pipeline, independent of the primary processor pipeline. By doing so, the DLUT(s) minimize or reduce memory usage and enhance throughput while avoiding data-dependent memory bank conflicts—ultimately leading to improved overall system performance. The VPU VMEM(s) may provide local data storage for the VPU, allowing efficient implementation of various image processing and computer vision algorithms. The VPU VMEM(s) may support access from outside-VPS hosts such as direct memory access (DMA) and the CPU(s) 606 (e.g., ARM Cortex-R5 processor), facilitating data exchange with the CPU(s) 606 and other system-level components. The VPU I-cache may supply instruction data to the VPU(s) when requested, may request missing instruction data from system memory, and/or may maintain temporary instruction storage for the VPU. For each VPU task, the CPU(s) 606 may configure the DMA system, optionally prefetch the VPU program into VPU I-cache, and/or kick off each VPU-DMA pair to process a task. The PVA(s) 607 may also include an L2 SRAM memory to be shared between the one or more (e.g., two) sets of VPS and DMA. In some embodiments, one or more (e.g., two) DMA devices are used to move data among external memory, PVA L2 memory, the VMEMs (e.g., one in each VPS), CPU(s) tightly coupled memory (TCM), DMA descriptor memory, and/or PVA-level config registers. In a lightly loaded system, two parallel DMA accesses to DRAM can achieve a read/write bandwidth of up to 15 GB/s each and, in a heavily loaded system, this bandwidth can reach up to 10 GB/s each. With respect to compute compacity, the INT8 Giga Multiply-Accumulate Operations per Second (GMACs) may be 2048 or greater, excluding the DLUT. The FP32 GMACs may include 32 per PVA instance.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA system may enable components of the PVA(s) 607 to access the system memory independently of the CPU(s) 606. The DMA may support any number of features used to provide optimization to the PVA(s) 607 including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors or VPUs may be programmable processors that may be designed to efficiently and flexibly execute programming for computer vision algorithms and provide signal processing capabilities. In some examples, the PVA(s) 607 may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA(s) 607, and may include one or more vector processing units (VPUs), one or more pixel processing engines (PPEs)—which may include a 2D layout of interconnected (e.g., for north, south, east, west intercommunication) processing elements, one or more instruction caches, and/or one or more shared or vector memories (e.g., VMEMs). A VPU core may include a digital signal processor such as, for example, a single instruction, multiple data (SIMD), very long instruction word (VLIW) digital signal processor. The combination of the SIMD and VLIW may enhance throughput and speed.

In some embodiments, each of the vector processors may include an instruction cache and may be coupled to dedicated memory. As a result, in some examples, each of the vector processors may be configured to execute independently of the other vector processors. In other examples, the vector processors that are included in a particular PVA(s) 607 may be configured to employ data parallelism. For example, in some embodiments, the plurality of vector processors included in a single PVA(s) 607 may execute the same computer vision algorithm, but on different regions of an image. In other examples, the vector processors included in a particular PVA(s) 607 may simultaneously execute different computer vision algorithms, on the same image, or even execute different algorithms on sequential images or portions of an image. Among other things, any number of PVAs 607 may be included in the hardware acceleration cluster and any number of vector processors may be included in each of the PVAs. In addition, the PVA(s) 607 may include additional error correcting code (ECC) memory, to enhance overall system safety.

The accelerator(s) 614 (e.g., the hardware accelerator cluster) have a wide array of uses for autonomous and semi-autonomous machine control. The PVA(s) 607 may be a programmable vision accelerator that may be used for key processing stages in perception, robotics understanding and reasoning, ADAS, semi-autonomous, and autonomous vehicles, etc. The PVA's 607 capabilities are a good match for algorithmic domains needing predictable processing, at low power and low latency. In other words, the PVA(s) 607 performs well on semi-dense or dense regular computation, even on small data sets, which need predictable run-times with low latency and low power. Thus, in the context of platforms for autonomous vehicles and robotics, the PVAs 607 are designed to run classic computer vision algorithms, as they are efficient at object detection and operating on integer math.

For example, according to one embodiment of the technology, the PVA 607 is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA(s) 607 may perform computer stereo vision function on inputs from two monocular cameras.

In some examples, the PVA(s) 607 may be used to perform dense optical flow. According to process raw RADAR data (e.g., using a 4D Fast Fourier Transform) to provide Processed RADAR. In other examples, the PVA(s) 607 is used for time-of-flight depth processing, by processing raw time of flight data to provide processed time of flight data, for example.

Although the VPU(s), DMA(s), RISC Core(s), VMEM(s), and decoupled co-processors (e.g., the DLUT(s)) are described as being included within the PVA(s) 607, this is not intended to be limiting. In some embodiments, these components may be included in alternative or additional processing components and/or accelerator(s) 614, and/or may be included as discrete components of the SoC(s) 604 and/or other computing system architecture(s).

In some examples, the SoC(s) 604 may include a real-time ray-tracing hardware accelerator (RTA) 651 that may be used to quickly and efficiently determine the positions and extents of objects (e.g., within a world model), to generate real-time or near-real time visualization simulations, for RADAR signal interpretation, for sound propagation synthesis and/or analysis, for simulation of SONAR, RADAR, LiDAR, camera, and/or other sensor modalities within a simulation, for general wave propagation simulation, for comparison to LiDAR data for purposes of localization, to generate realistic training data for training neural networks, and/or other functions and uses. In some embodiments, one or more tree traversal units (TTUs) may be used for executing one or more ray-tracing related operations. For example, the machine 600 (or another machine or device) may be simulated within a simulation environment, and the simulation environment may be generated using one or more light transport simulation algorithms (e.g., ray-tracing, path-tracing, etc.). These ray-tracing algorithms may thus be accelerated using a ray-tracing accelerator 651 and/or a ray-tracing optimized GPU 608—such as NVIDIA's RTX GPU.

The accelerator(s) 614 (e.g., in the hardware acceleration cluster) may include one or more optical flow accelerators (OFAs) 611. For example, the OFA(s) 611 may be used for computing optical flow and stereo disparity between frames of sensor data (e.g., images). Optical flow may be accelerated on the OFA(s) 611 for uses such as object detection and tracking, and/or for stereo depth estimation where used for computing stereo disparity between stereo image frames (e.g., two or more frames captured using two or more image sensors with at least partially overlapping fields of view).

The SoC(s) 604 may include one or more camera serial interfaces (CSIs) 623. For example, the CSI(s) 623 may include a mobile industry processor interface (MIPI) camera serial interface (CSI) for receiving video and input from cameras, a high-speed interface, and/or a video input block that may be used for camera and related pixel input functions. The SoC(s) 604 may further include an input/output controller(s) that may be controlled by software and may be used for receiving I/O signals that are uncommitted to a specific role. For example, the CSI 623 may include a MIPI CSI-2 connector—e.g., a 16 lane MIPI CSI-2 connector, D-PHY 2.1 (up to 40 Gbps), and C-PHY 2.0 (up to 164 Gbps) for supporting 16 virtual channels and six or more cameras, an 8 lane MIPI CSI-2 connector, D-PHY 2.1 (up to 20 Gbps for supporting 8 virtual channels and 4 or more cameras, and/or a 2x MIPI CSI-2, 22 pin camera connector, depending on the embodiment and implementation.

The accelerator(s) 614 (e.g., the hardware acceleration cluster) may include a computer vision network on-chip (CVNOC) 663 and SRAM, for providing a high-bandwidth, low latency SRAM for the accelerator(s) 614. In some examples, the on-chip memory may include at least 4 MB SRAM, consisting of, for example and without limitation, eight field-configurable memory blocks, that may be accessible by the PVA 607, OFA 611, DLA 609, and/or other accelerator(s) 614. Each pair of memory blocks may include an advanced peripheral bus (APB) interface, configuration circuitry, a controller, and a multiplexer. Any type of memory 615 may be used. The PVA 607, OFA 611, DLA 609, and/or other accelerator(s) 614 may access the memory via a backbone that provides the accelerator(s) 614 with high-speed access to memory. The backbone may include a computer vision network on-chip that interconnects the accelerator(s) 614 to the memory (e.g., using the APB).

The CVNOC 663 may include an interface that determines, before transmission of any control signal/address/data, that the accelerator(s) 614 provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

The SoC(s) 604 may include data store(s) 616 and/or memory 615. The data store(s) 616 may be on-chip memory 615 of the SoC(s) 604, which may store neural networks and/or other algorithms to be executed on the CPU(s) 606, the GPU(s) 608, and/or one or more of the accelerator(s) 614. In some examples, the data store(s) 616 may be large enough in capacity to store multiple instances of neural networks for redundancy and safety. The data store(s) 616 may comprise L2 and/or L3 cache(s) 612, for example. The memory(ies) 615 may include SRAM, LPDDR5, and/or other memory types. For example, the memory(ies) 615 may include 4 MB of SRAM, 32 GB and/or 64 GB 256-bit LPDDR5 at 204.8 GB/s, 8 GB and/or 16 GB 128-bit LPDDR5 at 102.4 GB/s, and/or other memory types and sizes. Reference to the data store(s) 616 may include reference to the memory associated with the PVA 607, OFA 611, DLA 609, and/or other accelerator(s) 614, as described herein.

The data store(s) 616 may include various storage types, such as eMMC, NVMe, etc. For example, the SoC(s) 604 may include storage in the form of an embedded multimedia card (eMMC) (e.g., 64 GB eMMC 5.1) and/or an SD card slot, with external NVM express (NVMe) capability, e.g., via M.2 Key M. For example, the data store(s) 616 and/or other storage may be accessed via, e.g., NVMe, using PCI Express (PCIe), RDMA, TCP, and/or other protocols.

The SoC(s) 604 may include one or more processor(s) 610 (e.g., embedded processors). The processor(s) 610 may include a boot and power management processor (BPMP) 653, that may be a dedicated processor and subsystem to handle boot power and management functions and related security enforcement. The BPMP 653 may be a part of the SoC(s) 604 boot sequence and may provide runtime power management services. The BPMP 653 may provide clock and voltage programming, assistance in system low power state transitions, management of SoC(s) 604 thermals and temperature sensors, and/or management of the SoC(s) 604 power states. Each temperature sensor may be implemented as a ring-oscillator whose output frequency is proportional to temperature, and the SoC(s) 604 may use the ring-oscillators to detect temperatures of the CPU(s) 606, GPU(s) 608, accelerator(s) 614, and/or other components. If temperatures are determined to exceed a threshold, BPMP 653 may enter a temperature fault routine and put the SoC(s) 604 into a lower power state and/or put the machine 600 into a chauffeur to safe stop mode (e.g., bring the machine 600 to a safe stop).

The processor(s) 610 may further include a set of embedded processors that may serve as an audio processing engine (APE) 655. The APE 655 may be an audio subsystem that enables full hardware support for multi-channel audio over multiple interfaces, and a broad and flexible range of audio I/O interfaces. In some examples, the APE 655 is a dedicated processor core with a digital signal processor with dedicated RAM.

The processor(s) 610 may further include an always on processor engine (AOPE) 657 that may provide necessary hardware features to support low power sensor management and wake use cases. The AOPE 657 may include a processor core, a tightly coupled RAM, supporting peripherals (e.g., timers and interrupt controllers), various I/O controller peripherals, and routing logic.

The processor(s) 610 may further include a safety processor(s) 613 (alternatively referred to as “safety island 613”), which may include a safety cluster engine that includes a dedicated processor or processor subsystem to handle safety management for automotive, robotics, and/or other applications. The safety processor(s) 613—and/or safety cluster engine—may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations. In some embodiments, the safety processor(s) 613 may include a discrete processor(s), such that fault of other system components may not impact the performance and availability of the safety processor 613.

The processor(s) 610 may further include a real-time or near real-time sensor engine (SE) 659 that may include a dedicated processor subsystem for handling real-time or near real-time camera, LiDAR, RADAR, and/or other sensor modality management.

The processor(s) 610 may further include one or more image signal processors (ISPs) 627, which may include a high-dynamic range signal processor and/or a hardware engine that is part of one or more sensor processing pipelines.

The processor(s) 610 may include a video image compositor (VIC) 661 that may be a processing block (e.g., implemented on a microprocessor) that implements video post-processing functions needed by a video playback application to produce the final image for the player window. The VIC 661 may perform lens distortion correction on wide-view camera(s) 668B, surround camera(s) 668D, in-cabin monitoring camera sensors, and/or other camera sensors with distorted fields of view.

A VIC 661 may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

A VIC 661 may also be configured to perform stereo rectification on input stereo lens frames. The video image compositor may further be used for user interface composition when the operating system desktop is in use, and the GPU(s) 608 is not required to continuously render new surfaces. Even when the GPU(s) 608 is powered on and active doing 3D rendering, the video image compositor may be used to offload the GPU(s) 608 to improve performance and responsiveness.

The SoC(s) 604 may further include a broad range of peripheral interfaces for input/output (I/O) 625, such as to enable communication with peripherals, audio codecs, power management, and/or other devices. The SoC(s) 604 may be used to process data from cameras (e.g., connected over Gigabit Multimedia Serial Link and/or Ethernet), sensors (e.g., LiDAR sensor(s) 664, RADAR sensor(s) 660, etc. that may be connected over Ethernet), data from bus 602 (e.g., speed of machine 600, steering wheel position, etc.), data from GNSS sensor(s) 658 (e.g., connected over Ethernet or CAN bus). The SoC(s) 604 may further include dedicated high-performance mass storage controllers that may include their own DMA engines, and that may be used to free the CPU(s) 606 from routine data management tasks. In some embodiments, the SoC(s) 604 I/O 625 may include a header (e.g., a 40 pin header, or 40 pin expansion header) with support for universal asynchronous receiver/transmitter (UART), serial peripheral interface (SPI), inter-integrated circuit sound (I²S), inter-integrated circuit (I2C), controller area network (CAN), pulse width modulation (PWM), digital microphone interface (DMIC), digital speaker station (DSPK), general purpose I/O (GPIO), etc., an automation header (e.g., 12 pin automation header), an audio panel header (e.g., a 10 pin audio panel header), a joint test action group (JTAG) header (e.g., a 10 pin JTAG header), a fan header (e.g., a 4 pin fan header), an RTC battery backup connector (e.g., a 2 pin battery backup connector), a microSD slot, a DC power jack, power, force, recovery, and reset buttons, one or more display connectors (e.g., DisplayPort (DP), such as a DP 1.4A (+MST), an eDP 1.41, an HDMI 2.1, and/or a 4K30 multi-model DP 1.2 (+MST) connector), and/or other I/O 625 elements, components, or features.

The SoC(s) 604 may include in-machine networking capability using, for example, Ethernet (e.g., automotive Ethernet), SERDES, controller area network (CAN), FlexRay, local interconnect network (LIN), low voltage differential signaling (LVDS), media oriented system transport (MOST), another networking type, and/or a combination thereof. For example, the SoC(s) 604 may include an RJ45 connector with up to 10 GbE, a 1 GbE connector, and/or other networking connector types.

The SoC(s) 604 may include one or more digital signal processors (DSPs) 643. For example, the DSP(s) 643 may include a dedicated or specialized microprocessor chip optimized for digital signal processing—such as in audio signal processing, telecommunications, digital image processing, RADAR, SONAR, LiDAR, and/or other sensor processing, speech recognition, and/or other applications.

The SoC(s) 604 may include one or more video encoders 619 and/or one or more video decoders 621. For example, the video encoder(s) 619 may include a hardware-based (e.g., as part of the GPU(s) 608) video encoder (e.g., supporting H.264, H.265, etc., and being HEVC compliant, such as NVIDIA's NVENC) that may process image inputs (e.g., as YUV, RGB, etc.) to generate a video bit stream. The video decoder(s) 621 may include a video decoder engine that may provide fully-accelerated hardware video decoding capabilities (e.g., supporting decoding of bitstreams in various formats, such as AV1, H.264, H.265, VP8, VP9, MPEG-1, MPEG-2, MPEG-4, VC-1, etc, and being HEVC compliant, such as NVIDIA's NVDEC). In some examples, the video decoder(s) 621 may be hardware-based (e.g., as part of the GPU(s) 608).

The SoC(s) 604 may include one or more general compute acceleration clusters (GCAC(s)) 629. For example, the GCAC(s) 629 may include various processor types that may be used to accelerate compute, such as one or more vector microcode processors (VMPs) 633, one or more multi-threaded processing clusters (MPCs) 631, one or more programmable macro arrays (PMA(s)) 635, and/or one or more other processor types. For example, the GCAC(s) 629 may include a PMA 635, two VMPs 633, and 2 MPCs 631.

The SoC(s) 604 may include one or more vector microcode processors (VMPs) 633. The VMP(s) 633, in embodiments, may include a wide vector (very long instruction word (VLIW) and single instruction multiple data (SIMD)) machine with performing various operations, such as short integral type operations common in computer vision and deep learning algorithms.

The SoC(s) 604 may include one or more multi-threaded processing clusters (MPCs) 631. The MPC(s) 631 may include a processing cluster that be, in embodiments, more versatile than a GPU, and with higher efficiency than a CPU. For example, the MPC(s) 631 may include a multi-threaded processor that allows multiple threads to share resources and execute instructions concurrently.

The SoC(s) 604 may include one or more programmable macro arrays (PMA(s)) 635. The PMA(s) 635 may include a coarse-grained reconfigurable architecture (CGRA) dataflow machine, having a unique architecture that delivers strong performance on dense computer vision and deep learning algorithms that may be unachievable in classic digital signal processing (DSP) architectures.

The SoC(s) 604 may include one or more display processing units (DPUs) 645 for performing hardware-accelerated image processing. For example, the DPU(s) 645 may retrieve pixel data from memory 615 and send it to a display peripheral through standard interfaces. As such, the DPU(s) 645 may handle display processing and rendering for in-machine and/or on-machine displays.

The SoC(s) 604 may include one or more application processing units (APUs) 639. For example, the APU(s) 639 may include a quad or dual-core processor with 48 KB/32 KB L1 cache with parity and ECC, along with a 1 MB L2 cache with ECC. The APU(s) 639 may support NEON instructions and single and double precision floating point operations.

The SoC(s) 604 may include one or more real-time processing units (RTPUs) 669. The RTPU(s) 669 may include a dual-core processor with 32 KB/32 KB L1 cache, and 256 KB TCM with ECC. The RTPU(s) 669 may support single and double precision floating point operations.

The SoC(s) 604 may include one or more built-in self-test (BIST) components 637. For example, the BIST component(s) 637 may include memory BIST (MBIST) to test memories of the system and/or logic BIST (LBIST) to test logic of the system. The BIST components 637 may include embedded logic for directly testing logic and/or memory of the system.

The SoC(s) 604 may include one or more dynamically reconfigurable processors (DRPs) 671. For example, the DRP(s) 671 may be used for accelerating various computing operations. For example, the DRP(s) 671 may be combined, in embodiments, with a MAC unit for use as an AI accelerator. In embodiments, the DRP(s) 671 may execute applications while dynamically switching the circuit connection configuration of the arithmetic units (e.g., ALUs) on the chip at each operating clock according to the content to be processed. Since only the necessary arithmetic circuits are used, the DRP(s) 671 may consume less power than with CPU processing and can achieve higher speed. Furthermore, compared to CPUs, where frequent external memory accesses due to cache misses and other causes will degrade performance, the DRP(s) 671 can build the necessary data paths in hardware ahead of time, resulting in less performance degradation and less variation in operating speed (jitter) due to memory accesses. The DRP(s) 671 may include a dynamic loading function that switches the circuit connection information each time the algorithm changes, enabling processing with limited hardware resources, even in robotic/automotive applications that require processing of multiple algorithms.

In some embodiments, the accelerator(s) 614 may include an OpenCV accelerator for speeding up processing of OpenCV, an open-source industry standard library for computer vision processing. In some embodiments, the combination of one or more DRP(s) 671 deployed as an AI accelerator along with an OpenCV accelerator(s) may enhance AI computing and image processing algorithms, enabling complex and compute-heavy operations such as Visual simultaneous localization and mapping (SLAM).

In contrast to conventional systems, by providing a CPU complex, GPU complex, and a hardware acceleration cluster, the technology described herein allows for multiple neural networks to be performed simultaneously (e.g., at least partially in parallel) and/or sequentially, and for the results to be combined together to enable Level 2-5 autonomous driving functionality and/or autonomous robotics movement, control, planning, and/or navigation operations. In addition, because the SoC(s) 604 may include various compute engines (e.g., processors 610, CPUs 606, GPU(s) 608, accelerator(s) 614, etc.), tasks may be distributed between and among the compute engines, in some instances without common cause failures due to the discrete footprint of the compute engines. Further, because the SoC(s) 604 may include a dedicated safety processor(s) 613 (or safety island 613), critical safety or redundant operations may be performed without common cause failures from the main processing components or compute engines of the SoC(s) 604. Due to these features, the SoC(s) 604 and/or the underlying systems of the machine 600 may be capable of satisfying higher levels of safety—such as automotive safety integrity level (ASIL) D from the ISO 26262 standard.

FIG. 6E is a system diagram for communication between a cloud-based server(s) (e.g., in a data center, such as those described herein) and the example autonomous or semi-autonomous vehicle or machine 600 of FIG. 6A, in accordance with some embodiments of the present disclosure. The system 676 may include a server(s) 678, a network(s) 690, and a machine(s) 600. The server(s) 678 may include a plurality of GPUs 684(A)-684(H) (collectively referred to herein as GPUs 684), switches 682(A)-682(D) (such as PCIe 4.0/5.0/etc switches, M.2 slots, thunderbolt, USB4, NVIDIA's NVLink, NVIDIA's NVSwitch, GPUDirect RDMA, GPUDirect Storage, etc.), CPUs 680(A)-680(B) (collectively referred to herein as CPUs 680), accelerators, and/or other processor types. The GPUs 684, the CPUs 680, and the PCIe switches 682 may be interconnected with high-speed interconnects such as, for example and without limitation, NVLink interfaces 688 developed by NVIDIA and/or PCIe connections 686. In some examples, the GPUs 684 are connected via NVLink and/or NVSwitch SoC and the GPUs 684 and the PCIe switches 682 are connected via PCIe interconnects. Although eight GPUs 684, two CPUs 680, and four PCIe switches are illustrated, this is not intended to be limiting. Depending on the embodiment, each of the server(s) 678 may include any number of GPUs 684, CPUs 680, and/or PCIe switches. For example, the server(s) 678 may each include eight, sixteen, thirty-two, and/or more GPUs 684.

The server(s) 678 may receive, over the network(s) 690 and from the machine(s) 600, sensor data indicating information about new or previously unexplored locations, and/or sensor data indicating changes to previously seen/stored locations (e.g., unexpected or changed road conditions, such as recently commenced road-work). The server(s) 678 may transmit, over the network(s) 690 and to the machine(s) 600, neural networks 692, updated neural networks 692, map information 694, etc., including information regarding traffic and road conditions. The updates to the map information 694 may include updates for the HD map 622, SD map, navigation map, etc., such as information regarding construction sites, potholes, detours, flooding, and/or other obstructions. In some examples, the neural networks 692, the updated neural networks 692, the map information 694, and/or the other information may have resulted from new training and/or experiences represented in data received from any number of machine(s) 600 in the environment, and/or based on training performed at a datacenter (e.g., using the server(s) 678 and/or other servers).

The server(s) 678 may be used to train machine learning models (e.g., neural networks) based on training data. The training data may be generated by the machine(s) 600, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the machine(s) 600 (e.g., transmitted to the machine(s) 600 over the network(s) 690, and/or the machine learning models may be used by the server(s) 678 to remotely monitor and/or control the machine(s) 600.

In some examples, the server(s) 678 may receive data from the machine(s) 600 and apply the data to up-to-date real-time neural networks for real-time intelligent inferencing. The server(s) 678 may include deep-learning supercomputers and/or dedicated AI computers powered by GPU(s) 684, such as a DGX and DGX Station machines developed by NVIDIA. However, in some examples, the server(s) 678 may include deep learning infrastructure that use only CPU-powered datacenters.

The deep-learning infrastructure of the server(s) 678 may be capable of fast, real-time inferencing, and may use that capability to evaluate and verify the health of the processors, software, and/or associated hardware in the machine 600. For example, the deep-learning infrastructure may receive periodic updates from the machine 600, such as a sequence of images and/or objects that the machine 600 has located in that sequence of images (e.g., via computer vision and/or other machine learning object classification techniques). The deep-learning infrastructure may run its own neural network to identify the objects and compare them with the objects identified by the machine 600 and, if the results do not match and the infrastructure concludes that the AI in the machine 600 is malfunctioning, the server(s) 678 may transmit a signal to the machine 600 instructing a fail-safe computer of the machine 600 to assume control, notify the passengers, and complete a safety maneuver or operation—such as to slow down, hand control back to a driver, come to a stop, and/or pull over/shut down.

For inferencing, the server(s) 678 may include the GPU(s) 684 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### Computing Ecosystem for Generating, Training, and Deploying AI

FIG. 7 is a system diagram illustrating a three computer ecosystem 700, including a first computing system 702 for generating or creating artificial intelligence (AI)—such as AI training and validation data, a second computing system 704 for training artificial intelligence, and a third computing system 706 (which may include or correspond to the SoC(s) 604 of FIGS. 6A-6E) deploying the AI at the edge, in accordance with at least some embodiments of the present disclosure. For example, to develop and deploy embodied or physical AI, the three computer ecosystem 700 may be used, including three accelerated computer systems to handle physical AI training, simulation, and runtime (e.g., edge deployment). These systems may generate training data for and train multimodal foundation models (and/or other model types) using scalable, physically based simulations of the machine(s) 600 and their worlds. By doing so, simulation of machine(s) 600 may be performed at scale, allowing for refinement, testing, and optimization of skills (e.g., robot skills) in a virtual world (e.g., using NVIDIA's OMNIVERSE) that mimics the laws of physics—helping to reduce real-world data acquisition costs and ensuring the machine(s) 600 can perform safely in controlled settings.

The computing system 704 (e.g., NVIDIA's DGX Platform) may be used to train and fine-tune powerful foundation and generative AI models. Models, such as general purpose foundation models (e.g., NVIDIA's Project GR00T), may be used to enable robots and other machine(s) 600 to understand natural language and emulate movements by observing human actions. The computing system 704 may include a platform that incorporates software, infrastructure, and expertise in a modern, unified AI development and training solution. The computing system 704 may include individual computing devices 710 (e.g., NVIDIA's DGX B200, H200, etc.) and/or any number of computing devices 710 in a data center infrastructure 712 (e.g., NVIDIA's DGX SuperPOD).

For example, the individual computing devices 710 may include GPUs (e.g., 8 GPUs with 1,440 GB total GPU memory) and CPUs (e.g., 2 CPUs with 112 cores total, 2.1 GHz, or 4 GHz (with boost)) that provide upwards of 72 petaFLOPS for training and 144 petaFLOPS for inference. The computing devices 710 may include memory (e.g., 4 TB memory, and storage (e.g., OS storage of 2×1.9 TB NVMe M.2, and internal storage of 8×3.84 TB NVMe U.2). The computing devices 710 may include various networking and network management components, such as OSFP ports (e.g., 4 OSFP ports) serving single-port smart host channel adapters (e.g., 8 single port ConnextX-7 virtual protocol interconnects (VPIs)), providing up to 400 GB/s Infiniband/Ethernet. The computing devices 710 may further include, e.g., dual port quad small form-factor pluggable (QSFFP) data processing units (DPUs) (e.g., 2 dual-port QSFP112 DPUs—such as NVIDIA's BlueField-3 DPUs), providing up to 400 Gb/s InfiniBand/Ethernet. The computing device(s) 710 may include an onboard network interface card (NIC) (e.g., 10 Gb/s onboard NIC with RJ45), a dual-port Ethernet NIC (e.g., 100 GB/s dual-port Ethernet NIC), and/or a host baseboard management controller (MBC) (e.g., with RJ45). In some embodiments, the NICs used for the computing device(s) 710 may include SuperNICs (e.g., NVIDIA's ConnectX-8 SuperNIC) to provide up to 800 Gb/s of data throughput for in-network computing acceleration engines to deliver the performance and robust feature set needed to power trillion-parameter scale AI factories and scientific computing workloads. In other embodiments, the computing device(s) 710 may include a smart host channel adapter (HCA) (e.g., NVIDIA's ConnectX-7) to provide ultra-low latency, 400 Gb/s throughput for in-network computing acceleration engines.

The data center infrastructure 712 may include any number of the computing devices 710, along with an operating system (OS) (e.g., DGX OS extensions for Linux distributions) to maximize system uptime, security, and reliability, network/storage acceleration libraries and management to accelerate end-to-end infrastructure performance, cluster management to scale and manage one node (e.g., one computing device 710) to thousands, job scheduling and orchestration to ensure hassle-free execution of every developer's job, AI workflow management and machine learning operations (MLOps) to move more models from prototype to production, and enterprise software to speed developer success.

The computing system 702 (e.g., NVIDIA's OVX servers) may provide a development and simulation platform for testing and optimizing physical AI with APIs and frameworks for simulation (e.g., NVIDIA's DriveSIM, ISAAC Sim, ISAAC Gym, ISAAC Labetc.). The computing system 702 allows developers to use simulation frameworks to simulate and validate robot models, and/or to generate massive amounts of physically-based synthetic data to bootstrap model training. The computing system 702 may support learning frameworks that power robot reinforcement learning and imitation learning, to accelerate robot policy training and refinement. For example, the computing system 702 may be used to generate any number of simulations 708—such as within NVIDIA's OMNIVERSE. The computing system 702 may be used optimized for accelerating an entire software stack, from training, fine-tuning, and deploying generative AI to powering industrial digitalization within a content collaboration platform of APIs, software developer kits (SDKs), and services that allow for integration of OpenUSD, ray-tracing rendering technologies (e.g., NVIDIA's RTX), and generative physical AI into existing software tools and simulation workflows for, e.g., industrial and robotics use cases (e.g., NVIDIA's OMNIVERSE). As such, the computing system 702 may host or support a native OpenUSD software platform enabling enterprises to connect 3D pipelines and develop advanced, real-time 3D applications for industrial digitalization. With powerful ray-tracing-accelerated AI and graphics capabilities, the computing system 702 delivers powerful performance for workloads like extended reality (XR), multi-user design collaboration, and digital twins. This allows creation of physically accurate models with high-fidelity ray-traced and path-traced rendering of materials, operation of large-scale, AI-enabled simulations, and generation of photorealistic 3D synthetic data for training. The computing system 702 may include individual computing devices 714 (e.g., NVIDIA's OVX L40S Server) and/or any number of computing devices 714 in a data center infrastructure 716 (e.g., NVIDIA's OVX Systems).

The computing device(s) 714 (which may include a server) may include CPUs (e.g., 2 CPUs with 32 cores each), and GPUs (e.g., 4 or 8 GPUs, each including 48 GB GDDR6 with ECC memory, 864 GB/s memory bandwidth, PCIe Gen4×16: 64 GB/s bidirectional interconnect interface, 18,176 CUDA cores, 142 ray tracing (RT) cores, and 568 tensor cores). The computing devices 714 may include various networking and network management components, such as smart host channel adapters (HCA) (e.g., 2 or 4 single port ConnextX-7 at 200 Gb/s each, providing up to 800 Gb/s Infiniband/Ethernet), one or more DPUs (e.g., a dual-port QSFP112 DPUs—such as an NVIDIA BlueField-3 DPU), providing up to 400 Gb/s InfiniBand/Ethernet. In some embodiments, the NICs used for the computing device(s) 714 may include SuperNICs (e.g., NVIDIA's ConnectX-8 SuperNIC) to provide up to 800 Gb/s of data throughput for in-network computing acceleration engines to deliver the performance and robust feature set needed to power trillion-parameter scale AI factories and scientific computing workloads. In other embodiments, the computing device(s) 714 may include a smart host channel adapter (HCA) (e.g., NVIDIA's ConnectX-7) to provide ultra-low latency, 400 Gb/s throughput for in-network computing acceleration engines. The computing device(s) 714 may include a host memory (e.g., 384 Gb DDR5 ECC for 4 GPUs, or 768 Gb DDR5 ECC for 8 GPUs), and may include a dual in-line memory module (DIMM) slot(s), a host boot drive (e.g., 1 TB NVMe), and/or a host storage (e.g., 2 4TB NVMe).

Similar to the data center infrastructure 712, the data center infrastructure 716 may allow for any number of computing device(s) 714 to be combined in cluster configuration according to a reference architecture.

The computing system 706 may be used to deploy trained AI models on a runtime computer—such as the SoC(s) 604 described herein. For example, these computing systems 706 may be designed for compact, on-board computing needs, including an ensemble of models for control policy, vision and language models, etc., deployed on a power-efficient on-board edge computing system 706. Details of components, features, and capabilities of the computing system 706 may be described in more detail herein with respect to FIGS. 6A-6E.

### Example Generative Models

In at least some embodiments, language models, such as large language models (LLMs), vision language models (VLMs), multi-modal language models (MMLMs), vision-language-action (VLA) models, and/or other types of generative artificial intelligence (AI) may be implemented. These models may be capable of understanding, summarizing, translating, and/or otherwise generating text (e.g., natural language text, code, etc.), images, video, computer aided design (CAD) assets, OMNIVERSE and/or METAVERSE file information (e.g., in USD format, such as OpenUSD), and/or the like, based on the context provided in input prompts or queries. These language models may be considered “large,” in embodiments, based on the models being trained on massive datasets and having architectures with large number of learnable network parameters (weights and biases)—such as millions or billions of parameters. The LLMs/VLMs/MMLMs/etc. may be implemented for summarizing textual data, analyzing and extracting insights from data (e.g., textual, image, video, etc.), and generating new text/image/video/etc. in user specified styles, tones, and/or formats. The LLMs/VLMs/MMLMs/etc. of the present disclosure may be used exclusively for text processing, in embodiments, whereas in other embodiments, multi-modal LLMs may be implemented to accept, understand, and/or generate text and/or other types of content like images, audio (sounds, synthetic speech, etc.), 2D and/or 3D data (e.g., in USD formats), and/or video. For example, vision language models (VLMs), or more generally multi-modal language models (MMLMs), may be implemented to accept image, video, sensor, audio, textual, 3D design (e.g., CAD), and/or other inputs data types and/or to generate or output image, video, audio, textual, 3D design, and/or other output data types.

Various types of LLMs/VLMs/MMLMs/etc. architectures may be implemented in various embodiments. For example, different architectures may be implemented that use different techniques for understanding and generating outputs—such as text, audio, video, image, 2D and/or 3D design or asset data, etc. In some embodiments, LLMs/VLMs/MMLMs/etc. architectures such as recurrent neural networks (RNNs) or long short-term memory networks (LSTMs) may be used, while in other embodiments transformer architectures—such as those that rely on self-attention and/or cross-attention (e.g., between contextual data and textual data) mechanisms—may be used to understand and recognize relationships between words or tokens and/or contextual data (e.g., other text, video, image, design data, USD, etc.). One or more generative processing pipelines that include LLMs/VLMs/MMLMs/etc. may also include one or more diffusion block(s) (e.g., denoisers). The LLMs/VLMs/MMLMs/etc. of the present disclosure may include encoder and/or decoder block(s). For example, discriminative or encoder-only models like BERT (Bidirectional Encoder Representations from Transformers) may be implemented for tasks that involve language comprehension such as classification, sentiment analysis, question answering, and named entity recognition. As another example, generative or decoder-only models like GPT (Generative Pretrained Transformer) may be implemented for tasks that involve language and content generation such as text completion, story generation, and dialogue generation. LLMs/VLMs/MMLMs/etc. that include both encoder and decoder components like T5 (Text-to-Text Transformer) may be implemented to understand and generate content, such as for translation and summarization. These examples are not intended to be limiting, and any architecture type—including but not limited to those described herein—may be implemented depending on the particular embodiment and the task(s) being performed using the LLMs/VLMs/MMLMs/etc.

In various embodiments, the LLMs/VLMs/MMLMs/etc. may be trained using unsupervised learning, in which an LLMs/VLMs/MMLMs/etc. learns patterns from large amounts of unlabeled text/audio/video/image/design/USD/etc. data. Due to the extensive training, in embodiments, the models may not require task-specific or domain-specific training. LLMs/VLMs/MMLMs/etc. that have undergone extensive pre-training on vast amounts of unlabeled data may be referred to as foundation models and may be adept at a variety of tasks like question-answering, summarization, filling in missing information, translation, image/video/design/USD/data generation. Some LLMs/VLMs/MMLMs/etc. may be tailored for a specific use case using techniques like prompt tuning, fine-tuning, retrieval augmented generation (RAG), adding adapters (e.g., customized neural networks, and/or neural network layers, that tune or adjust prompts or tokens to bias the language model toward a particular task or domain), and/or using other fine-tuning or tailoring techniques that optimize the models for use on particular tasks and/or within particular domains.

In some embodiments, the LLMs/VLMs/MMLMs/etc. of the present disclosure may be implemented using various model alignment techniques. For example, in some embodiments, guardrails may be implemented to identify improper or undesired inputs (e.g., prompts) and/or outputs of the models. In doing so, the system may use the guardrails and/or other model alignment techniques to either prevent a particular undesired input from being processed using the LLMs/VLMs/MMLMs/etc., and/or preventing the output or presentation (e.g., display, audio output, etc.) of information generating using the LLMs/VLMs/MMLMs/etc. In some embodiments, one or more additional models—or layers thereof—may be implemented to identify issues with inputs and/or outputs of the models. For example, these “safeguard” models may be trained to identify inputs and/or outputs that are “safe” or otherwise okay or desired and/or that are “unsafe” or are otherwise undesired for the particular application/implementation. As a result, the LLMs/VLMs/MMLMs/etc. of the present disclosure may be less likely to output language/text/audio/video/design data/USD data/etc. that may be offensive, vulgar, improper, unsafe, out of domain, and/or otherwise undesired for the particular application/implementation.

In some embodiments, the LLMs/VLMs/etc. may be configured to or capable of accessing or using one or more plug-ins, application programming interfaces (APIs), databases, data stores, repositories, etc. For example, for certain tasks or operations that the model is not ideally suited for, the model may have instructions (e.g., as a result of training, and/or based on instructions in a given prompt) to access one or more plug-ins (e.g., 3^{rd} party plugins) for help in processing the current input. In such an example, where at least part of a prompt is related to restaurants or weather, the model may access one or more restaurant or weather plug-ins (e.g., via one or more APIs) to retrieve the relevant information. As another example, where at least part of a response requires a mathematical computation, the model may access one or more math plug-ins or APIs for help in solving the problem(s), and may then use the response from the plug-in and/or API in the output from the model. This process may be repeated—e.g., recursively—for any number of iterations and using any number of plug-ins and/or APIs until a response to the input prompt can be generated that addresses each ask/question/request/process/operation/etc. As such, the model(s) may not only rely on its own knowledge from training on a large dataset(s), but also on the expertise or optimized nature of one or more external resources—such as APIs, plug-ins, and/or the like.

In some embodiments, multiple language models (e.g., LLMs/VLMs/MMLMs/etc., multiple instances of the same language model, and/or multiple prompts provided to the same language model or instance of the same language model may be implemented, executed, or accessed (e.g., using one or more plug-ins, user interfaces, APIs, databases, data stores, repositories, etc.) to provide output responsive to the same query, or responsive to separate portions of a query. In at least one embodiment, multiple language models e.g., language models with different architectures, language models trained on different (e.g. updated) corpuses of data may be provided with the same input query and prompt (e.g., set of constraints, conditioners, etc.). In one or more embodiments, the language models may be different versions of the same foundation model. In one or more embodiments, at least one language model may be instantiated as multiple agents—e.g., more than one prompt may be provided to constrain, direct, or otherwise influence a style, a content, or a character, etc., of the output provided. In one or more example, non-limiting embodiments, the same language model may be asked to provide output corresponding to a different role, perspective, character, or having a different base of knowledge, etc.—as defined by a supplied prompt.

In any one of such embodiments, the output of two or more (e.g., each) language models, two or more versions of at least one language model, two or more instanced agents of at least one language model, and/or two more prompts provided to at least one language model may be further processed, e.g., aggregated, compared or filtered against, or used to determine (and provide) a consensus response. In one or more embodiments, the output from one language model—or version, instance, or agent—maybe be provided as input to another language model for further processing and/or validation. In one or more embodiments, a language model may be asked to generate or otherwise obtain an output with respect to an input source material, with the output being associated with the input source material. Such an association may include, for example, the generation of a caption or portion of text that is embedded (e.g., as metadata) with an input source text or image. In one or more embodiments, an output of a language model may be used to determine the validity of an input source material for further processing, or inclusion in a dataset. For example, a language model may be used to assess the presence (or absence) of a target word in a portion of text or an object in an image, with the text or image being annotated to note such presence (or lack thereof). Alternatively, the determination from the language model may be used to determine whether the source material should be included in a curated dataset, for example and without limitation.

FIG. 8 is a block diagram of an example generative language model system 800 suitable for use in implementing at least some embodiments of the present disclosure. In the example illustrated in FIG. 8, the generative language model system 800 includes a retrieval augmented generation (RAG) component 892, an input processor 805, a tokenizer 810, an embedding component 820, plug-ins/APIs 895, and a generative language model (LM) 830 (which may include an LLM, a VLM, a MMLM, a VLA model, etc.).

At a high level, the input processor 805 may receive an input 801 comprising text and/or other types of input data (e.g., audio data, video data, image data, sensor data (e.g., LiDAR, RADAR, ultrasonic, etc.), 3D design data, CAD data, universal scene descriptor (USD) data—such as OpenUSD, etc.), depending on the architecture of the generative LM 830 (e.g., LLM/VLM/MMLM/etc.). In some embodiments, the input 801 includes plain text in the form of one or more sentences, paragraphs, and/or documents. Additionally or alternatively, the input 801 may include numerical sequences, precomputed embeddings (e.g., word or sentence embeddings), and/or structured data (e.g., in tabular formats, JSON, or XML). In some implementations in which the generative LM 830 is capable of processing multi-modal inputs, the input 801 may combine text (or may omit text) with image data, audio data, video data, design data, USD data, and/or other types of input data, such as but not limited to those described herein. Taking raw input text as an example, the input processor 805 may prepare raw input text in various ways. For example, the input processor 805 may perform various types of text filtering to remove noise (e.g., special characters, punctuation, HTML tags, stopwords, portions of an image(s), portions of audio, etc.) from relevant textual content. In an example involving stopwords (common words that tend to carry little semantic meaning), the input processor 805 may remove stopwords to reduce noise and focus the generative LM 830 on more meaningful content. The input processor 805 may apply text normalization (TN), for example, by converting all characters to lowercase, removing accents, and/or or handling special cases like contractions or abbreviations to ensure consistency (e.g., converting ¼ to one quarter). Similarly, the input processor 805 and/or a post-processor may perform inverse text normalization (ITN) in order to convert plain language back to canonical or other forms (e.g., to convert one quarter to ¼). These are just a few examples, and other types of input and/or output processing may be applied.

In some embodiments, a RAG component 892 (which may include one or more RAG models, and/or may be performed using the generative LM 830 itself) may be used to retrieve additional information to be used as part of the input 801 or prompt. RAG may be used to enhance the input to the LLM/VLM/MMLM/etc. with external knowledge, so that answers to specific questions or queries or requests are more relevant—such as in a case where specific knowledge is required. The RAG component 892 may fetch this additional information (e.g., grounding information, such as grounding text/image/video/audio/USD/CAD/etc.) from one or more external sources, which can then be fed to the LLM/VLM/MMLM/etc. along with the prompt to improve accuracy of the responses or outputs of the model.

For example, in some embodiments, the input 801 may be generated using the query or input to the model (e.g., a question, a request, etc.) in addition to data retrieved using the RAG component 892. In some embodiments, the input processor 805 may analyze the input 801 and communicate with the RAG component 892 (or the RAG component 892 may be part of the input processor 805, in embodiments) in order to identify relevant text and/or other data to provide to the generative LM 830 as additional context or sources of information from which to identify the response, answer, or output 890, generally. For example, where the input indicates that the user is interested in a desired tire pressure for a particular make and model of vehicle, the RAG component 892 may retrieve—using a RAG model performing a vector search in an embedding space, for example—the tire pressure information or the text corresponding thereto from a digital (embedded) version of the user manual for that particular vehicle make and model. Similarly, where a user revisits a chatbot related to a particular product offering or service, the RAG component 892 may retrieve a prior stored conversation history—or at least a summary thereof—and include the prior conversation history along with the current ask/request as part of the input 801 to the generative LM 830.

The RAG component 892 may use various RAG techniques. For example, naïve RAG may be used where documents are indexed, chunked, and applied to an embedding model to generate embeddings corresponding to the chunks. A user query may also be applied to the embedding model and/or another embedding model of the RAG component 892 and the embeddings of the chunks along with the embeddings of the query may be compared to identify the most similar/related embeddings to the query, which may be supplied to the generative LM 830 to generate an output.

In some embodiments, more advanced RAG techniques may be used. For example, prior to passing chunks to the embedding model, the chunks may undergo pre-retrieval processes (e.g., routing, rewriting, metadata analysis, expansion, etc.). In addition, prior to generating the final embeddings, post-retrieval processes (e.g., re-ranking, prompt compression, etc.) may be performed on the outputs of the embedding model prior to final embeddings being used as comparison to an input query.

As a further example, modular RAG techniques may be used, such as those that are similar to naïve and/or advanced RAG, but also include features such as hybrid search, recursive retrieval and query engines, StepBack approaches, sub-queries, and hypothetical document embedding.

As another example, Graph RAG may use knowledge graphs as a source of context or factual information. Graph RAG may be implemented using a graph database as a source of contextual information sent to the LLM/VLM/MMLM/etc. Rather than (or in addition to) providing the model with chunks of data extracted from larger sized documents—which may result in a lack of context, factual correctness, language accuracy, etc.—graph RAG may also provide structured entity information to the LLM/VLM/MMLM/etc. by combining the structured entity textual description with its many properties and relationships, allowing for deeper insights by the model. When implementing graph RAG, the systems and methods described herein use a graph as a content store and extract relevant chunks of documents and ask the LLM/VLM/MMLM/etc. to answer using them. The knowledge graph, in such embodiments, may contain relevant textual content and metadata about the knowledge graph as well as be integrated with a vector database. In some embodiments, the graph RAG may use a graph as a subject matter expert, where descriptions of concepts and entities relevant to a query/prompt may be extracted and passed to the model as semantic context. These descriptions may include relationships between the concepts. In other examples, the graph may be used as a database, where part of a query/prompt may be mapped to a graph query, the graph query may be executed, and the LLM/VLM/MMLM/etc. may summarize the results. In such an example, the graph may store relevant factual information, and a query (natural language query) to graph query tool (NL-to-Graph-query tool) and entity linking may be used. In some embodiments, graph RAG (e.g., using a graph database) may be combined with standard (e.g., vector database) RAG, and/or other RAG types, to benefit from multiple approaches.

In any embodiments, the RAG component 892 may implement a plugin, API, user interface, and/or other functionality to perform RAG. For example, a graph RAG plug-in may be used by the LLM/VLM/MMLM/etc. to run queries against the knowledge graph to extract relevant information for feeding to the model, and a standard or vector RAG plug-in may be used to run queries against a vector database. For example, the graph database may interact with a plug-in's REST interface such that the graph database is decoupled from the vector database and/or the embeddings models.

The tokenizer 810 may segment the (e.g., processed) text data into smaller units (tokens) for subsequent analysis and processing. The tokens may represent individual words, subwords, characters, portions of audio/video/image/etc., depending on the implementation. Word-based tokenization divides the text into individual words, treating each word as a separate token. Subword tokenization breaks down words into smaller meaningful units (e.g., prefixes, suffixes, stems), enabling the generative LM 830 to understand morphological variations and handle out-of-vocabulary words more effectively. Character-based tokenization represents each character as a separate token, enabling the generative LM 830 to process text at a fine-grained level. The choice of tokenization strategy may depend on factors such as the language being processed, the task at hand, and/or characteristics of the training dataset. As such, the tokenizer 810 may convert the (e.g., processed) text into a structured format according to tokenization schema being implemented in the particular embodiment.

The embedding component 820 may use any known embedding technique to transform discrete tokens into (e.g., dense, continuous vector) representations of semantic meaning. For example, the embedding component 820 may use pre-trained word embeddings (e.g., Word2Vec, GloVe, or FastText), one-hot encoding, Term Frequency-Inverse Document Frequency (TF-IDF) encoding, one or more embedding layers of a neural network, and/or otherwise.

In some implementations in which the input 801 includes image data/video data/etc., the input processor 805 may resize the data to a standard size compatible with format of a corresponding input channel and/or may normalize pixel values to a common range (e.g., 0 to 1) to ensure a consistent representation, and the embedding component 820 may encode the image data using any known technique (e.g., using one or more convolutional neural networks (CNNs) to extract visual features). In some implementations in which the input 801 includes audio data, the input processor 805 may resample an audio file to a consistent sampling rate for uniform processing, and the embedding component 820 may use any known technique to extract and encode audio features—such as in the form of a spectrogram (e.g., a mel-spectrogram). In some implementations in which the input 801 includes video data, the input processor 805 may extract frames or apply resizing to extracted frames, and the embedding component 820 may extract features such as optical flow embeddings or video embeddings and/or may encode temporal information or sequences of frames. In some implementations in which the input 801 includes multi-modal data, the embedding component 820 may fuse representations of the different types of data (e.g., text, image, audio, USD, video, design, etc.) using techniques like early fusion (concatenation), late fusion (sequential processing), attention-based fusion (e.g., self-attention, cross-attention), etc.

The generative LM 830 and/or other components of the generative LM system 800 may use different types of neural network architectures depending on the implementation. For example, transformer-based architectures such as those used in models like GPT may be implemented, and may include self-attention mechanisms that weigh the importance of different words or tokens in the input sequence and/or feedforward networks that process the output of the self-attention layers, applying non-linear transformations to the input representations and extracting higher-level features. Some non-limiting example architectures include transformers (e.g., encoder-decoder, decoder only, multi-modal), RNNs, LSTMs, fusion models, diffusion models, cross-modal embedding models that learn joint embedding spaces, graph neural networks (GNNs), hybrid architectures combining different types of architectures adversarial networks like generative adversarial networks or GANs or adversarial autoencoders (AAEs) for joint distribution learning, linear-time sequence modeling with selective state space modeling (SSM) architectures (e.g., Mamba LLM architectures), and/or others. As such, depending on the implementation and architecture, the embedding component 820 may apply an encoded representation of the input 801 to the generative LM 830, and the generative LM 830 may process the encoded representation of the input 801 to generate an output 890, which may include responsive text and/or other types of data.

As described herein, in some embodiments, the generative LM 830 may be configured to access or use—or capable of accessing or using—plug-ins/APIs 895 (which may include one or more plug-ins, application programming interfaces (APIs), databases, data stores, repositories, etc.). For example, for certain tasks or operations that the generative LM 830 is not ideally suited for, the model may have instructions (e.g., as a result of training, and/or based on instructions in a given prompt, such as those retrieved using the RAG component 892) to access one or more plug-ins/APIs 895 (e.g., 3^{rd} party plugins) for help in processing the current input. In such an example, where at least part of a prompt is related to restaurants or weather, the model may access one or more restaurant or weather plug-ins (e.g., via one or more APIs), send at least a portion of the prompt related to the particular plug-in/API 895 to the plug-in/API 895, the plug-in/API 895 may process the information and return an answer to the generative LM 830, and the generative LM 830 may use the response to generate the output 890. This process may be repeated—e.g., recursively—for any number of iterations and using any number of plug-ins/APIs 895 until an output 890 that addresses each ask/question/request/process/operation/etc. from the input 801 can be generated. As such, the model(s) may not only rely on its own knowledge from training on a large dataset(s) and/or from data retrieved using the RAG component 892, but also on the expertise or optimized nature of one or more external resources—such as the plug-ins/APIs 895.

In some embodiments, one or more transformer engines (TEs) may be implemented. The transformer engine may use micro-tensor scaling to optimize performance and accuracy—such as to enable 16-bit floating point (FP16), 8-bit floating point (FP8), and/or 4-bit floating point (FP4) artificial intelligence processing. For example, the transformer engine may use 16-bit or 8-bit floating point precision and an 8-bit or 4-bit floating point data format combined with software algorithms for increasing AI performance and capabilities. By reducing math operations to 8-bits or 4-bits, the TE allows for training larger networks faster without compromising accuracy. For example, the TEs may include a library for accelerating transformer models on processing devices—such as GPUs—to provide better performance with lower memory utilization in both training and inference. When the TE is combined with other technologies, such as high-speed interconnects between nodes (e.g., using switches—such as NVLink Switches) and tensor cores (which enable mixed-precision computing, such as micro-scaling precision support), server clusters may be more capable of training enormous networks (e.g., billions of parameters) at high speeds. As such, tensor core precisions of FP64, TF32, BF16, FP16, FP8, INT8, FP6, and FP4 may be supported, as well as CUDA core precisions of FP64, FP32, FP16, and BF16.

These and other architectures for LLMs/VLMs/MMLMs/VLAs/etc. described herein are meant simply as examples, and other suitable architectures may be implemented within the scope of the present disclosure.

### Example Computing Device

FIG. 9 is a block diagram of an example computing device(s) 900 suitable for use in implementing some embodiments of the present disclosure. Computing device 900 may include an interconnect system 902 that directly or indirectly couples the following devices: memory 904, one or more central processing units (CPUs) 906, one or more graphics processing units (GPUs) 908, a communication interface 910, input/output (I/O) ports 912, input/output components 914, a power supply 916, one or more presentation components 918 (e.g., display(s), speaker(s), etc.), and one or more logic units 920. In at least one embodiment, the computing device(s) 900 may comprise one or more virtual machines (VMs), and/or any of the components thereof may comprise virtual components (e.g., virtual hardware components). For non-limiting examples, one or more of the GPUs 908 may comprise one or more vGPUs, one or more of the CPUs 906 may comprise one or more vCPUs, and/or one or more of the logic units 920 may comprise one or more virtual logic units. As such, a computing device(s) 900 may include discrete components (e.g., a full GPU dedicated to the computing device 900), virtual components (e.g., a portion of a GPU dedicated to the computing device 900), or a combination thereof.

Although the various blocks of FIG. 9 are shown as connected via the interconnect system 902 with lines, this is not intended to be limiting and is for clarity only. For example, in some embodiments, a presentation component 918, such as a display device, may be considered an I/O component 914 (e.g., if the display is a touch screen). As another example, the CPUs 906 and/or GPUs 908 may include memory (e.g., the memory 904 may be representative of a storage device in addition to the memory of the GPUs 908, the CPUs 906, and/or other components). As such, the computing device of FIG. 9 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 9.

The interconnect system 902 may represent one or more links or busses, such as an address bus, a data bus, a control bus, or a combination thereof. The interconnect system 902 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 906 may be directly connected to the memory 904. Further, the CPU 906 may be directly connected to the GPU 908. Where there is direct, or point-to-point connection between components, the interconnect system 902 may include a PCIe link to carry out the connection. In these examples, a PCI bus need not be included in the computing device 900.

The memory 904 may include any of a variety of computer-readable media. The computer-readable media may be any available media that may be accessed by the computing device 900. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 904 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 900. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 906 may be configured to execute at least some of the computer-readable instructions to control one or more components of the computing device 900 to perform one or more of the methods and/or processes described herein. The CPU(s) 906 may each include one or more cores (e.g., one, two, four, eight, twenty-eight, seventy-two, etc.) that are capable of handling a multitude of software threads simultaneously. The CPU(s) 906 may include any type of processor, and may include different types of processors depending on the type of computing device 900 implemented (e.g., processors with fewer cores for mobile devices and processors with more cores for servers). For example, depending on the type of computing device 900, the processor may be an Advanced RISC Machines (ARM) processor implemented using Reduced Instruction Set Computing (RISC) or an x86 processor implemented using Complex Instruction Set Computing (CISC). The computing device 900 may include one or more CPUs 906 in addition to one or more microprocessors or supplementary co-processors, such as math co-processors.

In addition to or alternatively from the CPU(s) 906, the GPU(s) 908 may be configured to execute at least some of the computer-readable instructions to control one or more components of the computing device 900 to perform one or more of the methods and/or processes described herein. One or more of the GPU(s) 908 may be an integrated GPU (e.g., with one or more of the CPU(s) 906 and/or one or more of the GPU(s) 908 may be a discrete GPU. In embodiments, one or more of the GPU(s) 908 may be a coprocessor of one or more of the CPU(s) 906. The GPU(s) 908 may be used by the computing device 900 to render graphics (e.g., 3D graphics) or perform general purpose computations. For example, the GPU(s) 908 may be used for General-Purpose computing on GPUs (GPGPU). The GPU(s) 908 may include hundreds or thousands of cores that are capable of handling hundreds or thousands of software threads simultaneously. The GPU(s) 908 may generate pixel data for output images in response to rendering commands (e.g., rendering commands from the CPU(s) 906 received via a host interface). The GPU(s) 908 may include graphics memory, such as display memory, for storing pixel data or any other suitable data, such as GPGPU data. The display memory may be included as part of the memory 904. The GPU(s) 908 may include two or more GPUs operating in parallel (e.g., via a link). The link may directly connect the GPUs (e.g., using NVLINK) or may connect the GPUs through a switch (e.g., using NVSwitch). When combined together, each GPU 908 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 906 and/or the GPU(s) 908, the logic unit(s) 920 may be configured to execute at least some of the computer-readable instructions to control one or more components of the computing device 900 to perform one or more of the methods and/or processes described herein. In embodiments, the CPU(s) 906, the GPU(s) 908, and/or the logic unit(s) 920 may discretely or jointly perform any combination of the methods, processes and/or portions thereof. One or more of the logic units 920 may be part of and/or integrated in one or more of the CPU(s) 906 and/or the GPU(s) 908 and/or one or more of the logic units 920 may be discrete components or otherwise external to the CPU(s) 906 and/or the GPU(s) 908. In embodiments, one or more of the logic units 920 may be a coprocessor of one or more of the CPU(s) 906 and/or one or more of the GPU(s) 908.

Examples of the logic unit(s) 920 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Deep Learning Accelerator Clusters (XNNs), Neural Processing Units (NPUs), Neural Network Accelerators (NNAs), Programmable Vision Accelerators (PVAs)—which may include one or more direct memory access (DMA) systems, one or more vision or vector processing units (VPUs), one or more pixel processing engines (PPEs)—e.g., including a 2D array of processing elements that each communicate north, south, east, and west with one or more other processing elements in the array, one or more decoupled accelerators or units (e.g., decoupled lookup table (DLUT) accelerators or units), etc., Vision Processing Units (VPUs), Optical Flow Accelerators (OFAs), Field Programmable Gate Arrays (FPGAs), Neuromorphic Chips, Quantum Processing Units (QPUs), Associative Process Units (APUs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 910 may include one or more receivers, transmitters, and/or transceivers that allow the computing device 900 to communicate with other computing devices via an electronic communication network, included wired and/or wireless communications. The communication interface 910 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 920 and/or communication interface 910 may include one or more data processing units (DPUs) to transmit data received over a network and/or through interconnect system 902 directly to (e.g., a memory of) one or more GPU(s) 908.

The I/O ports 912 may allow the computing device 900 to be logically coupled to other devices including the I/O components 914, the presentation component(s) 918, and/or other components, some of which may be built in to (e.g., integrated in) the computing device 900. Illustrative I/O components 914 include a microphone, mouse, keyboard, joystick, game pad, game controller, satellite dish, scanner, printer, wireless device, etc. The I/O components 914 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 900. The computing device 900 may be include depth cameras, such as stereoscopic camera systems, infrared camera systems, RGB camera systems, touchscreen technology, and combinations of these, for gesture detection and recognition. Additionally, the computing device 900 may include accelerometers or gyroscopes (e.g., as part of an inertia measurement unit (IMU)) that allow detection of motion. In some examples, the output of the accelerometers or gyroscopes may be used by the computing device 900 to render immersive augmented reality or virtual reality.

The power supply 916 may include a hard-wired power supply, a battery power supply, or a combination thereof. The power supply 916 may provide power to the computing device 900 to allow the components of the computing device 900 to operate.

The presentation component(s) 918 may include a display (e.g., a monitor, a touch screen, a television screen, a heads-up-display (HUD), other display types, or a combination thereof), speakers, and/or other presentation components. The presentation component(s) 918 may receive data from other components (e.g., the GPU(s) 908, the CPU(s) 906, DPUs, etc.), and output the data (e.g., as an image, video, sound, etc.).

### Example Network Environment

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 900 of FIG. 9—e.g., each device may include similar components, features, and/or functionality of the computing device(s) 900. In addition, where backend devices (e.g., servers, NAS, etc.) are implemented, the backend devices may be included as part of a data center (such as, but not limited to, those described herein).

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 900 described herein with respect to FIG. 9. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a talking kiosk, a remote control, an appliance, a consumer electronic device, a workstation, an edge device, any combination of these delineated devices, or any other suitable device.

### EXAMPLE CLAUSES

1. In some embodiments, a method comprises overlaying a voxel grid over a three-dimensional (3D) geometry for a first component; determining a set of contact surfaces on the first component based on a contact between a subset of grid cells in the voxel grid and the 3D geometry; and generating, based on the set of contact surfaces, a second component that is configured to couple to the first component within an assembly.
2. The method of clause 1, further comprising updating at least one of the set of contact surfaces on the first component or a corresponding set of contact surfaces on the second component based on a clearance distance between the first component and the second component.
3. The method of any of clauses 1-2, wherein updating at least one of the set of contact surfaces or the corresponding set of contact surfaces comprises generating an occupancy grid corresponding to at least one of the set of contact surfaces or the corresponding set of contact surfaces; and removing, from the occupancy grid, one or more grids that fall within the clearance distance.
4. The method of any of clauses 1-3, further comprising inputting a representation of the first component into a machine learning model; determining, via execution of the machine learning model, one or more attributes associated with the first component; and determining a top of the 3D geometry for the first component based on the one or more attributes.
5. The method of any of clauses 1-4, further comprising rotating the 3D geometry for the first component based on the one or more attributes prior to overlaying the voxel grid over the top of the 3D geometry.
6. The method of any of clauses 1-5, wherein the one or more attributes comprise at least one of a description of the first component, a type of the first component, an assembly axis, or an assembly direction.
7. The method of any of clauses 1-6, wherein the machine learning model comprises a vision language model.
8. The method of any of clauses 1-7, further comprising updating one or more parameters of a machine learning model based on the first component, the second component, and one or more training objectives associated with assembling the first component and the second component to produce a trained machine learning model.
9. The method of any of clauses 1-8, further comprising assembling, via execution of a robot, the assembly using the first component and the second component.
10. The method of any of clauses 1-9, wherein generating the second component comprises conditioning a denoising process associated with a diffusion model on the set of contact surfaces.
11. In some embodiments, at least one processor comprises processing circuitry to perform operations comprises projecting a voxel grid over a three-dimensional (3D) geometry for a first component; determining a set of contact surfaces on the first component based on a contact between a subset of grid cells in the voxel grid and the 3D geometry; and generating, based on the set of contact surfaces, a second component that couples to the first component within an assembly.
12. The at least one processor of clause 11, wherein the operations further comprise generating an occupancy grid corresponding to at least one of the set of contact surfaces or a corresponding set of contact surfaces on the second component; and removing, from the occupancy grid, one or more grids that fall within a clearance distance between the first component and the second component to generate at least one of an updated first component corresponding to the first component or an updated second component corresponding to the second component.
13. The at least one processor of any of clauses 11-12, wherein the operations further comprise providing a rendering of the 3D geometry for the first component and one or more instructions to describe the first component as input to a machine learning model; determining, via execution of the machine learning model, one or more attributes associated with the first component; and determining the set of contact surfaces based on the one or more attributes.
14. The at least one processor of any of clauses 11-13, wherein the operations further comprise rotating the 3D geometry for the first component based on the one or more attributes prior to overlaying the voxel grid over the 3D geometry.
15. The at least one processor of any of clauses 11-14, wherein the one or more attributes comprise at least one of a description of the first component, a type of the first component, an assembly axis, or an assembly direction.
16. The at least one processor of any of clauses 11-15, wherein generating the second component comprises conditioning a denoising process associated with a diffusion model on the set of contact surfaces.
17. The at least one processor of any of clauses 11-16, wherein the operations further comprise updating one or more parameters of a machine learning model based on the first component, the second component, and one or more training objectives associated with the assembly of the first component and the second component to produce a trained machine learning model.
18. The at least one processor of any of clauses 11-17, wherein the at least one processor is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using one or more large language model (LLMs); a system for performing operations using one or more vision language models (VLMs); a system for performing operations using one or more multi-modal language models (MMLMs); a system for performing operations using one or more vision-language-action (VLA) models; a system for using or deploying one or more inference microservices; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.
19. In some embodiments, a system comprises one or more processors to perform operations comprising projecting a voxel grid over a three-dimensional (3D) geometry for a first component; determining a set of contact surfaces on the first component based on a contact between a subset of grid cells in the voxel grid and the 3D geometry; and generating, based on the set of contact surfaces, a second component that couples to the first component within an assembly.
20. The system of claim 19, wherein the at least one processor is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using one or more large language model (LLMs); a system for performing operations using one or more vision language models (VLMs); a system for performing operations using one or more multi-modal language models (MMLMs); a system for performing operations using one or more vision-language-action (VLA) models; a system for using or deploying one or more inference microservices; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A method comprising:
overlaying a voxel grid over a three-dimensional (3D) geometry for a first component;
determining a set of contact surfaces on the first component based on a contact between a subset of grid cells in the voxel grid and the 3D geometry; and
generating, based on the set of contact surfaces, a second component that is configured to couple to the first component within an assembly.

2. The method of claim 1, further comprising updating at least one of the set of contact surfaces on the first component or a corresponding set of contact surfaces on the second component based on a clearance distance between the first component and the second component.

3. The method of claim 2, wherein updating at least one of the set of contact surfaces or the corresponding set of contact surfaces comprises:
generating an occupancy grid corresponding to at least one of the set of contact surfaces or the corresponding set of contact surfaces; and
removing, from the occupancy grid, one or more grids that fall within the clearance distance.

4. The method of claim 1, further comprising:
inputting a representation of the first component into a machine learning model;
determining, via execution of the machine learning model, one or more attributes associated with the first component; and
determining a top of the 3D geometry for the first component based on the one or more attributes.

5. The method of claim 4, further comprising rotating the 3D geometry for the first component based on the one or more attributes prior to overlaying the voxel grid over the top of the 3D geometry.

6. The method of claim 4, wherein the one or more attributes comprise at least one of a description of the first component, a type of the first component, an assembly axis, or an assembly direction.

7. The method of claim 4, wherein the machine learning model comprises a vision language model.

8. The method of claim 1, further comprising updating one or more parameters of a machine learning model based on the first component, the second component, and one or more training objectives associated with assembling the first component and the second component to produce a trained machine learning model.

9. The method of claim 1, further comprising assembling, via execution of a robot, the assembly using the first component and the second component.

10. The method of claim 1, wherein generating the second component comprises conditioning a denoising process associated with a diffusion model on the set of contact surfaces.

11. At least one processor comprising:
processing circuitry to perform operations comprising:
projecting a voxel grid over a three-dimensional (3D) geometry for a first component;
determining a set of contact surfaces on the first component based on a contact between a subset of grid cells in the voxel grid and the 3D geometry; and
generating, based on the set of contact surfaces, a second component that couples to the first component within an assembly.

12. The at least one processor of claim 11, wherein the operations further comprise:
generating an occupancy grid corresponding to at least one of the set of contact surfaces or a corresponding set of contact surfaces on the second component; and
removing, from the occupancy grid, one or more grids that fall within a clearance distance between the first component and the second component to generate at least one of an updated first component corresponding to the first component or an updated second component corresponding to the second component.

13. The at least one processor of claim 11, wherein the operations further comprise:
providing a rendering of the 3D geometry for the first component and one or more instructions to describe the first component as input to a machine learning model;
determining, via execution of the machine learning model, one or more attributes associated with the first component; and
determining the set of contact surfaces based on the one or more attributes.

14. The at least one processor of claim 13, wherein the operations further comprise rotating the 3D geometry for the first component based on the one or more attributes prior to overlaying the voxel grid over the 3D geometry.

15. The at least one processor of claim 13, wherein the one or more attributes comprise at least one of a description of the first component, a type of the first component, an assembly axis, or an assembly direction.

16. The at least one processor of claim 11, wherein generating the second component comprises conditioning a denoising process associated with a diffusion model on the set of contact surfaces.

17. The at least one processor of claim 11, wherein the operations further comprise updating one or more parameters of a machine learning model based on the first component, the second component, and one or more training objectives associated with the assembly of the first component and the second component to produce a trained machine learning model.

18. The at least one processor of claim 11, wherein the at least one processor is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using one or more large language model (LLMs);
a system for performing operations using one or more vision language models (VLMs);
a system for performing operations using one or more multi-modal language models (MMLMs);
a system for performing operations using one or more vision-language-action (VLA) models;
a system for using or deploying one or more inference microservices;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.

19. A system comprising:
one or more processors to perform operations comprising:
projecting a voxel grid over a three-dimensional (3D) geometry for a first component;
determining a set of contact surfaces on the first component based on a contact between a subset of grid cells in the voxel grid and the 3D geometry; and
generating, based on the set of contact surfaces, a second component that couples to the first component within an assembly.

20. The system of claim 19, wherein the one or more processors in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using one or more large language model (LLMs);
a system for performing operations using one or more vision language models (VLMs);
a system for performing operations using one or more multi-modal language models (MMLMs);
a system for performing operations using one or more vision-language-action (VLA) models;
a system for using or deploying one or more inference microservices;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.
